(19) United States
(12) Patent Application Publication
(10) Pub. No.: US 2026/0250507 A1
(43) Pub. Date: Aug. 27, 2026

(54) COMPOSITION, PREPREG, AND METAL-CLAD LAMINATE

(71) Applicant: AGC INC., Tokyo (JP)

(72) Inventors: Takuma HIRATA, Tokyo (JP); Masahito YAGISHITA, Tokyo (JP); Yu TAKEUCHI, Tokyo (JP); Tadashi IWAMOTO, Tokyo (JP); Naoki MAEDA, Tokyo (JP)

(73) Assignee: AGC INC., Tokyo (JP)

(21) Appl. No.: 19/648,447

(22) Filed: Apr. 15, 2026

Related U.S. Application Data
(63) Continuation of application No. PCT/JP2024/036778, filed on Oct. 16, 2024.

(30) Foreign Application Priority Data
Oct. 16, 2023 (JP) 2023-178264
Apr. 24, 2024 (JP) 2024-070639
Sep. 5, 2024 (JP) 2024-153223

(51) Int. Cl. C08L 71/00; B32B 15/08; B32B 27/28

(52) U.S. Cl. CPC C08L 71/00; B32B 15/08; B32B 27/285; B32B 2250/02; B32B 2307/204; B32B 2371/00

(57) ABSTRACT

An object of the present disclosure is to provide a composition with excellent electrical properties and heat resistance, a composition with excellent electrical properties, heat resistance, and curability, and a prepreg and a metal-clad laminate containing these compositions. The present disclosure relates to a composition containing a compound 1 having an olefin structure at a terminal portion and a compound 2 having a structure represented by Formula (1) as defined in the specification and a heterocyclic structure. In addition, the present disclosure relates to a composition containing a compound 1 having an olefin structure at a terminal portion and a crosslinking agent having an olefin structure and a benzene ring structure. The crosslinking agent may have a styrene structure and may include at least one selected from crosslinking agents A to D as defined in the specification.

### INCORPORATION BY REFERENCE

This application is based upon and claims the benefit of priority from Japanese Patent Application No. 2023-178264 filed on Oct. 16, 2023, Japanese Patent Application No. 2024-070639 filed on Apr. 24, 2024, Japanese Patent Application No. 2024-153223 filed on Sep. 5, 2024, and PCT application No. PCT/JP2024/036778 filed on Oct. 16, 2024, the disclosure of which is incorporated herein in its entirety by reference.

### BACKGROUND

The present disclosure relates to a composition, a prepreg, and a metal-clad laminate.

A laminate used for a printed circuit board employed in high-speed communication is required to have further improved performance. A composition used for the laminate is required to have not only electrical insulating properties but also practical performance such as heat resistance.

Japanese Unexamined Patent Application Publication No. 2022-61730 discloses a metal-clad laminate including a polymer layer containing materials such as bismaleimide and polyphenylene ether (PPE).

In addition, Japanese Unexamined Patent Application Publication No. 2022-131074 discloses a resin substrate with excellent electrical properties, which contains a fluororesin material such as polytetrafluoroethylene (PTFE).

### SUMMARY

When a polymer layer containing materials such as PPE described in Japanese Unexamined Patent Application Publication No. 2022-61730 is used in a metal-clad laminate, electrical properties may be inferior.

Further, when a polymer layer containing a fluororesin material such as PTFE described in Japanese Unexamined Patent Application Publication No. 2022-131074 is used in a metal-clad laminate, although electrical properties are excellent, heat resistance may be inferior because the polymer layer is a thermoplastic resin.

The present disclosure has been made in view of the above problems, and an object thereof is to provide a composition, a prepreg, and a metal-clad laminate with excellent electrical properties and heat resistance. Another object of the present disclosure is to provide a composition, a prepreg, and a metal-clad laminate with excellent electrical properties, heat resistance, and curability.

The composition, prepreg, and metal-clad laminate according to the present disclosure are as set forth in the following [1] to [33].

[1]A composition containing: a compound 1 having an olefin structure at a terminal portion; and a compound 2 having a structure represented by the following Formula (1) and a heterocyclic structure:

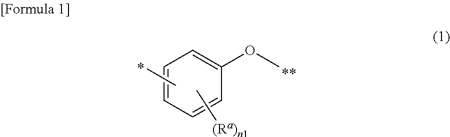

in Formula (1),
each R^{a} is independently a hydroxyl group, a halogen group, a substituted or unsubstituted C6-C20 aromatic hydrocarbon group, a substituted or unsubstituted C1-C20 alkyl group, a substituted or unsubstituted C5-C20 cycloalkyl group, or a substituted or unsubstituted C7-C20 aralkyl group,
n1 represents an integer of 0 to 4, and
* and ** each represent a bonding position.

[2] The composition according to [1], in which the compound 2 has a structure represented by the following Formula (2) or a structure represented by the following Formula (20):

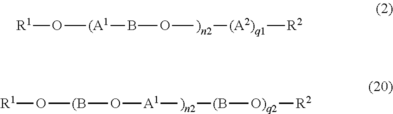

in Formulas (2) and (20),
R¹ and R² are each independently a C2-C50 group containing an ethylenically unsaturated double bond, a substituted or unsubstituted C6-C50 aromatic hydrocarbon group, a substituted or unsubstituted C6-C50 aliphatic hydrocarbon group, or a substituted or unsubstituted nitrogen-containing heteroaromatic ring,
A¹ and A² are each independently a group having a structure represented by Formula (1), provided that, in Formula (2), ** in Formula (1) represents a bonding position with B or R², and in Formula (20), ** in Formula (1) represents a bonding position with B or R²,
each B is independently a divalent group having a nitrogen-containing heterocyclic structure,
each n2 is independently an integer of 1 or more,
q1 is 0 or 1, and when q1 is 0, (A²)_{q1} represents a single bond, and
q2 is 0 or 1, and when q2 is 0, (B—O)_{q2} represents a single bond.

[3] The composition according to [1] or [2], in which the compound 2 has a structure represented by the following Formula (3):

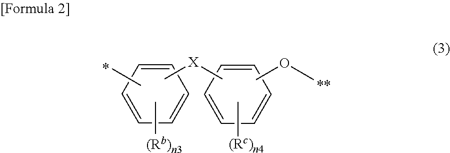

in Formula (3),
R^{b} and R^{c} are each independently a hydroxyl group, a halogen group, a substituted or unsubstituted C6-C20 aromatic hydrocarbon group, a substituted or unsubstituted C1-C20 alkyl group, a substituted or unsubstituted C5-C20 cycloalkyl group, or a substituted or unsubstituted C7-C20 aralkyl group,
n3 and n4 each independently represent an integer of 0 to 4,
X is a single bond, a substituted or unsubstituted C6-C20 aromatic hydrocarbon group, a substituted or unsubstituted C1-C20 alkylene group, a substituted or unsubstituted C5-C20 cycloalkylene group, a substituted or unsubstituted C1-C20 alkylidene group, a substituted or unsubstituted C5-C20 cycloalkylidene group, a substituted or unsubstituted C8-C20 aralkylene group, a substituted or unsubstituted C7-C20 aralkylidene group, or a group obtained by combining these groups, and
* and ** each represent a bonding position.

[4] The composition according to [2], in which the group having a structure represented by Formula (1) is a group represented by the following Formula (3):

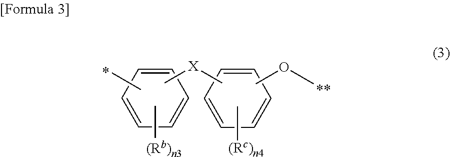

in Formula (3),
R^{b} and R^{c} are each independently a hydroxyl group, a halogen group, a substituted or unsubstituted C6-C20 aromatic hydrocarbon group, a substituted or unsubstituted C1-C20 alkyl group, a substituted or unsubstituted C5-C20 cycloalkyl group, or a substituted or unsubstituted C7-C20 aralkyl group,
n3 and n4 each independently represent an integer of 0 to 4,
X is a single bond, a substituted or unsubstituted C6-C20 aromatic hydrocarbon group, a substituted or unsubstituted C1-C20 alkylene group, a substituted or unsubstituted C5-C20 cycloalkylene group, a substituted or unsubstituted C1-C20 alkylidene group, a substituted or unsubstituted C5-C20 cycloalkylidene group, a substituted or unsubstituted C8-C20 aralkylene group, a substituted or unsubstituted C7-C20 aralkylidene group, or a group obtained by combining these groups, and
* and ** each represent a bonding position, provided that * is a bonding position with 0, and ** is a bonding position with B or R²

[5] The composition according to any one of [1] to [4], in which the heterocyclic structure is a structure selected from the following:

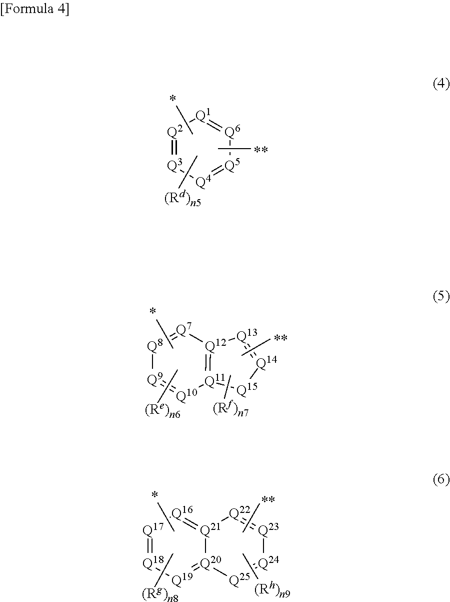

in Formulas (4) to (6),
R^{d} to Rh are each independently a substituted or unsubstituted C1-C20 alkyl group or a substituted or unsubstituted C6-C20 aromatic hydrocarbon group,
n5 represents an integer of 0 to 4,
n6, n8, and n9 each independently represent an integer of 0 to 3,
n7 represents an integer of 0 to 2,
Q¹ to Q²⁵ are each independently a nitrogen atom or a carbon atom, provided that at least one of Q¹ to Q⁶ is a nitrogen atom, at least one of Q⁷ to Q¹⁵ is a nitrogen atom, at least one of Q¹⁶ to Q²⁵ is a nitrogen atom, and when at least one of Q¹¹ and Q¹² is a nitrogen atom, the bond between Q¹¹ and Q¹², and the bond between Q⁷ and Q¹² and the bond between Q¹² and Q¹³, or the bond between Q¹¹ and Q¹² and the bond between Q¹¹ and Q¹², are single bonds, and when at least one of Q²⁰ and Q²¹ is a nitrogen atom, the bond between Q²⁰ and Q²¹, and the bond between Q¹⁶ and Q²¹ and the bond between Q²¹ and Q²², or the bond between Q¹⁹ and Q²⁰ and the bond between Q²⁰ and Q²⁵, are single bonds, and
* and ** each represent a bonding position.

[6] The composition according to [2], in which the divalent group having a nitrogen-containing heterocyclic structure is a group selected from the following:

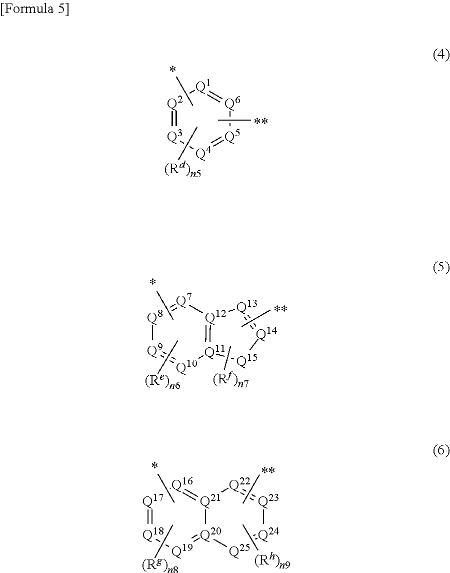

in Formulas (4) to (6),
R^{d} to R^{h} are each independently a substituted or unsubstituted C1-C20 alkyl group or a substituted or unsubstituted C6-C20 aromatic hydrocarbon group,
n5 represents an integer of 0 to 4,
n6, n8, and n9 each independently represent an integer of 0 to 3,
n7 represents an integer of 0 to 2,
Q¹ to Q²⁵ are each independently a nitrogen atom or a carbon atom, provided that at least one of Q¹ to Q⁶ is a nitrogen atom, at least one of Q⁷ to Q¹⁵ is a nitrogen atom, at least one of Q¹⁶ to Q²¹ is a nitrogen atom, and when at least one of Q¹¹ and Q¹² is a nitrogen atom, the bond between Q¹¹ and Q¹², and the bond between Q⁷ and Q¹² and the bond between Q¹² and Q¹³, or the bond between Q¹⁰ and Q¹¹ and the bond between Q¹¹ and Q¹⁵, are single bonds, and when at least one of Q²⁰ and Q²¹ is a nitrogen atom, the bond between Q²⁰ and Q²¹ and the bond between Q¹⁶ and Q²¹ and the bond between Q²¹ and Q²², or the bond between Q¹⁹ and Q²⁰ and the bond between Q²⁰ and Q²⁵, are single bonds, and
* and ** are each a bonding position with A¹ or O in Formula (2), and a bonding position with O or A¹ in Formula (20).

[7] The composition according to any one of [1] to [6], in which the compound 2 is a compound represented by the following Formula (7):

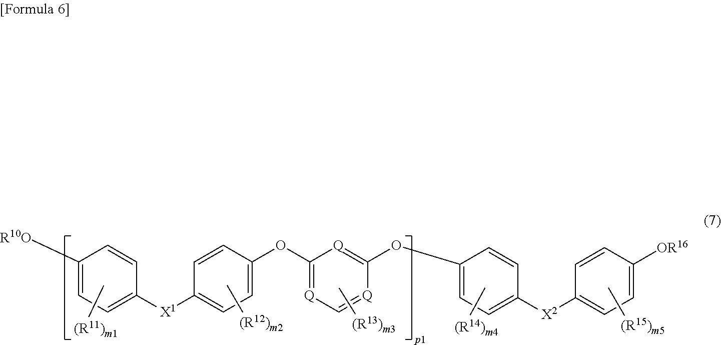

in Formula (7),
R¹⁰ and R¹⁶ are each independently a C2-C50 group containing an ethylenically unsaturated double bond, a substituted or unsubstituted C6-C50 aromatic hydrocarbon group, a substituted or unsubstituted C6-C50 aliphatic hydrocarbon group, or a substituted or unsubstituted nitrogen-containing heteroaromatic ring,
R¹¹, R¹², R¹⁴, and R¹⁵ are each independently a hydroxyl group, a halogen group, a substituted or unsubstituted C6-C20 aromatic hydrocarbon group, a substituted or unsubstituted C1-C20 alkyl group, a substituted or unsubstituted C5-C20 cycloalkyl group, or a substituted or unsubstituted C7-C20 aralkyl group,
each R¹³ is independently a substituted or unsubstituted C1-C20 alkyl group or a substituted or unsubstituted C6-C20 aromatic hydrocarbon group,
X¹ and X² are each independently a single bond, a substituted or unsubstituted C6-C20 aromatic hydrocarbon group, a substituted or unsubstituted C1-C20 alkylene group, a substituted or unsubstituted C5-C20 cycloalkylene group, a substituted or unsubstituted C1-C20 alkylidene group, a substituted or unsubstituted C5-C20 cycloalkylidene group, a substituted or unsubstituted C8-C20 aralkylene group, a substituted or unsubstituted C7-C20 aralkylidene group, or a group obtained by combining these groups,
each Q is independently a nitrogen atom or a carbon atom, provided that at least two of Q are nitrogen atoms,
m1, m2, m4, and m5 each independently represent an integer of 0 to 4,
each m3 independently represents an integer of 0 to 2, and
p1 is an integer of 1 or more.

[8] The composition according to any one of [1] to [7], in which the compound 2 is a compound represented by the following Formula (7A):

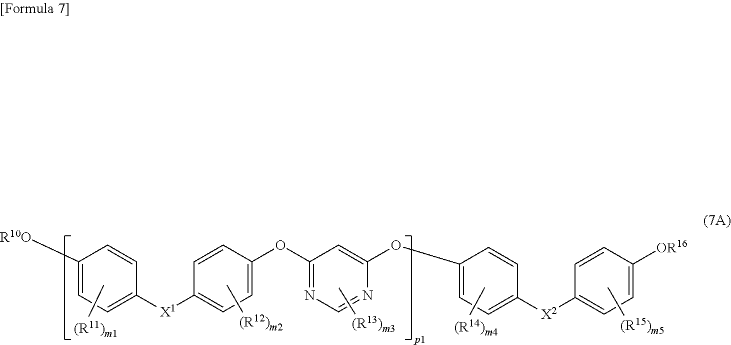

in Formula (7A),
R¹⁰ and R¹⁶ are each independently a C2-C50 group containing an ethylenically unsaturated double bond, a substituted or unsubstituted C6-C50 aromatic hydrocarbon group, a substituted or unsubstituted C6-C50 aliphatic hydrocarbon group, or a substituted or unsubstituted nitrogen-containing heteroaromatic ring,
R¹¹, R¹², R¹⁴, and R¹⁵ are each independently a hydroxyl group, a halogen group, a substituted or unsubstituted C6-C20 aromatic hydrocarbon group, a substituted or unsubstituted C1-C20 alkyl group, a substituted or unsubstituted C5-C20 cycloalkyl group, or a substituted or unsubstituted C7-C20 aralkyl group,
each R¹³ is independently a substituted or unsubstituted C1-C20 alkyl group or a substituted or unsubstituted C6-C20 aromatic hydrocarbon group,
X¹ and X² are each independently a single bond, a substituted or unsubstituted C6-C20 aromatic hydrocarbon group, a substituted or unsubstituted C1-C20 alkylene group, a substituted or unsubstituted C5-C20 cycloalkylene group, a substituted or unsubstituted C1-C20 alkylidene group, a substituted or unsubstituted C5-C20 cycloalkylidene group, a substituted or unsubstituted C8-C20 aralkylene group, a substituted or unsubstituted C7-C20 aralkylidene group, or a group obtained by combining these groups,
m1, m2, m4, and m5 each independently represent an integer of 0 to 4,
each m3 independently represents an integer of 0 to 2, and
p1 is an integer of 1 or more.

[9] The composition according to any one of [1] to [8], in which the compound 2 has a weight average molecular weight Mw of 1,000 or more and 500,000 or less.

[10] The composition according to any one of [1] to [9], in which the compound 1 has an isoalkenyl group at a terminal portion and further has a benzene ring structure in a molecular structure.

[11] The composition according to any one of [1] to [10], in which the compound 1 is a compound derived from a raw material compound having a benzene ring and a plurality of isoalkenyl groups, or a compound derived from a precursor of the raw material compound.

[12] The composition according to [11], in which the raw material compound is 1,3-diisoalkenylbenzene or 1,4-diisoalkenylbenzene.

[13] The composition according to any one of [1] to [12], further containing at least one of a resin containing a radical-polymerizable group and a crosslinking agent.

[14] The composition according to [13], in which the crosslinking agent is a compound having one or more reactive functional groups selected from a styryl group (St group), a maleimide group, an allyl group, and a (meth)acryloyl group.

[15] The composition according to [13] or [14], in which the crosslinking agent is 1,2-bis(vinylphenyl)ethane (BVPE).

[16] The composition according to any one of [1] to [15], in which a content ratio of the compound 1 with respect to a total content of the compound 1 and the compound 2 is 10 to 99 mass %.

[17] The composition according to any one of [1] to [16], in which a dielectric loss tangent Df at 25° C. and a measurement frequency of 10 GHz is 0.0003 to 0.0009.

[18] The composition according to any one of [1] to [17], in which a dielectric constant Dk at 25° C. and a measurement frequency of 10 GHz is 2.3 to 3.0.

[19] The composition according to any one of [1] to [18], in which a glass transition temperature Tg is 120 to 250° C.

[20] A prepreg containing the composition according to any one of [1] to [19].

[21]A metal-clad laminate including a cured product of the composition according to any one of [1] to [19] and a metal foil.

[22]A composition containing a compound 1 having an olefin structure at a terminal portion and a crosslinking agent having an olefin structure and a benzene ring structure.

[23] The composition according to [22], in which the crosslinking agent has a styrene structure.

[24] The composition according to [22], in which the crosslinking agent includes at least one selected from the following crosslinking agents A to D:

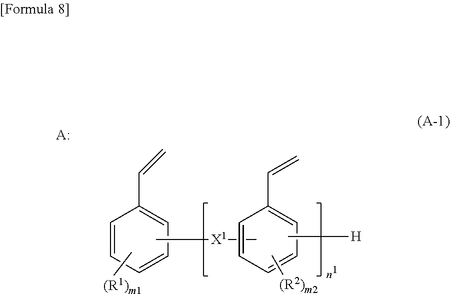

in Formula (A-1),
R¹ and R² are each independently a hydroxyl group, a halogen group, a substituted or unsubstituted C1-C20 hydrocarbon group, a substituted or unsubstituted C1-C20 heterocyclic group, a C1-C20 alkoxy group, a C1-C20 thioalkoxy group, or a C1-C20 thioaryloxy group,
each X¹ is independently a C1-C20 divalent organic group,
n¹ is an integer of 1 to 10,
m¹ is an integer of 0 to 4, and
each m² is independently an integer of 0 to 3,

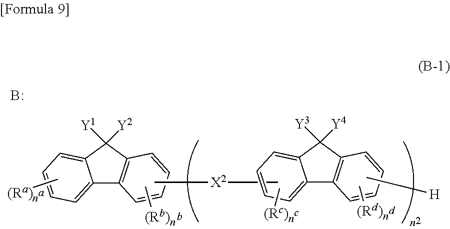

in Formula (B-1),
Y¹ to Y⁴ are each independently a hydrogen atom, a vinyl group, an allyl group, a group represented by the following Formula (B-2), or a group represented by the following Formula (B-3), provided that at least one of Y¹ to Y⁴ is a vinyl group, an allyl group, a group represented by the following Formula (B-2), or a group represented by the following Formula (B-3),
R^{a} to R^{d} are each independently a halogen group, a substituted or unsubstituted C1-C20 hydrocarbon group, a C1-C20 alkoxy group, a C1-C20 thioalkoxy group, or a C1-C20 thioaryloxy group,
each X² is independently a C1-C20 divalent organic group,
n² is an integer of 0 to 20,
n^{a} and n^{b} are each independently an integer of 0 to 4, and
n^{c} and n^{d} are each independently an integer of 0 to 3,

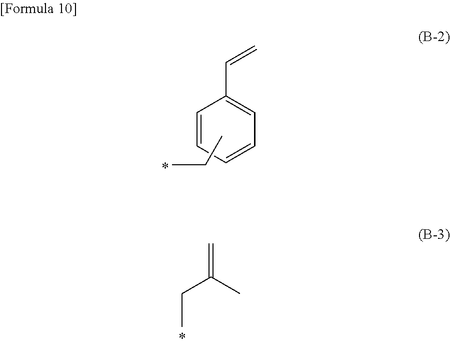

in Formulas (B-2) and (B-3),
* represents a bonding position,

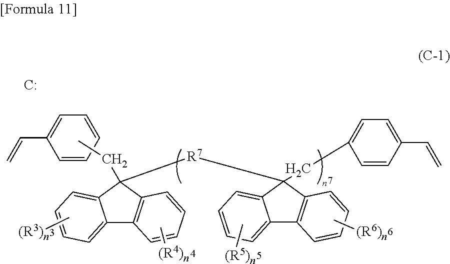

in Formula (C-1),
R³ to R⁶ are each independently a hydroxyl group, a halogen group, a substituted or unsubstituted C1-C20 hydrocarbon group, a C1-C20 alkoxy group, a C1-C20 thioalkoxy group, or a C1-C20 thioaryloxy group,
each R⁷ is independently a C1-C20 divalent organic group,
n³ to n⁶ are each independently an integer of 0 to 4, and
n⁷ is an integer of 1 to 20,

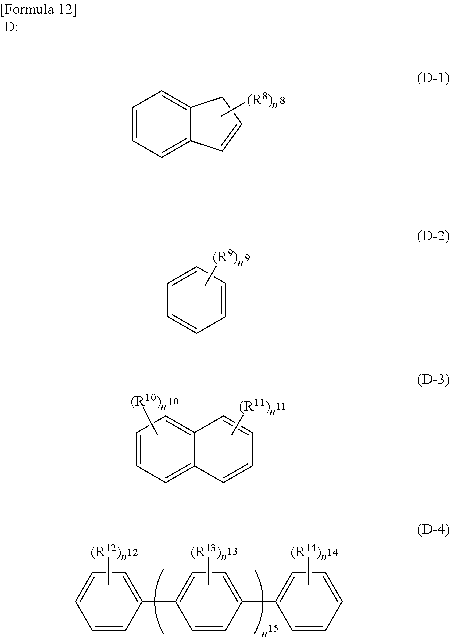

in Formulas (D-1) to (D-4)
each R⁸ is independently a vinyl group, an allyl group, a group represented by the following Formula (B-2), or a. group represented by the following Formula (B3-3),
R⁹ to R¹⁴ are each independently a hydroxyl group, a halogen group, a substituted or unsubstituted C1-C20 hydrocarbon group, a substituted or unsubstituted C1-C20 heterocyclic group, a C1-C20 alkoxy group, a C1-C20 thioalkoxy group. a C1-C20 thioaryloxy group, a vinyl group, an allyl group, a group represented by the following Formula (B-2), a group represented by the following Formula (D-5), or a group represented by the following Formula (B-3), provided that each compound represented by any one of Formulas (D-2) to (D-4) has at least one selected from a vinyl group, an allyl group, a group represented by the following Formula (B-2), a group represented by the following Formula (D-5), or a group represented by the following Formula (B-3),
n⁸ is an integer of 1 to 3,
n⁹ is an integer of 1 to 6,
n¹⁰ and n¹¹ are each independently an integer of 0 to 4, provided that either n¹⁰ or n¹¹ is an integer of 1 or more,
n¹² and n¹¹ are each independently an integer of 0 to 5, n¹¹ is an integer of 0 to 4, provided that any one of n¹² to n¹⁴ is an integer of 1 or more, and
n¹⁵ is an integer of 0 to 20,

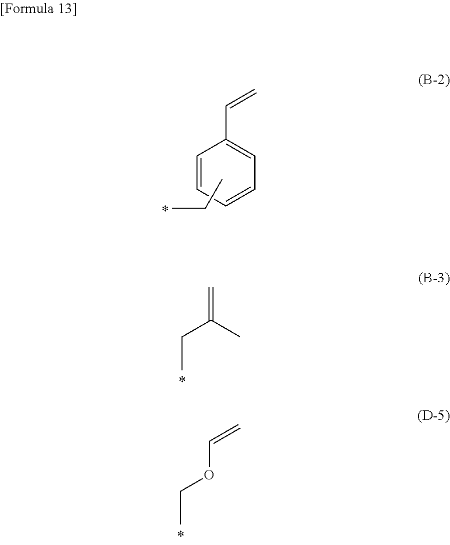

in Formulas (B3-2), (B-3), and (D-5),
* represents a bonding position.

[25] The composition according to any one of [22] to [24], in which the composition contains two or more kinds of the crosslinking agent.

[26] The composition according to any one of [22] to [25], in which the compound 1 has an isoalkenyl group at a terminal portion and further has a benzene ring structure in a molecular structure.

[27] The composition according to any one of [22] to [26], in which the compound 1 is a compound derived from a raw material compound having a benzene ring and a plurality of isoalkenyl groups, or a compound derived from a precursor of the raw material compound.

[28] The composition according to [27], in which the raw material compound is 1,3-diisoalkenylbenzene or 1,4-diisoalkenylbenzene.

[29] The composition according to any one of [22] to [28], further containing a radical polymerization initiator.

[30] The composition according to any one of [22] to [29], in which a glass transition temperature Tg of a cured product of the composition is 120° C. or higher.

[31] The composition according to any one of [22] to [30], in which a dielectric loss tangent Df of a cured product of the composition at 25° C. and a measurement frequency of 10 GHz is 0.003 or less.

[32]A prepreg containing the composition according to any one of [22] to [31].

[33]A metal-clad laminate including a cured product of the composition according to any one of [22] to [31] and a metal foil.

According to the present disclosure, there are provided a composition, a prepreg, and a metal-clad laminate with excellent electrical properties and heat resistance. In addition, according to the present disclosure, there are provided a composition, a prepreg, and a metal-clad laminate with excellent electrical properties, heat resistance, and curability.

The above and other objects, features and advantages of the present disclosure will become more fully understood from the detailed description given hereinbelow.

### DESCRIPTION OF EMBODIMENTS

In the present specification, numerical ranges expressed using “to” include the numerical values described before and after “to” as the minimum value and the maximum value, respectively.

In numerical ranges described stepwise in the present specification, an upper limit value or a lower limit value described in one numerical range may be replaced with an upper limit value or a lower limit value of another stepwise-described numerical range. In addition, in numerical ranges described in the present specification, an upper limit value or a lower limit value of the numerical range may be replaced with a value shown in the Examples.

When the same symbol is present in a single chemical formula, the same symbol may represent structures that are identical to each other, or may represent structures that are different from each other within the defined range.

As described above, a composition (resin composition) used for a laminate mounted on electric and electronic components is required to have not only electrical properties but also practical performance such as heat resistance and curability.

In particular, for laminates used in high-speed communication, it is desirable to use a resin having an extremely low loss, for example, a dielectric loss tangent at a frequency of 10 GHz of 0.003 or less (more preferably 0.0015 or less), or 0.002 or less (more preferably 0.001 or less).

In addition, as such resins, a hydrocarbon-based resin composed of carbon atoms and hydrogen atoms, and a fluororesin have heretofore been used. More specifically, examples of the hydrocarbon-based resin include a polyfunctional vinyl aromatic polymer, a cyclic polyolefin resin, and a vinyl aromatic compound-conjugated diene-based compound copolymer. In addition, examples of the fluororesin include polytetrafluoroethylene described in Japanese Unexamined Patent Application Publication No. 2022-131074. However, a fluororesin, which is a thermoplastic resin, may be inferior in heat resistance.

As a result of intensive studies, the present inventors have found that, by using, for a metal-clad laminate, a composition containing a compound 1 having an olefin structure at a terminal portion and a crosslinking agent having an olefin structure and a benzene ring structure, electrical properties, heat resistance, and curability can be made better than those of conventional metal-clad laminates.

In addition, as described above, Japanese Unexamined Patent Application Publication No. 2022-61730 discloses a metal-clad laminate including a low-dielectric and adhesive polymer layer containing materials such as bismaleimide and polyphenylene ether in order to improve high-speed transmission properties.

However, even when the materials described in Japanese Unexamined Patent Application Publication No. 2022-61730 are used in a laminate, electrical properties may be insufficient in some cases. The present inventors have found that, by using, for a metal-clad laminate, a composition containing a compound 1 having an olefin structure at a terminal portion and a compound 2 having a structure represented by Formula (1) described above and a heterocyclic structure, excellent electrical properties and heat resistance can be imparted.

Hereinafter, embodiments of a composition according to the present disclosure (hereinafter, also referred to as “the present composition”) will be described in detail; however, the present disclosure is not limited to these embodiments. In addition, the present disclosure can be carried out with arbitrary modifications within a range not departing from the gist of the present disclosure. The present composition may be a curable composition. Hereinafter, the composition according to the present disclosure containing the compound 1 and the compound 2 is referred to as a first composition, and the composition according to the present disclosure containing the compound 1 and the specific crosslinking agent is referred to as a second composition. Two embodiments according to the present disclosure will be described.

### First Composition

A first composition contains a compound 1 having an olefin structure at a terminal portion and a compound 2 having a structure represented by the following Formula (I) and a heterocyclic structure. By using the compound 1 and the compound 2 in combination, the first composition can keep a dielectric loss tangent Df low and can further have excellent heat resistance. Each of the compound 1 and the compound 2 may be used alone as a single kind, or a plurality of kinds thereof may be used in combination. The molecular structure of each compound contained in the composition can be identified using ¹H-NMR, ¹³C-NMR, and the like. Details will be described below.

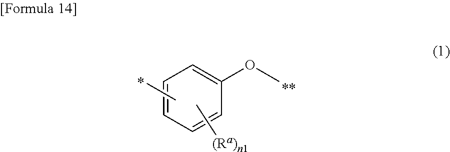

In Formula (1), each R^{a} is independently a hydroxyl group, a halogen group, a substituted or unsubstituted C6-C20 aromatic hydrocarbon group, a substituted or unsubstituted C1-C20 alkyl group, a substituted or unsubstituted C5-C20 cycloalkyl group, or a substituted or unsubstituted C7-C20 aralkyl group, n1 represents an integer of 0 to 4, and * and ** each represent a bonding position.

### Compound 1

The compound 1 has an olefin structure at a terminal portion in the molecular structure. The compound 1 may be a resin. The compound 1 may have, for example, an isoalkenyl group at a terminal portion, more specifically, for example, a C2-C10 alkenyl group. That is, the olefin structure may be a carbon-carbon double bond of the C2-C10 alkenyl group. The alkenyl group may be linear or branched, and may be, for example, a normal alkenyl group or an isoalkenyl group. More specifically, examples of the alkenyl group include a normal propenyl group, an isopropenyl group. a 2-butenyl group, and a 3-butenyl group.

When the compound 1 has an isopropenyl group as an olefin structure at a terminal portion in the molecular structure, the compound 1 can be represented, for example, by the following Formula (8).

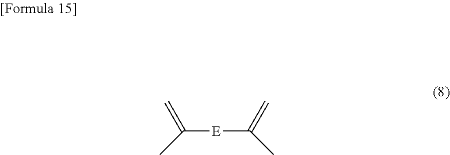

In Formula (8), E represents a polymer chain.

Furthermore, the compound 1 may have a benzene ring structure in the molecular structure. The benzene ring structure may have a substituent on the benzene ring, or may not have a substituent. Examples of the substituent include a hydroxyl group, a halogen group, a C1-C20 alkyl group, a C1-C20 halogenated alkyl group, a C5-C20 cycloalkyl group, or a C7-C20 aralkyl group. Examples of the halogen group include —F, —Cl, —Br, and —I. Examples of the C1-C20 alkyl group include a methyl group, an ethyl group, an n-propyl group, an isopropyl group, an isopropenyl group, a t-butyl group, and an n-butyl group. The halogenated alkyl group is a group in which a hydrogen atom of an alkyl group is substituted with a halogen atom, and examples of the halogen atom include F, Cl, Br, and 1. Examples of the C5-C20 cycloalkyl group include a cyclopentyl group and a cyclohexyl group. Examples of the C7-C20 aralkyl group include a phenylmethyl group (benzyl group), a phenylethyl group (phenethyl group), a phenylpropyl group, and a diphenylmethyl group.

The compound 1 may have, for example, a structure represented by the following Formula (8-1).

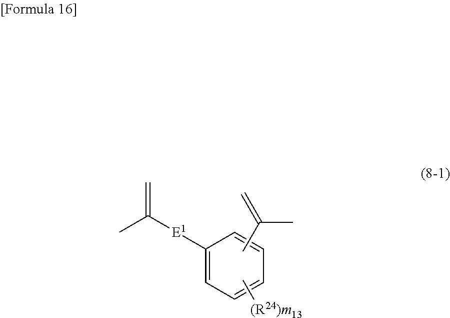

In Formula (8-1), E¹ represents a polymer chain, each R²⁴ independently represents a C1-C10 hydrocarbon group or a halogenated alkyl group, and m13 represents an integer of 0 to 4. Here, from the viewpoint of electrical properties, R²⁴ is preferably a C1-C5 hydrocarbon group, and more preferably a C1-C3 hydrocarbon group. Examples of the C1-C10 hydrocarbon group include a methyl group, an ethyl group, an n-propyl group, an isopropyl group, an isopropenyl group, a t-butyl group, and an n-butyl group. The halogenated alkyl group is a group in which a hydrogen atom of an alkyl group is substituted with a halogen atom, and examples of the halogen atom include F, Cl, Br, and I. The number of carbon atoms of the alkyl group is, for example, 1 to 10. When a plurality of R²⁴ are present, the plurality of R²⁴ may be the same group or may be different groups.

In addition, in Formula (8-1), m13 is an integer of 0 to 4, preferably 0 to 3, and more preferably 0.

In the structure represented by Formula (8-1), the bonding positions of the isopropenyl group and the m₁₃ R²⁴ groups bonded to the benzene ring are not particularly limited.

The compound 1 can be, for example, a compound derived from a raw material compound having a benzene ring and a plurality of alkenyl groups (for example, isoalkenyl groups), or a compound derived from a precursor of the raw material compound. In addition, the raw material compound can be 1,3-diisoalkenylbenzene (for example, 1,3-diisopropenylbenzene) or 1.4-diisoalkenylbenzene (for example, 1,4-diisopropenylbenzene).

The compound 1 can be, for example, a resin (polymer) obtained by polymerizing a compound having a plurality of alkenyl groups (for example, a diisoalkenyl compound) in the presence of an acid catalyst at a specific reaction temperature. The compound having a plurality of alkenyl groups can be a compound produced by a known method. The diisoalkenyl compound can be produced, for example, by adding an alkene to an aromatic compound and subjecting the resulting compound to a dehydrogenation reaction. In addition, for example, a diisopropenyl compound can also be synthesized by intramolecular dehydration of a diol compound obtained by oxidizing a cumyl group and subjecting the oxidized product to hydrogenation.

The raw material compound (raw material monomer) for producing the compound 1 may be a precursor of a compound having a plurality of alkenyl groups (for example, a diisopropenyl compound precursor).

As described above, two or more kinds of the compound 1 may be used, and the mixing ratio of each compound can be appropriately set within a range in which the effects of the present disclosure can be obtained. In addition, the first composition may contain, for example, the compound 1 having an olefin structure at a terminal portion and another compound (for example, a compound having an olefin structure at a portion other than a terminal portion), or may contain two or more kinds of the compound 1 as described above.

When, for example, 1,3- or 1,4-diisopropenylbenzene is used as the raw material compound, the compound 1 can be a resin having at least one of the six structures shown below.

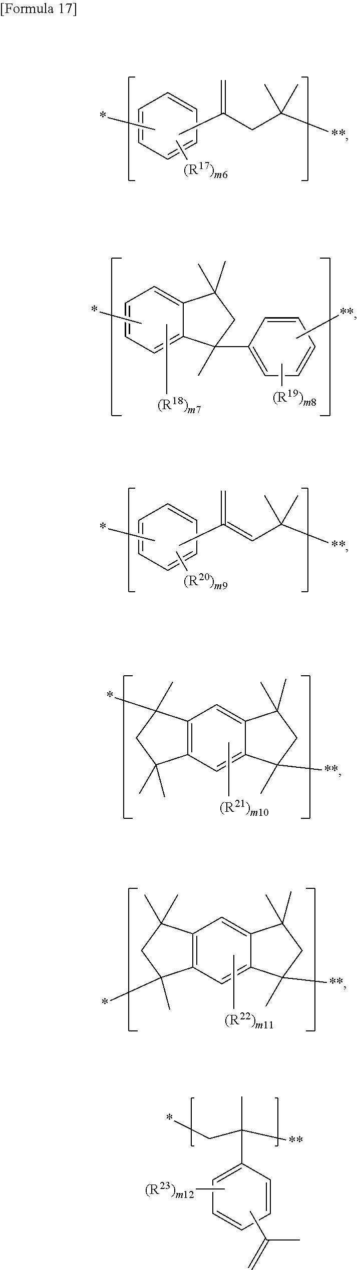

Here, R¹⁷ to R²³ each independently represent a C1-C10 hydrocarbon group or a halogenated alkyl group, m6, m8, m9, and m12 each independently represent an integer of 0 to 4, m7 represents an integer of 0 to 3, m10 and m11 each independently represent an integer of 0 to 2, and * and ** each represent a bonding position. R¹⁷ to R²³ may be the same group or may be different groups. From the viewpoint of electrical properties, R¹⁷ to R²³ are preferably a C1-C5 hydrocarbon group, and more preferably a C1-C3 hydrocarbon group. Examples of the C1-C10 hydrocarbon group include a methyl group, an ethyl group, an n-propyl group, an isopropyl group, an isopropenyl group, a t-butyl group, and an n-butyl group. The halogenated alkyl group is a group in which a hydrogen atom of an alkyl group is substituted with a halogen atom, and examples of the halogen atom include F, Cl, Br, and I. The number of carbon atoms of the alkyl group is, for example, 1 to 10.
m6, m8, m9, and m12 are real numbers of 0 to 4, preferably 0 to 3, and more preferably 0.
m7 is an integer of 0 to 3, preferably 0 to 2, and more preferably 0.
m10 and m11 are real numbers of 0 to 2, preferably 0 to 1, and more preferably 0.

In the six structures, the bonding positions of bonding groups such as R¹⁷ to R²³ and isopropenyl groups bonded to the benzene ring structure are not particularly limited.

In Formula (8), the polymer chain represented by E can include at least one of the six structures described above. In addition, the polymer chain represented by E¹ in Formula (8-1) can also include at least one of the six structures described above.

The weight average molecular weight Mw of the compound 1 is preferably 2,500 or more, more preferably 5,000 or more, and still more preferably 10,000 or more, from the viewpoints of curability and heat resistance. In addition, the weight average molecular weight Mw of the compound 1 is preferably 500,000 or less, more preferably 200,000 or less, still more preferably 150,000 or less, and particularly preferably 100,000 or less, from the viewpoint of solvent solubility. The method for measuring the weight average molecular weight will be described below.

### Compound 2

The compound 2 has two or more structures (ether structures) represented by the following Formula (1) in the molecule and further has a heterocyclic structure.

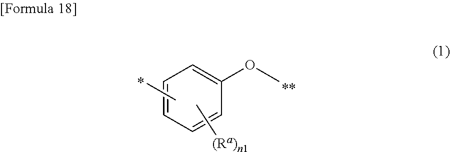

In Formula (1), each R^{a} is independently a hydroxyl group, a halogen group, a substituted or unsubstituted C6-C20 aromatic hydrocarbon group, a substituted or unsubstituted C1-C20 alkyl group, a substituted or unsubstituted C5-C20 cycloalkyl group, or a substituted or unsubstituted C7-C20 aralkyl group, n1 represents an integer of 0 to 4, and * and ** each represent a bonding position. In the compound 2, the bonding positions of bonding groups such as R^{a} bonded to the benzene ring in Formula (1) are not particularly limited, as long as the compound has the structure shown in (1).

Examples of the halogen group represented by R^{a} include —F, —Cl, —Br, and —I.

Examples of the C6-C20 aromatic hydrocarbon group (the total number of carbon atoms including the number of carbon atoms of the substituent), which may have a substituent, include monovalent aromatic hydrocarbon groups such as a phenyl group, a naphthyl group, and a biphenyl group. Examples of the substituent of the aromatic hydrocarbon group include alkyl groups such as a methyl group, an ethyl group, a propyl group, and a butyl group, a hydroxyl group, and a halogen group, but are not limited thereto.

Examples of the C1-C20 alkyl group (the total number of carbon atoms including the number of carbon atoms of the substituent), which may have a substituent. include linear or branched groups such as a methyl group, an ethyl group, a propyl group, a butyl group, a pentyl group, and a hexyl group. Examples of the substituent of the alkyl group include a hydroxyl group and a halogen group, but are not limited thereto.

Examples of the C5-C20 cycloalkyl group (the total number of carbon atoms including the number of carbon atoms of the substituent), which may have a substituent, include a cyclopentyl group and a cyclohexyl group. Examples of the substituent of the cycloalkyl group include alkyl groups such as a methyl group, an ethyl group, a propyl group, and a butyl group, a hydroxyl group, and a halogen group, but are not limited thereto.

Examples of the C7-C20 aralkyl group (the total number of carbon atoms including the number of carbon atoms of the substituent), which may have a substituent, include a phenylmethyl group, a phenylethyl group, a phenylpropyl group, and a diphenylmethyl group. Examples of the substituent of the aralkyl group include a hydroxyl group and a halogen group, but are not limited thereto.

In Formula (1), n1 is an integer of 0 to 4, preferably 0 to 3, and more preferably 0 or 1, from the viewpoint of achieving both polymerizability and heat resistance.

The compound 2 preferably has, as the structure represented by Formula (1), a structure represented by the following Formula (3).

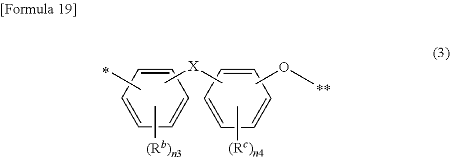

In Formula (3),
R^{b} and R^{c} are each independently a hydroxyl group, a halogen group, a substituted or unsubstituted C6-C20 aromatic hydrocarbon group, a substituted or unsubstituted C1-C20 alkyl group, a substituted or unsubstituted C5-C20 cycloalkyl group, or a substituted or unsubstituted C7-C20 aralkyl group,
n3 and n4 each independently represent an integer of 0 to 4,
X is a single bond, a substituted or unsubstituted C6-C20 aromatic hydrocarbon group, a substituted or unsubstituted C1-C20 alkylene group, a substituted or unsubstituted C5-C20 cycloalkylene group, a substituted or unsubstituted C1-C20 alkylidene group, a substituted or unsubstituted C5-C20 cycloalkylidene group, a substituted or unsubstituted C8-C20 aralkylene group, a substituted or unsubstituted C7-C20 aralkylidene group, or a group obtained by combining these groups, and
* and ** each represent a bonding position.

A halogen group, a substituted or unsubstituted C6-C20 aromatic hydrocarbon group, a substituted or unsubstituted C1-C20 alkyl group, a substituted or unsubstituted C5-C20 cycloalkyl group, and a substituted or unsubstituted C7-C20 aralkyl group, represented by R^{b} and Re, including preferred embodiments thereof, are the same as those described for Formula (1), and thus description thereof is omitted.

In Formula (3), n3 and n4 are real numbers of 0 to 4, and are preferably 0 to 3, and more preferably 0 or 1, from the viewpoint of heat resistance. In Formula (3), the bonding positions of bonding groups such as R^{b} and R^{c} bonded to the benzene ring are not particularly limited.

Examples of the C6-C20 aromatic hydrocarbon group represented by X (the total number of carbon atoms including the number of carbon atoms of the substituent), which may have a substituent, include divalent aromatic hydrocarbon groups such as a phenylene group, a naphthylene group, a biphenylene group, a divalent fluorene group (for example, a 9,9-fluorene group), and a divalent anthracene group. The aromatic hydrocarbon group may be a monocyclic aromatic hydrocarbon group or a polycyclic aromatic hydrocarbon group. Examples of the substituent of the aromatic hydrocarbon group include alkyl groups such as a methyl group, an ethyl group, a propyl group, and a butyl group, a hydroxyl group, and a halogen group, but are not limited thereto.

Examples of the C1-C20 alkylene group (the total number of carbon atoms including the number of carbon atoms of the substituent), which may have a substituent, include a methylene group, an ethylene group, an n-propylene group, an isopropylene group, an n-butylene group, and an isobutylene group. Examples of the substituent of the alkylene group include a hydroxyl group and a halogen group, but are not limited thereto.

Examples of the C5-C20 cycloalkylene group (the total number of carbon atoms including the number of carbon atoms of the substituent), which may have a substituent, include a cyclopentylene group and a cyclohexylene group. Examples of the substituent of the cycloalkylene group include alkyl groups such as a methyl group, an ethyl group, a propyl group, and a butyl group, a hydroxyl group, and a halogen group, but are not limited thereto. Examples of the cycloalkylene group having a substituent include a 3,3,5-trimethylcyclohexylene group.

Examples of the C1-C20 alkylidene group (the total number of carbon atoms including the number of carbon atoms of the substituent), which may have a substituent, include an ethylidene group and a hexylidene group. Examples of the substituent of the alkylidene group include a hydroxyl group and a halogen group, but are not limited thereto.

Examples of the C5-C20 cycloalkylidene group (the total number of carbon atoms including the number of carbon atoms of the substituent), which may have a substituent, include a cyclopentylidene group and a cyclohexylidene group. Examples of the substituent of the cycloalkylidene group include alkyl groups such as a methyl group, an ethyl group, a propyl group, and a butyl group, a hydroxyl group, and a halogen group, but are not limited thereto.

Examples of the C8-C20 aralkylene group (the total number of carbon atoms including the number of carbon atoms of the substituent), which may have a substituent, include a phenyldimethylene group, a naphthyldimethylene group, and a biphenyldimethylene group. Examples of the substituent of the aralkylene group include alkyl groups such as a methyl group, an ethyl group, a propyl group, and a butyl group, a hydroxyl group, and a halogen group, but are not limited thereto.

Examples of the C7-C20 aralkylidene group (the total number of carbon atoms including the number of carbon atoms of the substituent), which may have a substituent, include a phenylmethylidene group, a phenylethylidene group, and a phenylpropylidene group. Examples of the substituent of the aralkylidene group include alkyl groups such as a methyl group, an ethyl group, a propyl group, and a butyl group, a hydroxyl group, and a halogen group, but are not limited thereto.

Examples of the group represented by X formed by combining these groups include a divalent group obtained by combining at least two selected from the above-described aromatic hydrocarbon group, alkylene group, cycloalkylene group, alkylidene group, cycloalkylidene group, aralkylene group, and aralkylidene group. The bonding positions and arrangement of each group are not particularly limited and can be appropriately set.

The heterocyclic structure of the compound 2 is not particularly limited; however, it is preferably a heterocyclic structure containing a nitrogen atom, which may have a substituent, that is, a substituted or unsubstituted nitrogen-containing heterocyclic structure, and more preferably a substituted or unsubstituted nitrogen-containing heteroaromatic ring structure.

Examples of the heterocycle of the compound 2 include a pyrrole ring, a pyridine ring, a pyrimidine ring, a pyrazine ring, a pyridazine ring, a triazine ring, a quinoline ring, an isoquinoline ring, a quinoxaline ring, a phthalazine ring, a quinazoline ring, a naphthyridine ring, a carbazole ring, an acridine ring, and a phenazine ring. From the viewpoints of reactivity and solubility in various organic solvents, the heterocycle is preferably a pyrimidine ring or a triazine ring.

The bonding position of the heterocycle with another structure (for example, the structure represented by Formula (1) described above) is not particularly limited; however, when the heterocycle is bonded to two other structures, that is, when two bonding sites are present, the bonding sites are preferably at the meta positions from the viewpoint of reactivity.

Examples of the substituent of the heterocyclic structure include a halogen group, a C1-C20 hydrocarbon group, a C1-C20 halogenated hydrocarbon group, a group in which a part of these hydrocarbon groups or halogenated hydrocarbon groups is substituted with at least one atom selected from an oxygen atom and a sulfur atom, a nitro group, a cyano group, an amino group, and a salt of an amino group.

Examples of the halogen group as the substituent include —F, —Cl, —Br, and —I.

Examples of the C1-C20 hydrocarbon group as the substituent include a chain hydrocarbon group, an alicyclic hydrocarbon group, and an aromatic hydrocarbon group.

Examples of the chain hydrocarbon group include alkyl groups such as a methyl group, an ethyl group, an n-propyl group, an isopropyl group, an n-butyl group, an isobutyl group, a sec-butyl group, a tert-butyl group, and an n-pentyl group; alkenyl groups such as an ethenyl group, a propenyl group, a butenyl group, and a pentenyl group; and alkynyl groups such as an ethynyl group, a propynyl group, a butynyl group, and a pentynyl group.

Examples of the alicyclic hydrocarbon group include monocyclic cycloalkyl groups such as a cyclopropyl group, a cyclobutyl group, a cyclopentyl group, and a cyclohexyl group; polycyclic cycloalkyl groups such as a norbornyl group and an adamantyl group; monocyclic cycloalkenyl groups such as a cyclopropenyl group, a cyclobutenyl group, a cyclopentenyl group, and a cyclohexenyl group; and polycyclic cycloalkenyl groups such as a norbornenyl group.

Examples of the aromatic hydrocarbon group include aryl groups such as a phenyl group, a tolyl group, a xylyl group, a naphthyl group, and an anthryl group; and aralkyl groups such as a benzyl group, a phenethyl group, a phenylpropyl group, and a naphthylmethyl group.

Examples of the C1-C20 halogenated hydrocarbon group as the substituent include a group in which a part or all of hydrogen atoms of the C1-C20 hydrocarbon group are substituted with halogen atoms such as a fluorine atom, a chlorine atom, a bromine atom, or an iodine atom.

Examples of the group in which a part of the substituent that is a C1-C20 hydrocarbon group or a C1-C20 halogenated hydrocarbon group is substituted with at least one selected from an oxygen atom and a sulfur atom include a group in which a part of the hydrocarbon group or the halogenated hydrocarbon group is substituted with —O—, —S—, an ester group, or a sulfonyl group.

The amino group as the substituent is not particularly limited, and may be a primary amino group (—NH₂), a secondary amino group (—NHR), or a tertiary amino group (—NR₂).

The substituent (R) in the secondary amino group and the tertiary amino group is not particularly limited, and examples thereof include the above-described C1-C20 hydrocarbon groups.

The anion constituting the anionic moiety of the salt of the amino group is not particularly limited, and examples thereof include known anions such as Cl⁻.

From the viewpoints of reactivity and solubility, the substituents on the heterocyclic structure are preferably a halogen group, a C1-C6 hydrocarbon group, a C1-C6 halogenated hydrocarbon group, a nitro group, a cyano group, an amino group, or a salt of an amino group, and more preferably a fluorine atom, a chlorine atom, a methyl group, a nitro group, a cyano group, a tert-butyl group, a phenyl group, and a primary amino group.

From the viewpoints of heat resistance and electrical properties, the heterocyclic structure is preferably a structure selected from the structures represented by the following Formulas (4) to (6), and more preferably a structure represented by Formula (4).

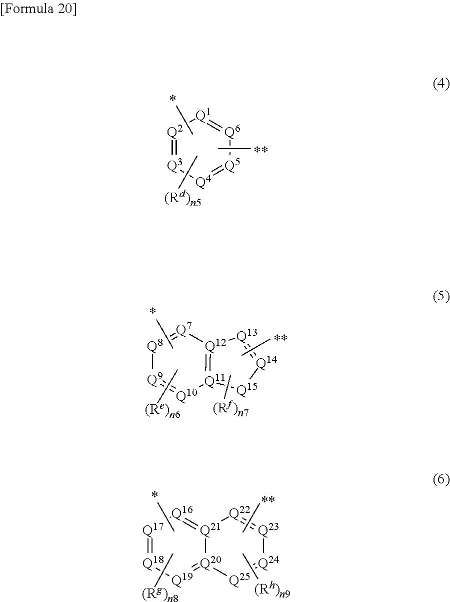

In Formulas (4) to (6),
R^{d} to R^{h} are each independently a substituted or unsubstituted C1-C20 alkyl group or a substituted or unsubstituted C6-C20 aromatic hydrocarbon group,
n5 represents an integer of 0 to 4,
n6, n8, and n9 each independently represent an integer of 0 to 3,
n7 represents an integer of 0 to 2,
Q¹ to Q²⁵ are each independently a nitrogen atom or a carbon atom, provided that at least one of Q¹ to Q⁶ is a nitrogen atom, at least one of Q⁷ to Q¹⁵ is a nitrogen atom, at least one of Q¹⁶ to Q²⁵ is a nitrogen atom, and when at least one of Q¹ and Q¹² is a nitrogen atom, the bond between Q¹¹ and Q², and the bond between Q⁷ and Q¹² and the bond between Q¹² and Q¹³, or the bond between Q¹⁰ and Q¹¹ and the bond between Q¹¹ and Q¹², are single bonds, and when at least one of Q²⁰ and Q²¹ is a nitrogen atom, the bond between Q²⁰ and Q²¹, and the bond between Q¹⁶ and Q²¹ and the bond between Q²¹ and Q²², or the bond between Q¹¹ and Q²⁰ and the bond between Q²⁰ and Q²⁵, are single bonds, and
* and ** are each a bonding position.

Examples of the C1-C20 alkyl groups represented by R^{d} to R^{h} include a methyl group, an ethyl group, an n-propyl group an isopropyl group, an n-butyl group, an isobutyl group, a sec-butyl group, a tert-butyl group, and an n-pentyl group.

Examples of the C6-C20 aromatic hydrocarbon groups represented by R^{d} to R^{h} include aryl groups such as a phenyl group, a tolyl group, a xylyl group, a naphthyl group, and an anthryl group; and aralkyl groups such as a benzyl group, a phenethyl group, a phenylpropyl group, and a naphthylmethyl group.

Examples of substituents that the alkyl group and the aromatic hydrocarbon group represented by R^{d} to R^{h} may have include those same as the substituents of the heterocyclic structure described above.

n5 is an integer of 0 to 4, and is preferably 0 to 3, and more preferably 0 to 2, from the viewpoint of polymerizability.

n6, n8, and n9 are each independently an integer of 0 to 3, and are preferably 0 to 2, and more preferably 0 or 1, from the viewpoint of polymerizability.

n7 is an integer of 0 to 2, and is preferably 0 or 1 from the viewpoint of polymerizability.

In Formulas (4) to (6), the bonding positions of bonding groups such as R^{d}to R^{h} bonded to the cyclic structure are not particularly limited.

As described above, in the heterocyclic structures represented by Formulas (4) to (6), the arrangement of nitrogen atoms is not particularly limited, and accordingly, the positions of double bonds in the ring structure can be appropriately selected and are not particularly limited.

The compound 2 can be represented by, for example, structures represented by the following Formulas (2) and (20).

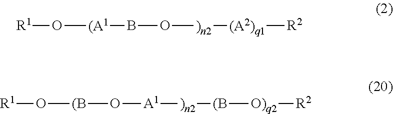

In Formulas (2) and (20),
R¹ and R² are each independently a C2-C50 group containing an ethylenically unsaturated double bond, a substituted or unsubstituted C6-C50 aromatic hydrocarbon group, a substituted or unsubstituted C6-C50 aliphatic hydrocarbon group, or a substituted or unsubstituted nitrogen-containing heteroaromatic ring,
A¹ and A² are each independently a group having a structure represented by Formula (1) (or a group having a structure represented by Formula (3)), provided that, in Formula (2), ** in Formula (1) (and Formula (3)) represents a bonding position with B or R², and in Formula (20), ** in Formula (1) (and Formula (3)) represents a bonding position with B or R
each B is independently a divalent group having a nitrogen-containing heterocyclic structure,
each n2 is independently an integer of 1 or more,
q1 is 0 or 1, and when q1 is 0, (A²)_{q1} represents a single bond, and
q2 is 0 or 1, and when q2 is 0, (B—O)_{q2} represents a single bond.

Examples of the C2-C50 group containing an ethylenically unsaturated double bond represented by R¹ and R² include aromatic ring-containing groups such as a 3-isopropenylphenyl group, a 4-isopropenylphenyl group, a 2-allylphenyl group, a 2-methoxy-4-allylphenyl group, a 4-(1-propenyl)-2-methoxyphenyl group, a 3-isopropenylbenzyl group, a 4-isopropenylbenzyl group, a 4-vinylbenzyl group, a 3-vinylbenzyl group, and a 2-vinylbenzyl group, an allyl group, an acryloyl group, a methacryloyl group, and a methallyl group.

Examples of the C6-C50 aromatic hydrocarbon group include aryl groups such as a phenyl group, a biphenyl group, a tolyl group, a xylyl group, a naphthyl group, and an anthryl group; and aralkyl groups such as a benzyl group, a phenethyl group, a phenylpropyl group, and a naphthylmethyl group.

Examples of the C6-C50 aliphatic hydrocarbon group include monocyclic cycloalkyl groups such as a cyclopropyl group, a cyclobutyl group, a cyclopentyl group, and a cyclohexyl group; polycyclic cycloalkyl groups such as a norbornyl group and an adamantyl group; monocyclic cycloalkenyl groups such as a cyclopropenyl group, a cyclobutenyl group, a cyclopentenyl group, and a cyclohexenyl group; and polycyclic cycloalkenyl groups such as a norbornenyl group.

Examples of the nitrogen-containing heteroaromatic ring include the same rings as those exemplified in the heterocyclic structures described above.

Examples of substituents that R¹ and R² may have include groups other than a hydroxyl group, and specific examples thereof include an allyl group, a halogen group, a C1-C20 hydrocarbon group, a C1-C20 halogenated hydrocarbon group, a C1-C20 alkoxy group, a C1-C20 alkylthio group, a nitro group, a cyano group, a carboxy group, a sulfonic acid group, a phosphonic acid group, a phosphoric acid group, a hydroxyl group, a primary to tertiary amino group, a salt of a carboxy group, a salt of a sulfonic acid group, a salt of a phosphonic acid group, a salt of a phosphoric acid group, a salt of a hydroxyl group, or a salt of a primary to tertiary amino group. Among these, an allyl group is preferable.

Examples of the halogen group, the C1-C20 hydrocarbon group, and the C1-C20 halogenated hydrocarbon group as the substituent include the same groups as those exemplified for the substituents of the heterocyclic structure described above.

Examples of the C1-C20 alkoxy group include a methoxy group, an ethoxy group, an n-propoxy group, an isopropoxy group, a butoxy group, a pentyloxy group, a hexyloxy group, and an octyloxy group.

Examples of the C1-C20 alkylthio group include a methylthio group, an ethylthio group, an n-propylthio group, an isopropylthio group, a butylthio group, a pentylthio group, a hexylthio group, and an octylthio group.

The substituent (R) in the secondary amino group (—NHR) and the tertiary amino group (—NR₂) is not particularly limited, and examples thereof include a C1-C20 hydrocarbon group. Specific examples thereof include the same groups as those exemplified as substituents of the heterocyclic structure described above.

The cation constituting the cationic moiety of a salt of a carboxy group, a salt of a sulfonic acid group, a salt of a phosphonic acid group, a salt of a phosphoric acid group, and a salt of a hydroxyl group is not particularly limited, and examples thereof include known cations such as Na

The anion constituting the anionic moiety of the salt of the amino group is not particularly limited, and examples thereof include known anions such as Cl⁻.

The group represented by A¹ and A² and having the structure represented by Formula (1) is preferably the group represented by Formula (3) described above. In this case, in Formula (2), * in Formula (3) represents a bonding position with O, and ** represents a bonding position with B or R². Similarly, in the case of Formula (20), * in Formula (3) represents a bonding position with 0, and ** represents a bonding position with B or R

In addition, the divalent group having a nitrogen-containing heterocyclic structure represented by B is preferably a group selected from the structures represented by Formulas (4) to (6) described above. In this case, * and ** in Formulas (4) to (6) each represent a bonding position with A¹ or 0 in Formula (2), and a bonding position with 0 or A¹ in Formula (20).

n2 is an integer of 1 or more, for example, an integer of 1 to 100.

In addition, the compound 2 is preferably a compound represented by the following Formula (7),

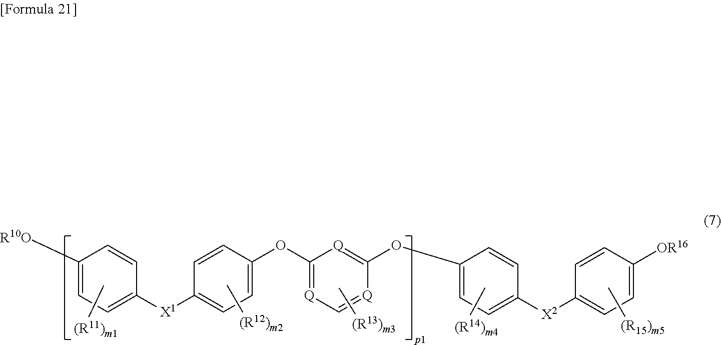

In Formula (7),
R¹⁰ and R¹⁶ are each independently a C2-C50 group containing an ethylenically unsaturated double bond, a substituted or unsubstituted C6-C50 aromatic hydrocarbon group. a substituted or unsubstituted C6-C50 aliphatic hydrocarbon group, or a substituted or unsubstituted nitrogen-containing heteroaromatic ring,
R¹¹, R¹², R¹⁴, and R¹⁵ are each independently a hydroxyl group, a halogen group, a substituted or unsubstituted C6-C20 aromatic hydrocarbon group, a substituted or unsubstituted C1-C20 alkyl group, a substituted or unsubstituted C5-C20 cycloalkyl group, or a substituted or unsubstituted C7-C20 aralkyl group,
each R¹³ is independently a substituted or unsubstituted C1-C20 alkyl group or a substituted or unsubstituted C6-C20 aromatic hydrocarbon group,
X¹ and X² are each independently a single bond, a substituted or unsubstituted C6-C20 aromatic hydrocarbon group, a substituted or unsubstituted C1-C20 alkylene group, a substituted or unsubstituted C5-C20 cycloalkylene group, a substituted or unsubstituted C1-C20 alkylidene group, a substituted or unsubstituted C5-C20 cycloalkylidene group, a substituted or unsubstituted C8-C20 aralkylene group, a substituted or unsubstituted C7-C20 aralkylidene group, or a group obtained by combining these groups,
each Q is independently a nitrogen atom or a carbon atom, provided that at least two of Q are nitrogen atoms, and
m1, m2, m4, and m5 are real numbers of 0 to 4, preferably 0 to 2, and more preferably 0 or 1, from the viewpoints of polymerizability and heat resistance.
m3 is an integer of 0 to 2, and is preferably 0 or 1, from the viewpoints of polymerizability and heat resistance.
p1 is an integer of 1 or more, for example, an integer of 1 to 100.

Each structure represented by R¹⁰ and R¹⁶ is the same as R¹ and R² in Formula (2) described above, and preferred embodiments thereof are also the same. In addition, each structure represented by R¹¹, R¹², R¹⁴, and R¹⁵ is the same as R^{b} and R^{c} in Formula (3) described above, and preferred embodiments thereof are also the same. Furthermore, each structure represented by R¹³ is the same as R^{d} to R^{h} in Formulas (4) to (6) described above, and preferred embodiments thereof are also the same. In addition, each structure represented by X¹ and X² is the same as X in Formula (3) described above, and preferred embodiments thereof are also the same.

In addition, the compound 2 is particularly preferably a compound represented by the following Formula (7A)

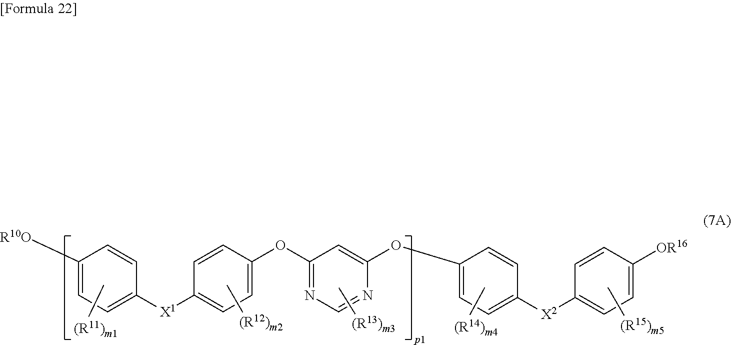

In Formula (7A),
R¹⁰ to R¹⁶, X¹ and X², m1 to in m5, and p1 are the same as those shown in Formula (7) described above, and preferred embodiments thereof are also the same.

The weight average molecular weight Mw of the compound 2 is preferably 1,000 or more from the viewpoints of electrical properties, heat resistance, polymerizability, and the like. In addition, the weight average molecular weight Mw of the compound 2 is preferably 500,000 or less, more preferably 100,000 or less, still more preferably 50,000 or less, and particularly preferably 10,000 or less, from the viewpoint of solubility in solvents.

### (Other Components)

The first composition can further contain additives such as other curable resins, crosslinking agents, flame retardants, fillers, and elastomers. In addition, the first composition may also contain a polymerization initiator such as dicumyl peroxide, 2,3-dimethyl-2,3-diphenylbutane (CCDFB), or an azo initiator.

The first composition can be used in combination with other curable resins (for example, resins containing a radical-polymerizable group) as necessary. As the other curable resins, known resins can be appropriately used, and examples thereof include ODV, modified polyphenylene ether (PPE) resins, soluble divinylbenzene polymers, vinylbenzyl ether resins, maleimide resins, and curable resins having a heterocyclic ether bond such as a triazine ether in the main chain. Examples of the modified PPE resins include, for example. trade name: Noryl (registered trademark) SA-9000, manufactured by SABIC Innovative Plastics. The radical-polymerizable group may be any group that enables radical polymerization, and may be a group containing an unsaturated double bond or an unsaturated triple bond. Examples of the radical-polymerizable group include a vinyl group, a vinylidene group, a vinylene group, an ethynyl group, an allyl group, an isopropenyl group, a 1-butenyl group, a 2-butenyl group, an acryloyl group, a methacryloyl group, a fumaroyl group, a maleoyl group, an acryloyloxy group, a methacryloyloxy group, a vinylphenyl group, a fluorovinyl group, a vinyl ether group, an allyl ether group, a styryl group, a vinylnaphthyl group, a norbornyl group, a cinnamoyl group, and a maleimide group (a 2,5-dihydro-2,5-dioxo-1H-pyrrol-1-yl group).

By curing the first composition with a crosslinking agent added thereto, a cured composition with excellent properties can be obtained.

Examples of the crosslinking agent include compounds having, in the molecule, reactive functional groups such as a styryl group (St group), a maleimide group, an allyl group, and a (meth)acryloyl group. From the viewpoint of reactivity with the first composition, the reactive functional group is preferably a styryl group. More specifically, from the viewpoint of electrical properties, the crosslinking agent is preferably 1,2-bis(vinylphenyl)ethane (BVPE), a fluorene compound having a vinylbenzyl group described in Japanese Patent No. 3681170, an indene compound having a vinylbenzyl group, vinyl compounds such as divinylbenzene, and the like, and more preferably BVPE. The crosslinking agent may be a mixture of two or more kinds or a compound having a repeating unit (polymer), and a vinyl compound represented by the following Formula (9), a vinyl compound represented by the following Formula (10), or a compound having a vinylbenzyl ether group can be used.

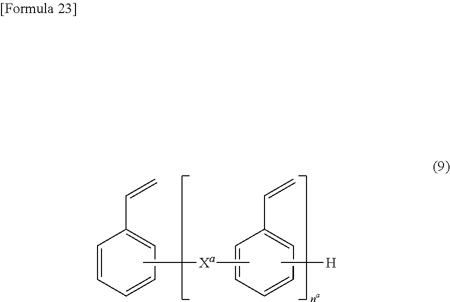

In Formula (9), X^{a} represents a hydrocarbon group having 6 or more carbon atoms and containing at least one selected from an aromatic cyclic group and an aliphatic cyclic group, and n^{a} represents an integer of 1 to 10.

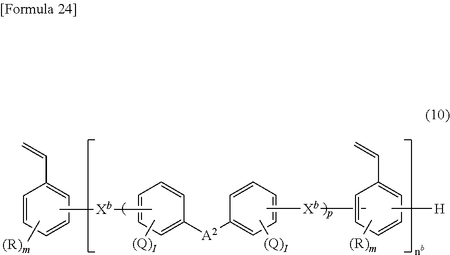

In Formula (10), X^{b} represents one or more selected from (a) to (h) described in the following Formula (11). Here, when a plurality of X^{b} are present, the plurality of X^{b} may be the same as or different from each other. A² represents a methylene group or an oxygen atom, and Q represents a C1-C10 hydrocarbon group or a halogenated alkyl group. The plurality of Q may be the same as or different from each other. R represents a C1-C10 hydrocarbon group or a halogenated alkyl group. When a plurality of R are present, the plurality of R may be the same as or different from each other. l and m each represent an integer of 0 to 3, n^{b} represents a repeating unit and satisfies 1≤n^{b}≤20, and p represents a repeating unit and satisfies 1.1≤p≤20.

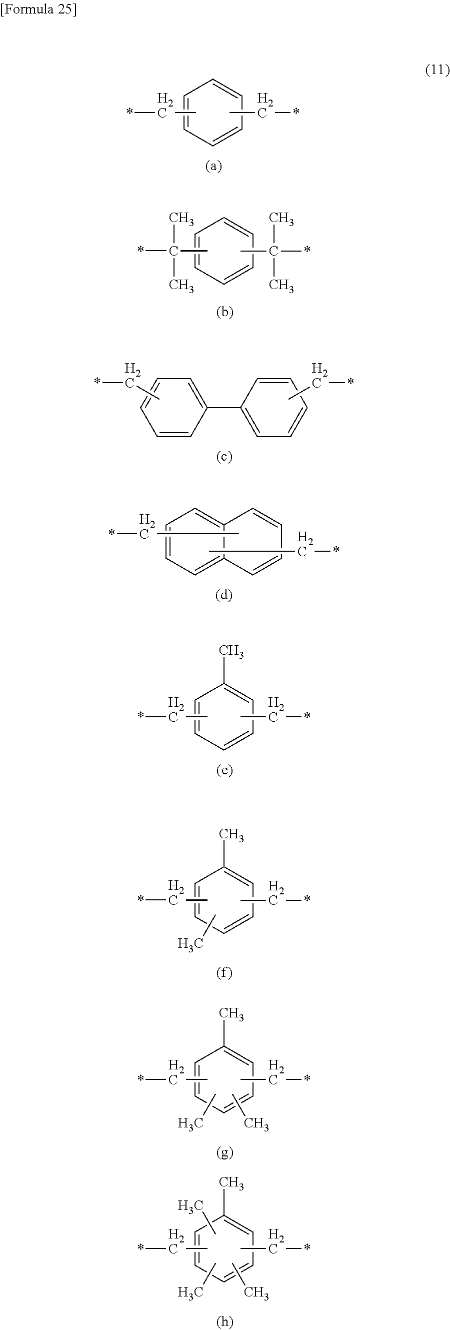

In Formula (11), each * represents a bonding position.

A compound having a vinylbenzyl ether group can be synthesized, for example, by reacting a phenolic resin such as a biphenyl aralkyl-type phenol, an aralkyl phenol, or a naphthol aralkyl resin with chloromethylstyrene in the presence of an alkaline catalyst.

Examples of the crosslinking agent include a compound obtained by reacting a compound having fluorene or indene as a partial skeleton with a halogenated compound having a styryl group (St group), such as chloromethylstyrene, in the presence of an alkaline catalyst. In the reaction, a phase-transfer catalyst may be used, and the solvent is preferably a non-protic organic solvent or a solvent containing a non-protic organic catalyst. More specifically, examples of the crosslinking agent include a compound represented by the following Formula (12), which is obtained by reacting a compound having fluorene as a partial skeleton with chloromethylstyrene.

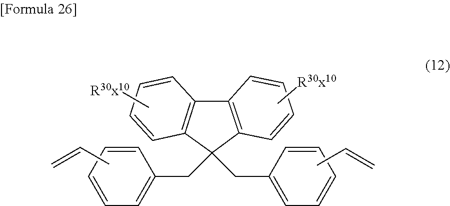

In Formula (12), R³⁰ represents a hydrogen atom, a C1-C10 hydrocarbon group, or a halogenated alkyl group, and X¹⁰ represents an integer of 0 to 4.

In addition, as the crosslinking agent, trialkenyl isocyanurate compounds such as triallyl isocyanurate (TAIC), polyfunctional methacrylate compounds having two or more methacryloyl groups in the molecule, polyfunctional acrylate compounds having two or more acryloyl groups in the molecule, vinyl compounds having two or more vinyl groups in the molecule (polyfunctional vinyl compounds) such as polybutadiene and styrene-butadiene copolymers, polyfunctional aromatic copolymers obtained by copolymerizing divinylbenzene with a styrene derivative, and vinylbenzyl compounds such as styrene and divinylbenzene having a vinylbenzyl group in the molecule may be used. Among these, those having two or more carbon-carbon double bonds in the molecule are preferable. Specific examples thereof include a trialkenyl isocyanurate compound, a polyfunctional acrylate compound, a polyfunctional methacrylate compound, a polyfunctional aromatic copolymer, and a divinylbenzene compound. By using these compounds, it is considered that crosslinking is more suitably formed by a curing reaction, and the heat resistance of a cured product of the first composition can be further enhanced. In addition, the exemplified crosslinking agents may be used alone, or two or more kinds thereof may be used in combination. In addition, as the crosslinking agent, a compound having two or more carbon-carbon unsaturated double bonds in the molecule may be used in combination with a compound having one carbon-carbon unsaturated double bond in the molecule. Specific examples of the compound having one carbon-carbon unsaturated double bond in the molecule include compounds having one vinyl group in the molecule (monovinyl compounds).

The average number of carbon-carbon unsaturated double bonds per molecule of the crosslinking agent (number of terminal double bonds) varies depending on the weight average molecular weight of the crosslinking agent; however, from the viewpoint of heat resistance of the cured product, it is preferably 1 or more, and more preferably 2 or more. In addition, the number of terminal double bonds per molecule of the crosslinking agent is preferably 20 or less, and more preferably 18 or less, from the viewpoints of reactivity, storage stability of the composition, and fluidity.

Considering the weight average molecular weight of the crosslinking agent, when the weight average molecular weight of the crosslinking agent is less than 500 (for example, 100 or more and less than 500), the number of terminal double bonds of the crosslinking agent is preferably 1 to 4. In addition, when the weight average molecular weight of the crosslinking agent is 500 or more (for example, 500 or more and 5,000 or less), the number of terminal double bonds of the crosslinking agent is preferably 3 to 20. In each case, when the number of terminal double bonds is equal to or greater than the lower limit of the above range, the crosslinking agent tends to have excellent reactivity, an appropriate crosslinking density is easily imparted to a cured product of the resin composition, and heat resistance and Tg can be readily improved. On the other hand, when the number of terminal double bonds is equal to or less than the upper limit of the above range, gelation of the composition can be easily prevented.

The number of terminal double bonds of the crosslinking agent can be determined from the product specification values of the crosslinking agent used. As used herein, the number of terminal double bonds refers to a value representing the average number of double bonds per molecule of the crosslinking agent, calculated for all crosslinking agent molecules present in one mole of the crosslinking agent.

Examples of the flame retardant include a halogen-based flame retardant such as a bromine-based flame retardant, and a phosphorus-based flame retardant. The flame retardant may be used alone, or two or more kinds thereof may be used in combination.

As the filler, silica, hollow silica, or the like can be used. From the viewpoint of dielectric properties, the filler preferably has a small amount of silanol groups. In addition, when silica is hollow, a composition having a low dielectric constant can be obtained. Silica having a surface subjected to a modification treatment can also be used. Specifically, silica subjected to a treatment with a functional group containing a carbon-carbon unsaturated double bond and/or to a trimethylsilylation treatment can be used.

Examples of the elastomer include styrene-based elastomers, and usable examples thereof include a styrene-butadiene-styrene copolymer, a hydrogenated styrene-butadiene-styrene copolymer, a styrene-isoprene-styrene copolymer, a hydrogenated styrene-isoprene-styrene copolymer, and a hydrogenated styrene-(butadiene/isoprene)-styrene copolymer.

In addition to the above, the first composition can further contain, as necessary, acenaphthylene and indene, derivatives thereof, and known maleimide compounds. The mixing ratio of these components can be set to 75 mass % or less with respect to the first composition.

Furthermore, the first composition may contain a fluororesin. From the viewpoint of improving adhesion, the fluororesin may have a functional group.

The content ratio of the compound 1 with respect to the total content of the compound 1 and the compound 2 in the first composition is preferably 10 to 99 mass %. When the content ratio of the compound 1 is 10 mass % or more, excellent electrical properties can be readily imparted. In addition, when the content ratio of the compound 1 is 99 mass % or less, excellent heat resistance can be readily imparted. From the same viewpoint, the content ratio of the compound 1 with respect to the total content of the compound 1 and the compound 2 in the first composition is more preferably from 30 to 99 mass %, and particularly preferably from 50 to 99 mass %.

The dielectric loss tangent Df of the first composition at a temperature of 25° C. and a measurement frequency of 10 GHz is preferably 0.0003 to 0.0009, and more preferably 0.0003 to 0.0007, from the viewpoint of practical application. The method for measuring the dielectric loss tangent will be described below.

The dielectric constant Dk of the first composition at a temperature of 25° C. and a measurement frequency of 10 GHz is preferably 2.3 to 3.0, and more preferably 2.3 to 2.6, from the viewpoint of practical application. The method for measuring the dielectric constant will be described below.

In the present specification, the glass transition temperature (Tg) (of a cured product) refers to the glass transition temperature of a cured product obtained by curing the composition according to the present disclosure. The cured product exhibits an excellent glass transition temperature and exhibits preferred heat resistance. The glass transition temperature of the cured product is preferably 110° C. or higher, more preferably 115° C. or higher, and still more preferably 120° C. or higher. The glass transition temperature is preferably 250° C. or lower, and more preferably 240° C. or lower. In addition, the method for measuring the glass transition temperature will be described below.

The first composition exhibits the above-described glass transition temperature even when thermally cured at a thermosetting temperature used in producing a substrate material such as a prepreg. The thermosetting temperature is at most 250° C., for example, 150 to 230° C.

### <Method for Producing Compound 1>

A method for producing a compound 1 having an olefin structure at a terminal portion is a method in which the compound 1 can be obtained, for example, by polymerizing a compound having a plurality of isoalkenyl groups (for example, a diisopropenyl compound) at a reaction temperature of 10 to 75° C. in the presence of an acid catalyst.

Here, the compound having a plurality of isoalkenyl groups is a compound having two or more isoalkenyl groups in one molecule. As the compound, as described above, a compound produced by a conventionally known method can be used, and for example, diisopropenylbenzene compounds such as 1,3-diisopropenylbenzene and 1,4-diisopropenylbenzene can be used. In addition, as such a compound, a precursor thereof (for example, α,α,α′,α′-tetramethyl-1,3-benzenedimethanol) can also be used.

In the present production method, another compound may be copolymerized together with the compound having a plurality of isoalkenyl groups. That is, the compound 1 may be a homopolymer of the compound having a plurality of isoalkenyl groups, or may be a copolymer obtained by using a plurality of compounds including the compound.

Examples of the other compound include a monovinyl compound and a divinyl compound. More specifically, as the other compound, a-methylstyrene, an a-methylstyrene dimer, α-olefin compounds such as diphenylethylene, a monoisopropenyl compound, a cyclic diene, or the like can be used. For example, the monoisoalkenyl compound can be used as a terminator that terminates the propagation reaction.

In addition, from the viewpoints of physical property adjustment and molecular weight control by functional group introduction, structures such as a phenol structure, an aromatic amine structure, an aromatic ether structure, and a maleimide structure may be introduced into the compound 1. When introducing such structures, these structures are preferably introduced into the structure by utilizing an electrophilic substitution reaction by a cation generated from an isoalkenyl group of a raw material during the polymerization reaction.

The water content in the raw materials for obtaining the compound 1, such as monomers, is preferably 500 ppm or less from the viewpoint of reactivity. If necessary, dehydration treatment of the raw materials can be performed using a molecular sieve, alumina, or the like.

Examples of the acid catalyst used in the polymerization reaction include the inorganic acids, solid acids, organic sulfonic acids, Lewis acids, and Brønsted acids shown below. One acid may correspond to a plurality of kinds among inorganic acids, solid acids, organic sulfonic acids, Lewis acids, and Brønsted acids.

Inorganic acids: for example, sulfuric acid, nitric acid, hydrochloric acid, and phosphoric acid

Solid acid: for example, activated clay, acid clay, silica alumina, zeolite, sulfonated carbon, strongly acidic ion-exchange resins, heteropoly acids, and tungstic acid.

Organic sulfonic acids: for example, benzenesulfonic acid, toluenesulfonic acid, xylenesulfonic acid, methanesulfonic acid, fluoromethanesulfonic acid, and perfluoroalkanesulfonic acids such as CF₃SO₃H, C₂F₅SO₃H, and C₆F₅SO₃H Lewis acids: for example, AlCl₃, TiCl₄, SnCl₄, B(C₆F₅)₃, BF₃, and complexes thereof with Lewis bases, methylaluminoxane, metallocene halides and combinations thereof with methylaluminoxane, and combinations thereof

Brønsted acids: for example boric acid, acetic acid, and benzoic acid

As the Lewis base that acts as a cocatalyst component, for example, one or more selected from the group consisting of an ester-based compound, a thioester-based compound, a ketone-based compound, an amine-based compound, an ether-based compound, a thioether-based compound, and a phosphine-based compound can be used.

Ester-based compound: for example, ethyl acetate, propyl acetate, isopropyl acetate, butyl acetate, phenyl acetate, methyl propionate, dimethyl carbonate, diethyl carbonate, and ethylene carbonate

Thioester-based compound: for example, methyl mercaptopropionate and ethyl mercaptopropionate

Ketone-based compound: for example, methyl ethyl ketone, methyl isobutyl ketone, and benzophenone

Amine-based compound: for example, methylamine, ethylamine, propylamine, butylamine, cyclohexylamine, methylethylamine, dimethylamine, diethylamine, dipropylamine, and dibutylamine

Ether-based compound: for example, diethyl ether, methyl tert-butyl ether, diethylene glycol dimethyl ether, propylene glycol dimethyl ether, tetrahydrofuran, and cyclopentyl methyl ether

Thioether-based compound: for example, diethyl sulfide and diphenyl sulfide

Phosphine-based compound: for example, tripropylphosphine, tributylphosphine, trihexylphosphine, tricyclohexylphosphine, trioctylphosphine, vinylphosphine, propenylphosphine, cyclohexenylphosphine, dialkenylphosphine, and trialkenylphosphine

In the present production method, from the viewpoint of being easy to control the structure to be generated and the molecular weight, it is preferable to use a combination (mixture) of one or more selected from the ester-based compound, the ketone-based compound, and the ether-based compound described above, and one or more selected from the acid catalysts described above. Here, examples of the acid catalyst include the Brønsted acids, Lewis acids, organic sulfonic acids, and inorganic acids described above. In addition, from the same viewpoint, as the acid catalyst, it is also preferable to use one selected from the group consisting of methanesulfonic acid, a BF₃ complex, tin chloride, and toluenesulfonic acid.

The amount of the cocatalyst with respect to the acid catalyst is not particularly limited because it may vary depending on reaction conditions; however, the amount of the cocatalyst is preferably 1 mol or more with respect to 1 mol of the acid catalyst.

For example, a catalyst mixture of a Lewis acid (for example, BF₃·O(C₂H₅)₂) and a Lewis base (for example, isopropyl acetate) can be used as the acid catalyst.

The polymerization reaction can be performed in a solvent. Examples of the solvent include the following solvents. Nonpolar organic solvents such as hexane, decane, dodecane, cyclohexane, benzene, toluene, o-xylene, m-xylene, p-xylene, ethylbenzene, and trimethylbenzene; chlorine-based organic solvents such as methylene chloride, chloroform, carbon tetrachloride, 1,2-dichloroethane, trichloroethane, and perchloroethane. Aromatic compounds such as halogenated benzene, nitrobenzene, and trifluoromethylbenzene. In addition to the solvents, the ester-based compound, the ketone-based compound, and the ether-based compound described above can also be used as the solvent.

In the present production method, the reaction temperature in the polymerization reaction is preferably 10 to 75° C. When the reaction temperature is 10° C. or higher, the reaction is completed within an appropriate period of time. In addition, when the reaction temperature is 75° C. or lower, the structure to be formed can be easily controlled.

In the present production method, the solution containing the polymer after termination of the polymerization reaction can be purified by a known method to obtain a target product (compound 1). Examples of the purification method include a method in which a water-soluble compound is washed with water and removed by liquid separation, a method in which a low-boiling compound such as a solvent is distilled off under reduced pressure, and a method in which reprecipitation is performed by mixing with a poor solvent.

The obtained polymer can be further purified by a known method to increase the purity. Examples of the purification method include a method of repeating redissolution and reprecipitation, washing with a poor solvent, drying under reduced pressure, and adsorption treatment using a cation-exchange adsorbent or an anion-exchange adsorbent.

The compound 1 can be obtained through the above operations. Different curable functional groups such as a hydroxyl group and an amino group can be introduced into the compound 1 to produce a cured product with a phenolic resin, an epoxy resin, a polyimide resin, or the like, or the compound 1 can be modified and used as a maleimide resin or a benzoxazine resin.

### Method for Producing Compound 2

A method for producing a compound 2 is not particularly limited, and a known method can be appropriately used. For example, when the compound 2 is represented by the structure shown in Formula (2) described above, the compound 2 can be synthesized by heating, in an organic solvent, a monomer serving as a raw material for a portion including A¹ in Formula (2), a monomer serving as a raw material for a portion including A², a monomer serving as a raw material for a portion including B, a monomer serving as a raw material for a portion including R¹, a monomer serving as a raw material for a portion including R², and, as necessary, another monomer, in the presence of an alkali metal, an alkali metal compound, or the like. The monomer serving as a raw material for a portion including A¹ and the monomer serving as a raw material for a portion including A² may be the same monomer or may be different monomers. In addition, the monomer serving as a raw material for a portion including R¹ and the monomer serving as a raw material for a portion including R² may be the same monomer or may be different monomers. For example, after polymerizing the monomer serving as a raw material for a portion including A¹ and the monomer serving as a raw material for a portion including B, a monomer serving as a raw material for a portion including Rr or R² and/or another monomer may be added and reacted by heating and mixing.

Examples of the monomer serving as a raw material for a portion including A¹ or A² include dihydroxyphenyl compounds such as hydroquinone, resorcinol, catechol, and phenylhydroquinone; bisphenol compounds such as 9,9-bis(4-hydroxyphenyl)fluorene, 9,9-bis(4-hydroxy-3-methylphenyl)fluorene, 9,9-bis(4-hydroxy-3-phenylphenyl)fluorene, 1,1-bis(4-hydroxyphenyl)-1-phenylethane, bis(4-hydroxyphenyl)diphenylmethane, 2,2-bis(4-hydroxyphenyl)propane, 2,2-bis(4-hydroxy-3-allylphenyl)propane, 2,2-bis(4-hydroxy-3-methylphenyl)propane, 2,2-bis(4-hydroxy-3-phenylphenyl)propane, 4,4′-(1,3-dimethylbutylidene)bisphenol, 1,1-bis(4-hydroxyphenyl)nonane, bis(4-hydroxyphenyl)sulfone, 1,1-bis(4-hydroxyphenyl)cyclohexane, 1,1-bis(4-hydroxyphenyl)-3,3,5-trimethylcyclohexane, 1,1-bis(3-methyl-4-hydroxyphenyl)-3,3,5-trimethylcyclohexane, 1,1-bis(3-cyclohexyl-4-hydroxyphenyl)-3,3,5-trimethylcyclohexane, 1,4-bis[2-(4-hydroxyphenyl)-2-propyl]benzene, 1,3-bis[2-(4-hydroxyphenyl)-2-propyl]benzene, 4,4-cyclododecylidenebisphenol, and 4,4′-decylidenebisphenol; and diol compounds such as Priplast 1901, 1838, 3186, 3192, 3197, and 3199 (all are trade names, manufactured by Croda Japan K.K.). These monomers may be used alone, or two or more kinds thereof may be used.

Examples of the monomer serving as a raw material for a portion including B include pyrimidine compounds such as 4,6-dichloropyrimidine, 4,6-dibromopyrimidine, 2,4-dichloropyrimidine, 2,5-dichloropyrimidine, 2,5-dibromopyrimidine, 5-bromo-2-chloropyrimidine, 5-bromo-2-fluoropyrimidine, 5-bromo-2-iodopyrimidine, 2-chloro-5-fluoropyrimidine, 2-chloro-5-iodopyrimidine, 2-phenyl-4,6-dichloropyrimidine, 2-methylthio-4,6-dichloropyrimidine, 2-methylsulfonyl-4,6-dichloropyrimidine, 5-methyl-4,6-dichloropyrimidine, 2-amino-4,6-dichloropyrimidine, 5-amino-4,6-dichloropyrimidine, 2,5-diamino-4,6-dichloropyrimidine, 4-amino-2,6-dichloropyrimidine, 5-methoxy-4,6-dichloropyrimidine, 5-methoxy-2,4-dichloropyrimidine, 2-methyl-4,6-dichloropyrimidine, 6-methyl-2,4-dichloropyrimidine, 5-methyl-2,4-dichloropyrimidine, 5-nitro-2,4-dichloropyrimidine, 4-amino-2-chloro-5-fluoropyrimidine, 2-methyl-5-amino-4,6-dichloropyrimidine, and 5-bromo-4-chloro-2-methylthiopyrimidine; pyridazine compounds such as 3,6-dichloropyridazine, 3,5-dichloropyridazine, and 4-methyl-3,6-dichloropyridazine; and pyrazine compounds such as 2,3-dichloropyrazine, 2,6-dichloropyrazine, 2,5-dibromopyrazine, 2,6-dibromopyrazine, 2-amino-3,5-dibromopyrazine, and 5,6-dicyano-2,3-dichloropyrazine. These monomers may be used alone, or two or more kinds thereof may be used.

Examples of the monomer serving as a raw material for a portion including R¹ or R² include monovalent phenol compounds such as t-butylphenol, nonylphenol, 4-isopropenylphenol, 4-vinylphenol, 2-allylphenol, isoeugenol, tocotrienol, a-tocopherol, 4-hydroxyphenylmaleimide, and 2-phenylphenol; monovalent amine compounds such as 4-hexylaniline and diallylamine; monovalent thiol compounds such as 1-octanethiol; monovalent aliphatic halides such as allyl chloride, 4-(chloromethyl)styrene, and 3-(chloromethyl)styrene; monovalent acid halides such as acryloyl chloride, methacryloyl chloride, crotonyl chloride, and cinnamoyl chloride; and monovalent acid anhydrides such as acrylic anhydride, crotonic anhydride, and methacrylic anhydride. These monomers may be used alone, or two or more kinds thereof may be used.

Examples of other monomers include compounds that introduce a structural unit containing a carbonate bond, a thiocarbonate bond, or a selenocarbonate bond, such as diphenyl carbonate, diphenyl thiocarbonate, diphenyl selenocarbonate, phosgene, thiophosgene, and selenophosgene; dihydroxy compounds such as benzenedimethanol and cyclohexanedimethanol; phosphine oxide compounds such as bis(fluorophenyl)phenylphosphine oxide, bis(fluorophenyl)naphthylphosphine oxide, and bis(fluorophenyl)anthrylphosphine oxide; and dihalides of dicarboxylic acids such as phthalic acid dichloride, isophthalic acid dichloride, and terephthalic acid dichloride. These monomers may be used alone, or two or more kinds thereof may be used.

The alkali metal and the alkali metal compound react with a compound having a hydroxyl group, such as a phenol compound, to form an alkali metal salt, when a compound having a hydroxyl group is used as a raw material in the process of synthesizing the compound 2.

Examples of such an alkali metal and alkali metal compound include:
alkali metals such as lithium, sodium, and potassium;
alkali metal hydrides such as lithium hydride, sodium hydride, and potassium hydride;
alkali metal hydroxides such as lithium hydroxide, sodium hydroxide, and potassium hydroxide;
alkali metal carbonates such as lithium carbonate, sodium carbonate, and potassium carbonate; and alkali metal hydrogen carbonates such as lithium hydrogen carbonate, sodium hydrogen carbonate, and potassium hydrogen carbonate.

Among these, alkali metal carbonates are preferred, and potassium carbonate is more preferable.

When a compound having a hydroxyl group is used in the synthesis of the compound 2, the amount of the alkali metal and the alkali metal compound used is such that the lower limit of a ratio of the number of moles of alkali metal atoms to the number of moles of hydroxyl groups in all compounds used in the synthesis of the compound 2 is preferably 1, more preferably 1.1, and still more preferably 1.2, and the upper limit of the ratio is preferably 3, more preferably 2, and still more preferably 1.8.

Examples of the organic solvent include:
ether-based solvents such as tetrahydrofuran (THF), dioxane, cyclopentyl methyl ether, anisole, phenetole, diphenyl ether, dialkoxybenzene, and trialkoxybenzene;
nitrogen-containing solvents such as N,N-dimethylacetamide (DMAc), N,N-dimethylformamide. N-methyl-2-pyrrolidone, and 1,3-dimethyl-2-imidazolidinone;
ester-based solvents such as y-butyrolactone;
sulfur-containing solvents such as sulfolane, dimethyl sulfoxide, diethyl sulfoxide, dimethyl sulfone, diethyl sulfone, diisopropyl sulfone, and diphenyl sulfone;
ketone-based solvents such as benzophenone, 2-heptanone, cyclohexanone, and methyl ethyl ketone;
halogen-based solvents such as methylene chloride, chloroform, and chlorobenzene; and aromatic hydrocarbon-based solvents such as benzene, toluene, and xylene.

Among these organic solvents, 2-heptanone, cyclohexanone, N-methyl-2-pyrrolidone, toluene, and xylene are preferred, and N-methyl-2-pyrrolidone, 2-heptanone, and cyclohexanone are more preferable.

The reaction temperature during the synthesis is preferably 50° C. or higher, more preferably 80° C. or higher, and preferably 300° C. or lower, more preferably 200° C. or lower.

The reaction time during the synthesis is preferably 1 hour or longer, more preferably 2 hours or longer, still more preferably 3 hours or longer, and preferably 100 hours or shorter, more preferably 50 hours or shorter, still more preferably 24 hours or shorter.

From the viewpoint of suppressing gelation of the polymerization reaction solution, when a monomer serving as a raw material for a portion including R¹ or R² is added after polymerization, the reaction temperature is preferably 0° C. or higher, more preferably 10° C. or higher, and preferably 130° C. or lower, more preferably 110° C. or lower.

The reaction time when a monomer serving as a raw material for a portion including R¹ or R² is added after polymerization and reacted is preferably 1 hour or longer, more preferably 2 hours or longer, still more preferably 3 hours or longer, and preferably 48 hours or shorter, more preferably 24 hours or shorter, still more preferably 10 hours or shorter.

By mixing the compound 1 and the compound 2 obtained as described above and, if necessary, various additives, the first composition can be obtained.

### Second Composition

The second composition contains a compound 1 having an olefin structure at a terminal portion and a crosslinking agent having an olefin structure and a benzene ring structure (hereinafter, also referred to as a crosslinking agent 1). The second composition, by using the compound 1 and the crosslinking agent 1 in combination, can suppress a dielectric loss tangent Df and the like to a low level, can further have excellent heat resistance and curability, and can further improve adhesion (adhesiveness) to a metal foil. The compound 1 can exclude those corresponding to the crosslinking agent 1, and can exclude those included in the crosslinking agent 1. In addition, the crosslinking agent 1 can exclude those corresponding to the compound 1, and can exclude those included in the compound 1.

Each of the compound 1 and the crosslinking agent 1 may be used alone as a single kind, or a plurality of kinds thereof may be used in combination. That is, the second composition may contain two or more types of the compound 1, and may include two or more types of the crosslinking agent 1. The molecular structure of each compound contained in the present composition can be identified using ¹H-NMR, ¹³C-NMR, and the like. Details will be described below.

### Compound 1

The compound 1 can be the same as the compound 1 in the first composition described above, and preferred embodiments thereof are also the same. Two or more kinds of the compound 1 may be used, and the mixing ratio of each compound can be appropriately set within a range in which the effects of the present disclosure can be obtained. In addition, the second composition may contain, for example, the compound 1 having an olefin structure at a terminal portion and another compound (for example, a compound having an olefin structure at a portion other than a terminal portion), or may contain two or more kinds of the compound 1 as described above.

### (Crosslinking Agent 1)

The crosslinking agent 1 has an olefin structure and a benzene ring structure in the molecular structure. When the crosslinking agent 1 is contained in the second composition, electrical properties, heat resistance, and curability can be improved. The olefin structure may include one unsaturated double bond, and examples thereof include alkenyl groups such as a vinyl group (H₂C═CH—), an ethylidene group (═CHCH₃), and an allyl group (—CH₂CH═CH₂), and cycloalkenyl groups. The olefin structure and the benzene ring structure may be directly bonded to each other, or may be indirectly bonded to each other via another atom (for example, a carbon atom or an oxygen atom). More specifically, the crosslinking agent 1 can have, for example, in the molecular structure, at least one structure selected from a styrene structure (styryl group), an allylbenzene structure, a vinylindene structure, a divinylindene structure, a trivinylindene structure, a divinylbiphenyl structure, a divinylnaphthalene structure, a divinylbenzene structure, and a vinylbenzyl ether structure. Among these, the crosslinking agent 1 preferably has a styrene structure (a vinylbenzene structure). The bonding position of the olefin structure in these structures is not particularly limited, and for example, the olefin structure may be bonded to any position of a benzene structure, an indene structure, a biphenyl structure, or a naphthalene structure. In addition, the olefin structure of the crosslinking agent 1 may be one or two or more in the molecular structure, but is preferably two or more. Furthermore, the benzene ring structure of the crosslinking agent 1 may be one or two or more in the molecular structure. The crosslinking agent 1 may be, for example, a styryl compound, a styryl resin, a divinyl compound, or the like. The crosslinking agent 1 may be a mixture of two or more types, or may be a compound having repeating units (a polymer).

The crosslinking agent 1 may have, in the molecular structure, structures other than an olefin structure and a benzene ring structure (for example, organic groups or inorganic groups). The other structures are not particularly limited, and examples thereof include organic groups such as monovalent, divalent, or trivalent or higher hydrocarbon groups (other than an olefin structure and a benzene ring structure), and monovalent, divalent, or trivalent or higher heterocyclic structures, and inorganic groups such as hydroxyl groups and halogen groups. In addition, each group or each structure may be bonded by various bonds such as an ether bond, an ester bond, or an amide bond, and may have a substituent. The substituent is not particularly limited, and examples thereof include an alkyl group, a hydroxyl group, a halogen group, an aldehyde group, a carboxy group, a carbonyl group, an amino group, a nitro group, and a sulfo group. The benzene ring structure included in these organic groups may be the benzene ring structure of the crosslinking agent 1 described above. In addition, the bonding positions of each group and each structure are not particularly limited.

Examples of the other monovalent, divalent, or trivalent or higher structures of the crosslinking agent 1 include an aliphatic saturated hydrocarbon group that may have a substituent, an aliphatic unsaturated hydrocarbon group (other than an olefin structure) that may have a substituent, an aromatic hydrocarbon group (other than a benzene ring structure) that may have a substituent, a heterocyclic structure that may have a substituent, a hydroxyl group, a halogen group, and groups obtained by combining these groups. As described above, the examples of the substituent include an alkyl group, a hydroxyl group, a halogen group, an aldehyde group, a carboxy group, a carbonyl group, an amino group, a nitro group, and a sulfo group.

Examples of the aliphatic saturated hydrocarbon group include an alkyl group, a cycloalkyl group, an alkylene group, and a cycloalkylene group. The number of carbon atoms of these aliphatic saturated hydrocarbon groups is, for example, 1 to 5,000.

Examples of the aliphatic unsaturated hydrocarbon group include an alkynyl group and a cycloalkynyl group. The number of carbon atoms of these aliphatic unsaturated hydrocarbon groups is, for example, 1 to 5,000.

Examples of the aromatic hydrocarbon structure of the aromatic hydrocarbon group include, in addition to a benzene ring, toluene, ethylbenzene, cumene, indene, xylene, mesitylene, naphthalene, azulene, fluorene, biphenyl, anthracene, tetracene, pentacene, phenanthrene, naphthacene, chrysene, triphenylene, tetraphene, pyrene, and picene. The number of carbon atoms of these aromatic hydrocarbon groups is, for example, 1 to 30.

Examples of the heterocyclic structure include aromatic heterocyclic structures and aliphatic heterocyclic structures such as succinimide, maleimide, oxazolidone, hydantoin, pyrrole, pyran, furan, thiophene, phosphole, pyrazole, imidazole, oxazole, isoxazole, thiazole, indole, benzofuran, benzothiophene, isoindole, isobenzofuran, benzophosphole, benzimidazole, benzoxazole, benzothiazole, benzisoxazole, indazole, benzisothiazole, benzotriazole, purine, pyridine, phosphinine, pyrazine, pyridazine, pyrimidine, triazine, tetrazine, pyrazine, quinoline, isoquinoline, quinoxaline, quinazoline, cinnoline, pteridine, phthalazine, acridine, xanthene, thioxanthene, phenoxazine, carbazole, aziridine, oxirane, pyrrolidine, 2-pyrroline, pyrazolidine, imidazolidine, 2-imidazoline, 1,3-dioxolane, tetrahydrofuran, tetrahydrothiophene, tetrahydrofuran, piperazine, 1,4-dioxane, piperazine, morpholine, 1,4-dithiane, quinuclidine, chromene, thianthrene, phenothiazine, phenoxazine, xanthene, acridine, phenazine, and carbazole. The number of carbon atoms of these heterocyclic structures is, for example, 1 to 20.

As the crosslinking agent 1, it is preferable to use one that is compatible in a mixed solvent including one organic solvent selected from toluene, methyl ethyl ketone (MEK), and methyl isobutyl ketone (MIBK), and the compound 1 described above. The state in which the crosslinking agent 1 is compatible in the mixed solvent refers to a state in which no phase-separated precipitate or particulate precipitate is present in a mixture including the crosslinking agent 1 and the mixed solvent. The mass ratio of the organic solvent to the compound 1 in the mixed solvent is preferably 99:1 to 30:70. In addition, the mass ratio of the crosslinking agent 1 to the mixed solvent in the mixture is preferably 1:99 to 50:50.

The crosslinking agent 1 preferably includes, for example, at least one selected from crosslinking agents A to D described below. When the crosslinking agent 1 includes at least one of these crosslinking agents, electrical properties, heat resistance, and curability can be further improved. The compounds shown as the crosslinking agents A to D may have overlapping structures included therein.

### Crosslinking Agent A

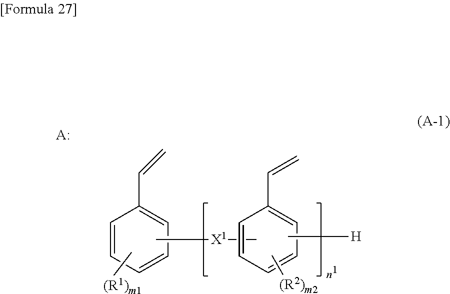

In Formula (A-1), R¹ and R² are each independently a hydroxyl group, a halogen group, a substituted or unsubstituted C1-C20 hydrocarbon group, a substituted or unsubstituted C1-C20 heterocyclic group, a C1-C20 alkoxy group, a C1-C20 thioalkoxy group, or a C1-C20 thioaryloxy group, each X¹ is independently a C1-C20 divalent organic group, n¹ is an integer of 1 to 10, m¹ is an integer of 0 to 4, and each m² is independently an integer of 0 to 3. The bonding positions of R¹, R², and X¹ and the bonding positions on the benzene ring are not particularly limited, and the crosslinking agent A may not have substituents R¹ and R².

Examples of the halogen group represented by R¹ and R² include —F, —Cl, —Br, and −I.

Examples of the C1-C20 hydrocarbon group represented by R¹ and R² (the total number of carbon atoms including the number of carbon atoms of the substituent), which may have a substituent, include a substituted or unsubstituted C1-C20 alkyl group, a substituted or unsubstituted C5-C20 cycloalkyl group, a substituted or unsubstituted C6-C20 aromatic hydrocarbon group, and a substituted or unsubstituted C7-C20 aralkyl group.

Examples of the C1-C20 alkyl group (the total number of carbon atoms including the number of carbon atoms of the substituent), which may have a substituent, include linear or branched groups such as a methyl group, an ethyl group, a propyl group, a butyl group, a pentyl group, and a hexyl group. Examples of the substituent of the alkyl group include a hydroxyl group and a halogen group, but are not limited thereto.

Examples of the C5-C20 cycloalkyl group (the total number of carbon atoms including the number of carbon atoms of the substituent), which may have a substituent, include a cyclopentyl group and a cyclohexyl group. Examples of the substituent of the cycloalkyl group include alkyl groups such as a methyl group, an ethyl group, a propyl group, and a butyl group, a hydroxyl group, and a halogen group, but are not limited thereto.

Examples of the C6-C20 aromatic hydrocarbon group (the total number of carbon atoms including the number of carbon atoms of the substituent), which may have a substituent, include monovalent aromatic hydrocarbon groups such as a phenyl group, a naphthyl group, and a biphenyl group. Examples of the substituent of the aromatic hydrocarbon group include alkyl groups such as a methyl group, an ethyl group, a propyl group, and a butyl group, a hydroxyl group, and a halogen group, but are not limited thereto.

Examples of the C7-C20 aralkyl group (the total number of carbon atoms including the number of carbon atoms of the substituent), which may have a substituent, include a phenylmethyl group, a phenylethyl group, a phenylpropyl group, and a diphenylmethyl group. Examples of the substituent of the aralkyl group include a hydroxyl group and a halogen group, but are not limited thereto.

Examples of the heterocyclic structure of the C1-C20 heterocyclic group (the total number of carbon atoms including the number of carbon atoms of the substituent), which may have a substituent represented by R¹ and R², include aromatic heterocyclic structures and aliphatic heterocyclic structures such as succinimide, maleimide, oxazolidone, hydantoin, pyrrole, pyran, furan, thiophene, phosphole, pyrazole, imidazole, oxazole, isoxazole, thiazole, indole, benzofuran, benzothiophene, isoindole, isobenzofuran, benzophosphole, benzimidazole, benzoxazole, benzothiazole, benzisoxazole, indazole, benzisothiazole, benzotriazole, purine, pyridine, phosphinine, pyridazine, pyridazine, pyrimidine, triazine, tetrazine, pyrazine, quinoline, isoquinoline, quinoxaline, quinazoline, cinnoline, pteridine, phthalazine, acridine, xanthene, thioxanthene, phenoxazine, carbazole, aziridine, oxirane, pyrrolidine, 2-pyrroline, pyrazolidine, imidazolidine, 2-imidazoline, 1, 3-dioxolane, tetrahydrofuran, tetrahydrothiophene, tetrahydrofuran, piperazine, 1,4-dioxane, piperazine, morpholine, 1,4-dithiane, quinuclidine, chromene, thianthrene, phenothiazine, phenoxazine, xanthene, acridine, phenazine, and carbazole. Examples of the substituent of the heterocyclic group include alkyl groups such as a methyl group, an ethyl group, a propyl group, and a butyl group, a hydroxyl group, and a halogen group, but are not limited thereto.

Examples of the C1-C20 alkoxy group represented by R¹ and R² include a methoxy group, an ethoxy group, an n-propoxy group, an isopropoxy group, a butoxy group, a pentyloxy group, a hexyloxy group, and an octyloxy group.

Examples of the C1-C20 thioalkoxy group represented by R¹ and R² include a thiomethoxy group, a thioethoxy group, a thio-n-propoxy group, a thioisopropoxy group, a thiobutoxy group, a thiopentyloxy group, a thiohexyloxy group, and a thiooctyloxy group.

Examples of the C1-C20 thioaryloxy group represented by R¹ and R² include a thiophenyloxy group and a thiophenylmethyloxy group.

Examples of the C1-C20 divalent organic group represented by X¹ include a substituted or unsubstituted C1-C20 divalent aliphatic linear or branched hydrocarbon group, a substituted or unsubstituted C5-C20 divalent aliphatic cyclic hydrocarbon group, a substituted or unsubstituted C6-C20 divalent aromatic hydrocarbon group (for example, an aromatic cyclic group), and combinations of these groups.

Examples of the C1-C20 divalent aliphatic linear or branched hydrocarbon group (the total number of carbon atoms including the number of carbon atoms of the substituent), which may have a substituent, include a linear or branched alkylene group. Examples of the alkylene group include a methylene group, an ethylene group, a propylene group, a butylene group, a pentylene group, and a hexylene group, which are linear or branched. Examples of the substituent of the hydrocarbon group include a hydroxyl group, a halogen group, and aryl groups such as a phenyl group and a biphenyl group, but are not limited thereto.

Examples of the C5-C20 divalent aliphatic cyclic hydrocarbon group (the total number of carbon atoms including the number of carbon atoms of the substituent), which may have a substituent, include a cyclopentylene group and a cyclohexylene group. Examples of the substituent of the aliphatic cyclic hydrocarbon group include alkyl groups such as a methyl group, an ethyl group, a propyl group, and a butyl group, a hydroxyl group, a halogen group, and aryl groups such as a phenyl group, but are not limited thereto.

Examples of the C6-C20 divalent aromatic hydrocarbon group (the total number of carbon atoms including the number of carbon atoms of the substituent), which may have a substituent, include divalent aromatic hydrocarbon groups such as a phenylene group, a naphthylene group, and a biphenylene group. Examples of the substituent of the aromatic hydrocarbon group include alkyl groups such as a methyl group, an ethyl group, a propyl group, and a butyl group, a hydroxyl group, and a halogen group, but are not limited thereto.

Examples of the combinations of the above-described C1-C20 aliphatic linear or branched hydrocarbon group, C5-C20 aliphatic cyclic hydrocarbon group, and C6-C20 divalent aromatic hydrocarbon group include the following groups, all of which may have substituents. Note that * represents a bonding position. *-The linear/branched hydrocarbon group-the aromatic hydrocarbon group-*; *-the aliphatic linear/branched hydrocarbon group-the aromatic hydrocarbon group-the aliphatic linear/branched hydrocarbon group-*; *-the aliphatic linear/branched hydrocarbon group-the aliphatic cyclic hydrocarbon group-*: *-the aliphatic linear/branched hydrocarbon group-the aliphatic cyclic hydrocarbon group-the aliphatic linear/branched hydrocarbon group-*; *-the aliphatic linear/branched hydrocarbon group-the aromatic hydrocarbon group-the aliphatic cyclic hydrocarbon group-*; *-the aliphatic linear/branched hydrocarbon group-the aliphatic cyclic hydrocarbon group-the aromatic hydrocarbon group-*; and the like.

X¹ can represent, for example, a hydrocarbon group having 6 or more carbon atoms, which includes at least one selected from an aromatic cyclic group and an aliphatic cyclic group.

n¹ is an integer of 1 to 10, but is preferably an integer of 1 to 8, and more preferably an integer of 1 to 4, from the viewpoint of compatibility. n¹ may be, for example, a decimal value such as 1.5 or 2.5.

m¹ is an integer of 0 to 4, but is preferably 0 or 1 from the viewpoint of compatibility. In addition, each m² is independently an integer of 0 to 3, but is preferably 0 or 1 from the viewpoint of compatibility.

The crosslinking agent A can be, for example, a compound represented by the following Formula (A-2).

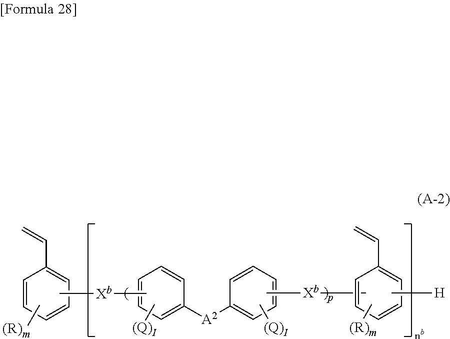

In Formula (A-2), each X^{b} independently represents a substituted or unsubstituted C1-C20 divalent aliphatic linear or branched hydrocarbon group, or represents one or more selected from (a) to (h) described in the following Formula (11). Here, when a plurality of X^{b} are present, the plurality of X^{b} may be the same as or different from each other. Examples of the divalent aliphatic linear or branched hydrocarbon group include those described for X¹. A² represents a methylene group or an oxygen atom, and each Q independently represents a C1-C1 0 hydrocarbon group or a halogenated alkyl group. The plurality of Q may be the same as or different from each other. Each R independently represents a C1-C10 hydrocarbon group or a halogenated alkyl group. When a plurality of R are present, the plurality of R may be the same as or different from each other. l and m each represent an integer of 0 to 3, n¹¹ represents a repeating unit and satisfies 1≤n^{b}≤10, and p represents a repeating unit and satisfies 0≤p≤20.

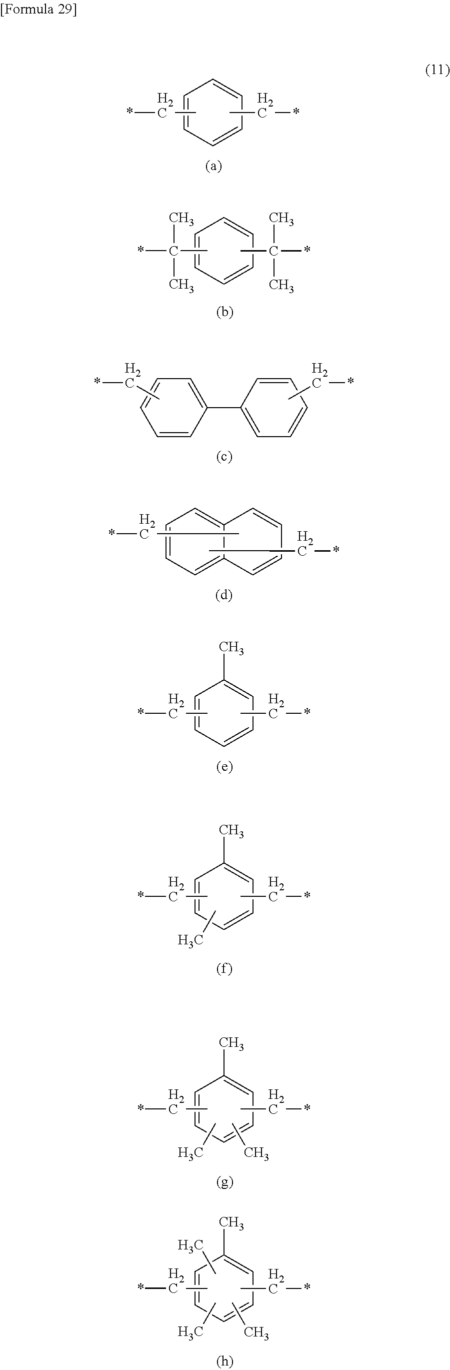

In Formula (11), each * represents a bonding position.

### Crosslinking Agent B

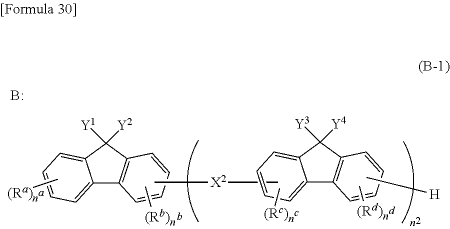

In Formula (B-1),
Y¹ to Y⁴ are each independently a hydrogen atom, a vinyl group, an allyl group, a group represented by the following Formula (B-2), or a group represented by the following Formula (B-3), provided that at least one of Y¹ to Y⁴ is a vinyl group, an allyl group, a group represented by the following Formula (B-2), or a group represented by the following Formula (B-3),
R^{a} to R^{d} are each independently a halogen group, a substituted or unsubstituted C1-C20 hydrocarbon group, a C1-C20 alkoxy group, a C1-C20 thioalkoxy group, or a C1-C20 thioaryloxy group,
each X² is independently a C1-C20 divalent organic group,
n² is an integer of 0 to 20,
n^{a} and n^{b} are each independently an integer of 0 to 4, and
n^{c} and n^{b} are each independently an integer of 0 to 3.

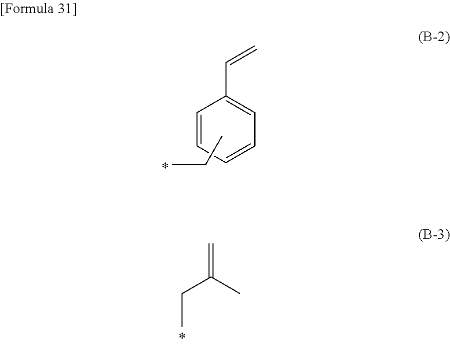

In Formulas (B-2) and (B-3),
* represents a bonding position.

As described above, at least one of Y to Y⁴ is a vinyl group, an allyl group, a group represented by Formula (B-2), or a group represented by Formula (B-3); however, from the viewpoint of crosslinkability, it is preferable that two to four of Y¹ to Y⁴ are groups represented by Formula (B-2).

As the halogen group, the substituted or unsubstituted C1-C20 hydrocarbon group, the C1-C20 alkoxy group, the C1-C20 thioalkoxy group, or the C1-C20 thioaryloxy group represented by R^{a} to R^{d}, for example, the groups described for R^{a} and R^{d} in the crosslinking agent A can be similarly used.

Examples of the C1-C20 divalent organic group represented by X² (the total number of carbon atoms including the number of carbon atoms of the substituent), which may have a substituent, include a substituted or unsubstituted C1-C20 divalent aliphatic linear or branched hydrocarbon group, a substituted or unsubstituted C5-C20 divalent aliphatic cyclic hydrocarbon group, a substituted or unsubstituted C6-C20 divalent aromatic hydrocarbon group (for example, an aromatic cyclic group), and combinations of these groups. As these groups, for example, the groups described for X¹ in the above-described crosslinking agent A can be similarly used.

n² is an integer of 0 to 20, but is preferably an integer of 1 to 10, more preferably an integer of 1 to 8, and still more preferably an integer of 1 to 4, from the viewpoint of compatibility.

n^{a} and n^{b} are real numbers of 0 to 4, but both are preferably 0 or 1, from the viewpoint of compatibility.

n^{c} and n^{d} are real numbers of 0 to 3, but both are preferably 0 or 1, from the viewpoint of compatibility.

### Crosslinking Agent C

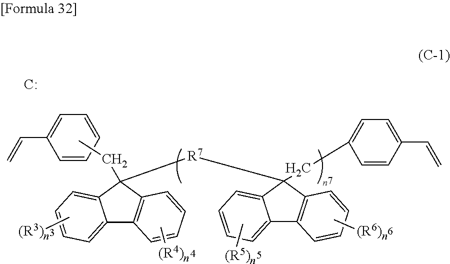

In Formula (C-1),
R³ to R⁶ are each independently a hydroxyl group, a halogen group, a substituted or unsubstituted C1-C20 hydrocarbon group, a C1-C20 alkoxy group, a C1-C20 thioalkoxy group, or a C1-C20 thioaryloxy group,
each R⁷ is independently a C1-C20 divalent organic group,
n³ to n⁶ are each independently an integer of 0 to 4, and
n⁷ is an integer of 1 to 20.

Examples of the halogen group represented by R³ to R⁶ include —F, —Cl, —Br, and —I.

Examples of the C1-C20 hydrocarbon group represented by R³ to R⁶ (the total number of carbon atoms including the number of carbon atoms of the substituent), which may have a substituent, include a substituted or unsubstituted C1-C20 alkyl group, a substituted or unsubstituted C5-C20 cycloalkyl group, a substituted or unsubstituted C6-C20 aromatic hydrocarbon group, and a substituted or unsubstituted C7-C20 aralkyl group. As these groups, for example, the groups described for X¹ in the above-described crosslinking agent A can be similarly used.

As the C1-C20 alkoxy group, thioalkoxy group, and thioaryloxy group represented by R³ to R⁶, the groups described for R¹ and R² in the above-described crosslinking agent A can be similarly used.

Examples of the C1-C20 divalent organic group represented by R⁷ include a substituted or unsubstituted C2-C20 divalent aliphatic linear or branched hydrocarbon group, a substituted or unsubstituted C5-C20 divalent aliphatic cyclic hydrocarbon group, a substituted or unsubstituted C6-C20 divalent aromatic hydrocarbon group (for example, an aromatic cyclic group), and combinations of these groups. As these groups, for example, the groups described for X¹ in the above-described crosslinking agent A can be similarly used.

n³ to n⁶ are real numbers of 0 to 4, but are preferably real numbers of 0 to 3, and more preferably real numbers of 0 to 2, from the viewpoint of compatibility.

n⁷ is an integer of 1 to 20, but is preferably an integer of 1 to 8, and more preferably an integer of 1 to 3, from the viewpoint of compatibility.

### Crosslinking Agent D

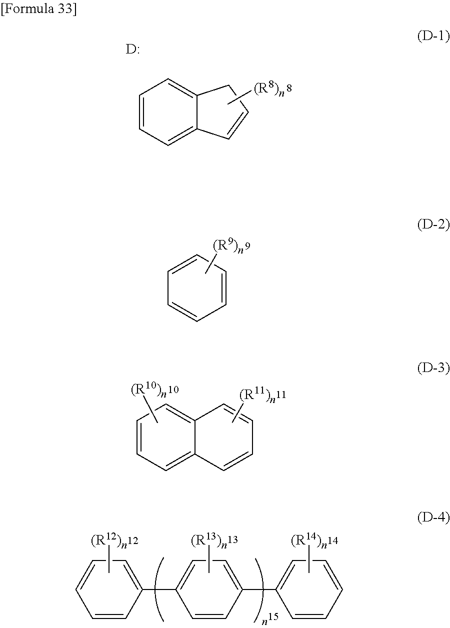

In Formulas (D-1) to (D-4),
each R⁸ is independently a vinyl group, an allyl group, a group represented by the following Formula (B-2), or a group represented by the following Formula (B-3),
R⁹ to R¹⁴ are each independently a hydroxyl group, a halogen group, a substituted or unsubstituted C1-C20 hydrocarbon group, a substituted or unsubstituted C1-C20 heterocyclic group, a C1-C20 alkoxy group, a C1-C20 thioalkoxy group, a C1-C20 thioaryloxy group, a vinyl group, an allyl group, a group represented by the following Formula (B-2), a group represented by the following Formula (D-5), or a group represented by the following Formula (B-3), provided that each compound represented by any one of Formulas (D-2) to (D-4) has at least one selected from a vinyl group, an allyl group, a group represented by the following Formula (B-2), a group represented by the following Formula (D-5), or a group represented by the following Formula (B-3),
n⁸ is an integer of 1 to 3,
n⁹ is an integer of 1 to 6,
n¹⁰ and n¹¹ are each independently an integer of 0 to 4, provided that either n¹⁰ or n¹¹ is an integer of 1 or more,
n¹² and n¹⁴ are each independently an integer of 0 to 5, n¹³ is an integer of 0 to 4, provided that any one of n¹² to n¹⁴ is an integer of or more and
n¹⁵ is an integer of 0 to 20.

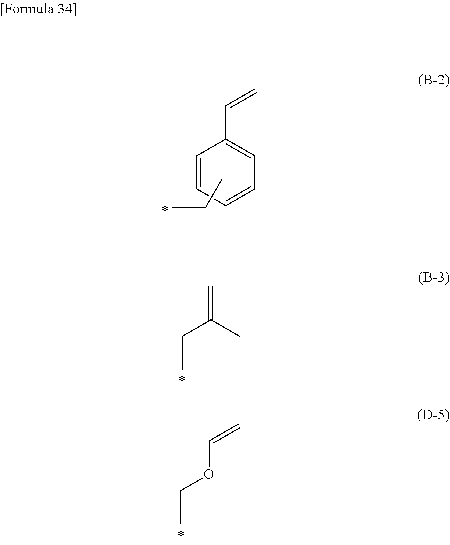

In Formula (B-2), Formula (B-3), and Formula (D-5),
* represents a bonding position.

R⁸ represents a vinyl group, an allyl group, a group represented by Formula (B-2), or a group represented by Formula (B-3), however, from the viewpoint of curability, R⁸ is preferably a group represented by Formula (B-2) or a group represented by Formula (B-3).

As the halogen group, the substituted or unsubstituted C1-C20 hydrocarbon group, the substituted or unsubstituted C1-C20 heterocyclic group, the C1-C20 alkoxy group, the C1-C20 thioalkoxy group, and the C1-C20 thioaryloxy group represented by R⁹ to R¹⁴ the groups described for R¹ and R² in the above-described crosslinking agent A can be similarly used. However, as described above, each of the compounds represented by Formulas (D-2) to (D-4) has at least one of a vinyl group, an allyl group, a group represented by the following Formula (B-2), a group represented by the following Formula (D-5), or a group represented by the following Formula (B-3). That is, when the compound represented by Formula (D-2) has one or more substituents R⁹, at least one of R⁹ is a vinyl group, an allyl group, a group represented by the following Formula (B-2), a group represented by the following Formula (D-5), or a group represented by the following Formula (B-3). In addition, among one or more substituents R¹⁰ and R¹¹ of the compound represented by Formula (D-3), at least one is a vinyl group, an allyl group, a group represented by the following Formula (B-2), a group represented by the following Formula (D-5), or a group represented by the following Formula (B-3). Furthermore, among one or more substituents R¹² to R¹⁴ of the compound represented by Formula (D-4), at least one is a vinyl group, an allyl group, a group represented by the following Formula (B-2), a group represented by the following Formula (D-5), or a group represented by the following Formula (B-3).

n⁸ is an integer of 1 to 3; however, from the viewpoint of compatibility, n⁸ is preferably 1.

n⁹ is an integer of 1 to 6; however, from the viewpoint of compatibility, n⁹ is preferably 1 or 2, and more preferably 1.

n¹⁰ and n¹¹ are real numbers of 0 to 4; however, from the viewpoint of compatibility, n¹⁰ and n¹¹ are preferably 0 or 1, and in this case, either one or both of n¹⁰ and n¹¹ are preferably 1.

n¹² and n¹⁴ are real numbers of 0 to 5, but are preferably 0 or 1 from the viewpoint of compatibility. In addition, n¹³ is an integer of 0 to 4, but is preferably 0 or 1 from the viewpoint of compatibility. In this case, at least one of n¹² to n¹⁴ is preferably 1.

n¹⁵ is an integer of 0 to 20, but is preferably an integer of 0 to 8, and more preferably an integer of 0 to 3, from the viewpoint of compatibility.

Examples of the crosslinking agent D include divinylindene, trivinylindene, divinylbiphenyl, divinylnaphthalene, divinylbenzene, and vinylbenzyl ether.

In addition, the second composition may contain a crosslinking agent E having a structural unit represented by the following Formula (E-1) (which may be present as a repeating unit), from the viewpoints of electrical properties and curability. The structure of the crosslinking agent E may overlap with the structures of the compounds shown as the above-described crosslinking agents A to D.

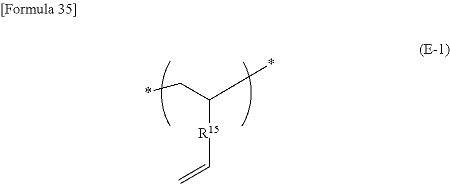

In Formula (E-1), R¹⁵ represents a divalent linking group including an aromatic hydrocarbon group, and * represents a bonding position.

The divalent linking group represented by R¹⁵ includes an aromatic hydrocarbon group, and the aromatic hydrocarbon group has at least a benzene ring structure. The divalent linking group may be a divalent group consisting only of an aromatic hydrocarbon that may have a substituent, or may be a divalent group consisting of a combination of an aromatic hydrocarbon that may have a substituent and another linking group. However, from the viewpoints of electrical properties and curability, the divalent linking group is preferably a divalent group consisting only of an aromatic hydrocarbon that may have a substituent. The number of carbon atoms in the divalent linking group represented by R¹⁵ is preferably from 6 to 22, more preferably from 6 to 18, and still more preferably from 6 to 10.

Examples of the substituent that the aromatic hydrocarbon may have include a CJ-C6 alkyl group, a C2-C6 alkenyl group, a C2-C6 alkynyl group, a C1-C6 alkoxy group, a hydroxyl group, an amino group, a carboxyl group, and a halogen atom.

Examples of the divalent linking group including an aromatic hydrocarbon group include a phenylene group, a naphthalenediyl group, an anthracenediyl group, a phenanthrenediyl group, a biphenyldiyl group, and a fluorenediyl group, each of which may have a substituent. Among these, a phenylene group that may have a substituent is preferable. Examples of the substituent include those described above.

In addition, the crosslinking agent E may further have at least one selected from structural units represented by the following Formulas (E-2) and (E-3).

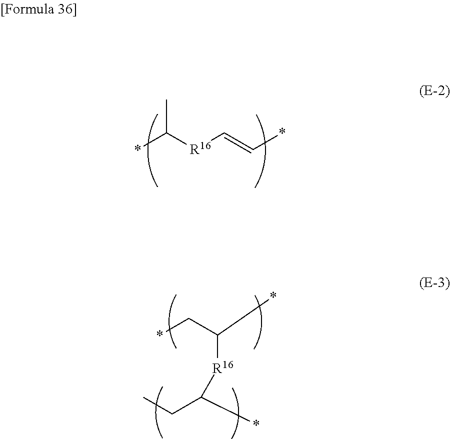

In Formulas (E-2) and (E-3), each R¹⁶ independently represents a divalent linking group including an aromatic hydrocarbon group and * represents a bonding position. As the divalent linking group including an aromatic hydrocarbon group represented by R¹⁶, the divalent linking group represented by R¹⁵ described above can be similarly used.

The crosslinking agent E may be a polymer having repeating units represented by Formulas (E-1) to (E-3) described above, or may be a polymer (copolymer) having structural units derived from other monomers. For example, in the crosslinking agent E, the content ratio of the structural units represented by Formulas (E-1) to (E-3) (particularly Formula (E-1)) can be 3 mol % or more, 5 mol % or more, 10 mol % or more, or 15 mol % or more. In addition, the content ratio of these structural units can be, for example, 90 mol % or less, 85 mol % or less, 80 mol % or less, or 70 mol % or less. Examples of the other monomers include vinyl aromatic compounds such as styrene, vinylnaphthalene, and vinylbiphenyl; and alkyl-substituted vinyl aromatic compounds such as o-methylstyrene, m-methylstyrene, and p-methylstyrene. The other monomers may be used alone as a single kind, or a plurality of kinds thereof may be used in combination.

From the above, as the crosslinking agent 1, for example, the following compounds can be used. As the crosslinking agent 1, from the viewpoint of electrical properties, vinyl compounds such as 1,2-bis(vinylphenyl)ethane (BVPE), a fluorene compound having a vinylbenzyl group and the like, an indene compound having a vinylbenzyl group and the like, divinylbenzene, bis(1-methylvinyl)benzene, divinylnaphthalene, divinylanthracene, divinylbiphenyl, and divinylphenanthrene are preferably used, and BVPF is more preferably used. In addition, as described above, two or more kinds of the crosslinking agent 1 can also be used. By using a plurality of kinds of crosslinking agents in combination, effects such as improvement in solubility in solvents, improvement in compatibility between a resin and the crosslinking agent, and improvement in heat resistance can be obtained. For example, as the crosslinking agent 1, the BVPF and the indene compound having a vinylbenzyl group and the like can be used in combination. The mixing ratio of each crosslinking agent can be appropriately set within a range in which the effects of the present invention can be obtained. For example, when a crosslinking agent 1 (for example, BVPE) and a crosslinking agent II (for example, an indene compound having a functional group) are used in combination, the mixing ratio therebetween (crosslinking agent I:crosslinking agent II) is preferably 10:90 to 90:10. By using two kinds of crosslinking agents in combination at the mixing ratio, effects such as improvement in solubility and improvement in heat resistance can be obtained.

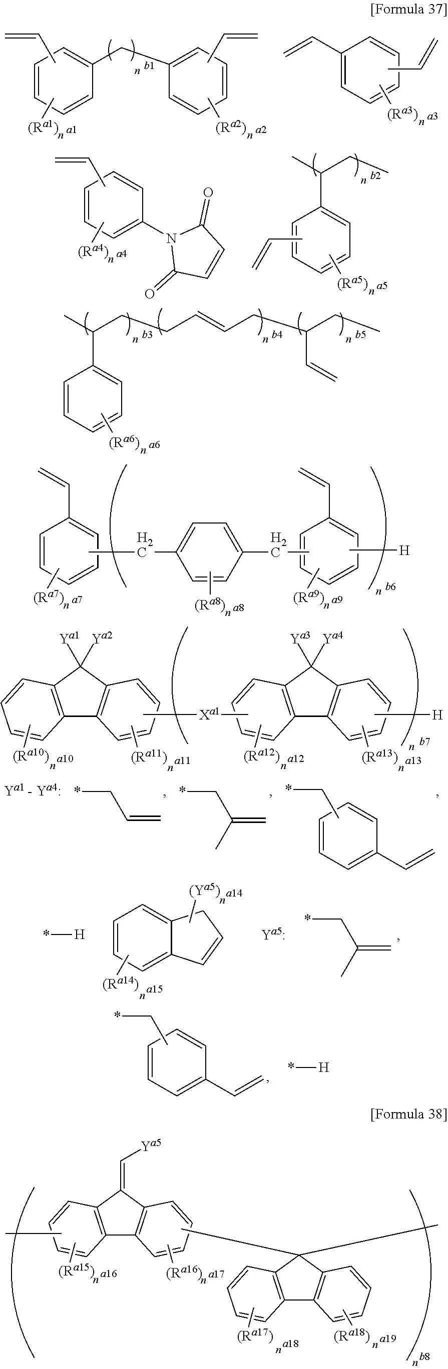

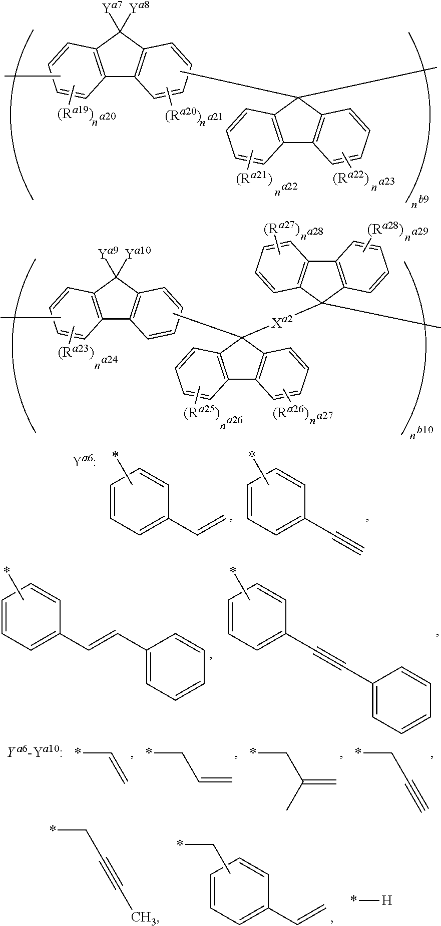

Here, in the compounds, R^{a1} to R^{a28} each independently represent a hydroxyl group, a halogen group, a substituted or unsubstituted C1-C20 hydrocarbon group, a substituted or unsubstituted C1-C20 heterocyclic group, a C1-C20 alkoxy group, a C1-C20 thioalkoxy group, or a C1-C20 thioaryloxy group. As these groups, the groups described for the above-described crosslinking agent A can be similarly used.

In addition, in the compounds, n^{a1} to n^{a29} each independently are real numbers of 0 to 3, or real numbers of 0 to 4, but are preferably 0 or 1, from the viewpoint of compatibility.

In the compounds, n^{b1} to n^{b10} are real numbers of 1 to 5,000, but are preferably real numbers of 1 to 20, and more preferably real numbers of 1 to 10, from the viewpoint of compatibility.

In addition, in the compounds, X^{a1} represents any one of the groups shown below.

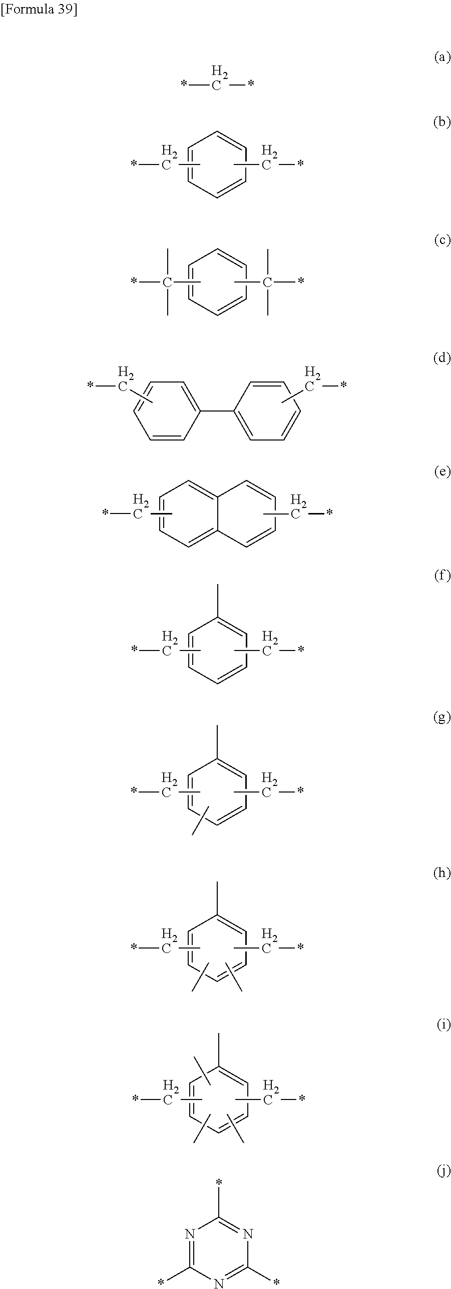

Furthermore, in the compounds, X^{a2} represents a C6-C50 divalent organic group having one or more aromatic rings. Examples of the aromatic ring include benzene, toluene, ethylbenzene, cumene, indene, xylene, mesitylene, naphthalene, azulene, fluorene, biphenyl, anthracene, tetracene, pentacene, phenanthrene, naphthacene, chrysene, triphenylene, tetraphene, pyrene, and picene. Examples of the divalent organic group include a divalent aliphatic linear or branched hydrocarbon group having the aromatic ring, a divalent aliphatic cyclic hydrocarbon group having the aromatic ring, a divalent aromatic hydrocarbon group, and combinations of these groups.

In the entire crosslinking agent (including the above-described crosslinking agent 1 and all other crosslinking agents described below), the average number of carbon-carbon unsaturated double bonds (number of terminal double bonds) per molecule of the crosslinking agent varies depending on the weight average molecular weight of the crosslinking agent; however, from the viewpoint of heat resistance of the cured product, the average number is preferably 1 or more, and more preferably 2 or more. In addition, the number of terminal double bonds per molecule of the crosslinking agent is preferably 20 or less, and more preferably 18 or less, from the viewpoints of reactivity, storage stability of the second composition, and fluidity.

Considering the weight average molecular weight of the entire crosslinking agent, when the weight average molecular weight of the crosslinking agent is less than 500 (for example, 100 or more and less than 500), the number of terminal double bonds of the crosslinking agent is preferably 1 to 4. In addition, when the weight average molecular weight of the crosslinking agent is 500 or more (for example, 500 or more and 5,000 or less), the number of terminal double bonds of the entire crosslinking agent is preferably 2 to 20. In each case, when the number of terminal double bonds is equal to or greater than the lower limit of the above range, the crosslinking agent tends to have excellent reactivity, an appropriate crosslinking density is easily imparted to a cured product of the second composition, and heat resistance and Tg can be readily improved. On the other hand, when the number of terminal double bonds is equal to or less than the upper limit of the above range, gelation of the composition can be easily prevented.

The number of terminal double bonds of the entire crosslinking agent can be determined from the product specification values of the crosslinking agent used. As used herein, the number of terminal double bonds refers to a value representing the average number of double bonds per molecule of the crosslinking agent, calculated for all crosslinking agent molecules present in one mole of the crosslinking agent.

### Other Components

The second composition can further contain additives such as other curable resins, other crosslinking agents, flame retardants, fillers, and elastomers. In addition, the second composition may contain a radical polymerization initiator, similarly to the first composition.

The second composition can be used in combination with other curable resins (for example, resins containing a radical-polymerizable group) as necessary. As the other curable resins, known resins can be appropriately used; for example, those described for the first composition can be similarly used.

The second composition can further contain a crosslinking agent other than the above-described crosslinking agent 1.

Examples of the other crosslinking agent include compounds having, in the molecule, a reactive functional group such as a maleimide group, an allyl group, or a (meth)acryloyl group (excluding those having a benzene ring structure).

As the other crosslinking agent, tri-alkenyl isocyanurate compounds such as triallyl isocyanurate (TAIC), polyfunctional methacrylate compounds having two or more methacryloyl groups in the molecule, polyfunctional acrylate compounds having two or more acryloyl groups in the molecule, and vinyl compounds having two or more vinyl groups in the molecule, such as polybutadiene and styrene-butadiene copolymers (polyfunctional vinyl compounds, excluding those corresponding to crosslinking agent 1), can be used.

Among these, as the other crosslinking agent, those having two or more carbon-carbon double bonds in the molecule are preferable. Specific examples thereof include a trialkenyl isocyanurate compound, a polyfunctional acrylate compound, and a polyfunctional methacrylate compound. When these are used in combination with the crosslinking agent 1, it is considered that crosslinking is more suitably formed by a curing reaction, and the heat resistance of a cured product of the second composition can be further enhanced. In addition, these other crosslinking agents may be used alone as a single type, or two or more types thereof may be used in combination. In addition, as the crosslinking agent, a compound having two or more carbon-carbon unsaturated double bonds in the molecule may be used in combination with a compound having one carbon-carbon unsaturated double bond in the molecule. Specific examples of the compound having one carbon-carbon unsaturated double bond in the molecule include compounds having one vinyl group in the molecule (monovinyl compounds).

As the flame retardant, the filler, and the elastomer, those described for the first composition can be similarly used.

In addition to the above, the second composition can further contain, as necessary, acenaphthylene and indene, derivatives thereof, and known maleimide compounds. The mixing ratio of these components can be set to 75 mass % or less with respect to the second composition.

Furthermore, the second composition may contain a fluororesin. From the viewpoint of improving adhesion, the fluororesin may have a functional group.

The content ratio of the compound 1 with respect to the total content of the compound 1 and the crosslinking agent 1 in the second composition is preferably 30 to 98 mass %. When the content ratio of the compound 1 is 30 mass % or more, excellent electrical properties can be readily imparted. In addition, when the content ratio of the compound 1 is 98 mass % or less, excellent heat resistance can be readily imparted. From the same viewpoint, the content ratio of the compound 1 with respect to the total content of the compound 1 and the crosslinking agent 1 in the second composition is more preferably from 40 to 95 mass %, and particularly preferably from 50 to 93 mass %.

The dielectric loss tangent Df of the second composition (cured product) at a temperature of 25° C. and a measurement frequency of 10 GHz is preferably 0.003 or less, more preferably 0.002 or less, and particularly preferably 0.0015 or less, from the viewpoint of electrical properties. In addition, the lower limit of the Df is not particularly limited, but is preferably 0.00001 or more, and more preferably 0.0001 or more. The method for measuring the dielectric loss tangent will be described below.

The dielectric constant Dk of the second composition (cured product) at a temperature of 25° C. and a measurement frequency of 10 GHz is preferably from 1.5 to 4.0, and more preferably from 1.7 to 3.0. The method for measuring the dielectric constant will be described below.

In the present specification, the glass transition temperature (Tg) (of a cured product) refers to the glass transition temperature of a cured product obtained by curing the composition according to the present disclosure as described above. The cured product exhibits an excellent glass transition temperature and exhibits preferred heat resistance. The glass transition temperature of the cured product is preferably 120° C. or higher, more preferably 125° C. or higher, and still more preferably 130° C. or higher. The glass transition temperature is preferably 280° C. or lower, and more preferably 2400C or lower. In addition, the method for measuring the glass transition temperature will be described below.

The second composition exhibits the above-described glass transition temperature even when thermally cured at a thermosetting temperature used in producing a substrate material such as a prepreg. The thermosetting temperature is at most 250° C., for example, 150 to 230° C.

### <Method for Producing Compound 1>

A method for producing a compound 1 having an olefin structure at a terminal portion can be the same as the method described for the first composition.

### <Method for Producing Crosslinking Agent 1>

A method for producing a crosslinking agent 1 is not particularly limited, and a conventionally known method can be appropriately used depending on the structure. The crosslinking agent 1 can be obtained, for example, by the method described below. In addition, a commercially available product may be used as the crosslinking agent 1.

For example, among the compounds represented by the following Formula (D-1), a compound in which R⁸ is a vinylbenzyl group (a group represented by Formula (3)), and a compound represented by the following Formula (12), can be produced by the following method.

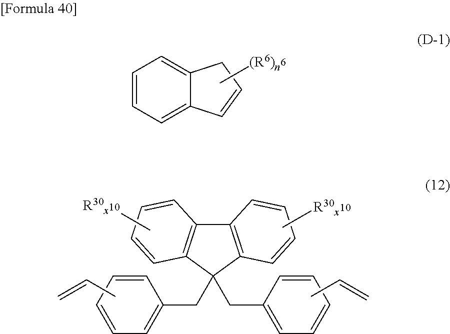

In Formula (5), each R⁸ independently is a vinyl group, an allyl group, a group represented by Formula (B-2) described above, or a group represented by Formula (B-3) described above, and n⁸ is an integer of 1 to 3.

In Formula (12), each R³⁰ independently is a halogen group, a substituted or unsubstituted C1-C20 hydrocarbon group, a C1-C20 alkoxy group, a C1-C20 thioalkoxy group, or a C1-C20 thioaryloxy group, and x¹⁰ is an integer of 0 to 4.

First, a method is exemplified in which a base compound into which a vinylbenzyl group is introduced and styrene having a halogenated methyl group are reacted in the presence of a basic compound. Examples of the base compound include compounds having a phenolic hydroxyl group, and compounds having a condensed polycyclic structure including an aromatic ring and a non-aromatic ring, such as fluorene, indene, indane, phenanthrene, and acenaphthylene. In addition, examples of the styrene having a halogenated methyl group include chloromethylstyrene. Examples of the basic compound include alkali metal hydroxides and alkali metal alkoxides. In the above reaction, a phase-transfer catalyst may be used. Examples of the phase-transfer catalyst include tetrabutylammonium bromide. The reaction solvent is preferably an aprotic organic solvent or a solvent containing an aprotic organic catalyst.

In order to reduce the amount of chlorine impurities in the crosslinking agent, when chloromethylstyrene is used as the styrene having a halogenated methyl group, a chloromethylstyrene having a low content of chlorine-based impurities can be used. For example, chloromethylstyrene having an organic chlorine content of 1,500 ppm or less can be used. The isomer ratio in the chloromethylstyrene is not particularly limited and can be appropriately set.

A compound having a vinylbenzyl ether group can be synthesized, for example, by reacting a phenolic resin such as a biphenyl aralkyl-type phenol, an aralkyl phenol, or a naphthol aralkyl resin with chloromethylstyrene in the presence of an alkaline catalyst.

As the crosslinking agent 1, a polyfunctional aromatic copolymer obtained by copolymerizing divinylbenzene and a styrene derivative, and vinylbenzyl compounds having a vinylbenzyl group in the molecule, such as styrene and divinylbenzene, may also be used.

By mixing the compound 1 and the crosslinking agent 1 obtained as described above and, if necessary, various additives, the second composition can be obtained.

### <Prepreg>

A prepreg according to the present disclosure (hereinafter, also referred to as “the present prepreg”) contains the above-described present composition, that is, one of the first composition or the second composition. The present prepreg may contain both the first composition and the second composition (for example, a mixture thereof). The present prepreg can be produced, for example, by the following method. Specifically, first, the present composition to which the above-described other additives (such as an elastomer, another crosslinking agent, an initiator, an inorganic filler, and a flame retardant) are added as necessary is mixed and stirred to prepare a resin varnish. Next, the resin varnish is impregnated into a fibrous material and dried to obtain a prepreg.

Here, as the fibrous material into which the resin varnish is impregnated, a glass cloth having an arbitrary composition is preferably used from the viewpoints of processability and electrical properties, and a quartz cloth is more preferably used from the viewpoint of electrical properties.

### <Metal-Clad Laminate and Method for Producing the Same>

A metal-clad laminate according to the present disclosure (hereinafter, also referred to as “the present laminate”) includes a cured product of one of the above-described present compositions, that is, the first composition or the second composition, and a metal foil. The present laminate may include a cured product of both the first composition and the second composition (for example, a mixture thereof). The present laminate can be obtained by laminating a prepreg containing the above-described present composition and a metal foil. More specifically, the present laminate can be produced by laminating metal foils (for example, copper foils) to both surfaces of a prepreg impregnated with the above-described present composition by lamination or the like, for example, under heating and pressurizing conditions.

The metal foil peel strength (peel strength) of a metal-clad laminate obtained by laminating, under heat and pressure, a prepreg obtained using the present composition and a metal foil is preferably 2.0 N/cm or more, and more preferably 2.5 N/cm or more, from the viewpoint of practical application.

### EXAMPLES

Hereinafter, the present disclosure will be described in more detail with reference to a plurality of examples; however, the present disclosure is not limited to these examples. Examples 1 to 33 are Examples relating to the first composition of the present disclosure, and Examples 34 to 41 are Comparative Examples relating to the first composition of the present disclosure. In addition, Examples 42 to 49 are Examples relating to the second composition of the present disclosure, and Examples 50 and 51 are Comparative Examples relating to the second composition of the present disclosure.

### <Method for Structural Analysis>

The structures of the obtained compounds were identified using ¹H-NMR and ¹³C-NMR.

### (¹H-NMR)

The measurement target (each compound) was dissolved in chloroform-di and measured by ¹H-NMR (manufactured by Bruker, trade name: Avance NEO400). At this time, tetramethylsilane was used as an internal standard substance.

### (¹³C-NMR)

The measurement target (each compound) was dissolved in chloroform-di so as to have a concentration of 20 mass %, and measurement was performed by ¹³C-NMR (manufactured by JEOL Ltd., trade name: ECZ600). At this time, hexamethyldisiloxane was used as an internal standard substance. Spectral analysis was performed using Delta v6.0 (analysis software manufactured by JEOL Ltd.).

### <Method for Measuring Molecular Weight>

The weight average molecular weight Mw was measured using gel permeation chromatography (GPC) (manufactured by Tosoh Corporation, trade name: HLC-8420 GPC). As the columns, a guard column “HXL-L” (trade name, manufactured by Tosoh Corporation), “SuperH-RC” (trade name, manufactured by Tosoh Corporation), “TSKgel SuperHZ2000” (trade name, manufactured by Tosoh Corporation), “TSKgel SuperHZ2500” (trade name, manufactured by Tosoh Corporation), “TSKgel SuperHZ3000” (trade name, manufactured by Tosoh Corporation), and “TSKgel SuperHZ4000” (trade name, manufactured by Tosoh Corporation), connected in series were used. In addition, the measurement was performed using tetrahydrofuran as an eluent, a flow rate of 1.0 ml/min, a column temperature of 40° C., and an RI detector (differential refractometer), with a calibration curve prepared using monodisperse polystyrene. For data processing, “GPC Workstation EcoSEC-WorkStation” (trade name, manufactured by Tosoh Corporation) was used.

### <Measurement of Dielectric Constant (Dk) and Dielectric Loss Tangent (Df)>

Using each film-shaped cured product described below as a test specimen, the dielectric constant (Dk) and the dielectric loss tangent (Df) at a frequency of GHz were measured at room temperature (25° C.) by the SPDR method using a vector network analyzer (“E8361C” (trade name), manufactured by Agilent Technologies, Inc.).

### <Preparation of Film-Shaped Cured Product>

The respective compounds (compound 1 and compound 2) were dissolved in toluene at the mass ratios shown in Tables 1 to 4 described below to obtain a toluene solution (composition) having a concentration of 50 mass %. Using an applicator (manufactured by Yoshimitsu Seiki Co., Ltd.), the toluene solution was applied onto a polyimide film having a thickness of 125 μm to form a coating film having a thickness of 250 m. After heating and drying in an oven at 80° C. for 30 minutes under an air atmosphere, the coating film was heated at 200° C. for 2 hours under a nitrogen atmosphere, thereby thermally curing the coating film by a thermal crosslinking reaction to obtain a film-shaped cured product for evaluation for the first composition having a thickness of about 100 μm.

In addition, the compound 1 and a crosslinking agent were dissolved in toluene at the mixing ratios (parts by mass) shown in Table 5 described below to prepare a 50 mass % solution, thereby obtaining a composition. Next, the composition obtained in each example was poured between PTFE spacers, sandwiched between polyimide films, held with SUS plates, and cured by maintaining at a pressure of 2 MPa and 200° C. for 2 hours using a vacuum press, thereby obtaining a film-shaped cured product for the second composition.

### <Glass Transition Temperature>

With respect to the glass transition temperature of the first composition, a film-shaped cured product for the first composition described above was prepared, and the glass transition temperature of the cured product was determined by performing differential scanning calorimetry (DSC) using 204 F1 Phoenix (trade name, manufactured by NETZSCH GmbH). 5 mg of a sample (film-shaped cured product) was heated from room temperature to 300° C. at a rate of 10° C./min under a nitrogen flow of 50 mL/min, then cooled to 30° C. at a rate of 10° C./min, and subsequently heated again to 300° C. at a rate of 10° C./min to measure a DSC curve. The glass transition temperature was defined as the temperature at the point, in the measurement results observed in the second heating step, where a straight line obtained by extending the baseline on the low-temperature side toward the high-temperature side intersects the curve of the step-like portion of the glass transition at the point having the maximum slope.

In addition, with respect to the glass transition temperature of the second composition, a substrate obtained by removing a copper foil by etching from a substrate for evaluation corresponding to each example described below was used as a test specimen, and dynamic mechanical analysis (DMA) was performed using a dynamic viscoelasticity measurement apparatus (“DVA-200” (trade name), manufactured by IT KEISOKU SEIGYO KK.) to measure the glass transition temperature (Tg) (° C.). The measurement was performed under conditions of a frequency of 10 Hz, a heating rate of 2° C./min, and a temperature range of 25 to 300° C.

### <Copper Foil Peel Strength: Measurement of Peel Strength>

From a substrate for evaluation corresponding to each example described below, a test specimen having a width of 20 mm and a length of 100 mm was cut out, and parallel cuts having a width of 10 mm were made on the copper foil surface. Thereafter, the copper foil was continuously peeled at a rate of 50 mm/min in a direction of 90° with respect to the copper foil surface, the stress at that time was measured using a tensile testing machine, and the minimum value of the stress was recorded as the copper foil peel strength (in accordance with JIS C 6481).

The copper peel strength was evaluated based on the following criteria.

(Evaluation criteria)
A+: 4 N/cm or more
A: 3 N/cm or more and less than 4 N/cm
B: 2 N/cm or more and less than 3 N/cm
C: less than 2 N/cm

### First Composition

### Synthesis of compound 1

### Synthesis Example 1-1

To a 1 L glass reaction vessel equipped with a stirring blade and a fluororesin-coated thermocouple under a flow of N₂, 480 g of p-xylene, 4.80 g (33.8 mmol) of a boron trifluoride/diethyl ether complex (manufactured by Tokyo Chemical Industry Co., Ltd.) as an acid catalyst, and 6.91 g (67.6 mmol) of propyl acetate as a cocatalyst were added, and the mixture was maintained at 25° C. for 2 hours. Thereafter, while the reaction temperature was maintained at 50° C., 120.0 g of 1,3-diisopropenylbenzene (manufactured by Tokyo Chemical Industry Co., Ltd.) was added dropwise into the reaction vessel over 2 hours using a syringe pump. Further, after the dropwise addition, as an aging step, the reaction was performed for 15 minutes (aging time) while the temperature was maintained at 50° C. (aging temperature). Thereafter, 100 g of a 5 mass % aqueous sodium hydrogencarbonate solution was added into the reaction vessel to terminate the reaction. Subsequently, the aqueous phase in the reaction vessel was discarded, and liquid-liquid separation washing was performed three times with 300 ml of ion-exchanged water to obtain a compound 1-1 solution.

Subsequently, 2,200 g of methanol was added to a separate 6 L flask, and the compound 1-1 solution was gradually added thereto to reprecipitate the compound. Thereafter, a cake was obtained by filtration. The cake was redispersed in 2,200 g of methanol, washed, and filtered, and this operation was performed twice. Thereafter, the obtained compound was vacuum-dried at 60° C. to obtain 107.9 g of a compound 1-1.

Structural analysis and molecular weight measurement of the obtained compound 1-1 (curable resin) were performed in accordance with the methods described above. As a result, the molecular weights of the obtained compound 1-1 were Mn: 1,770 and Mw: 7,090. It was confirmed by ¹³C-NMR and ¹H-NMR that an olefin structure was included in the terminal portion of the molecular structure of the obtained compound 1-1.

### Synthesis Example 1-2

The same procedure as in Synthesis Example 1-1 was performed, except that 2.0 g (14.1 mmol) of a boron trifluoride/diethyl ether complex and 2.87 g (28.1 mmol) of propyl acetate were used, and the aging time was set to 60 minutes, thereby obtaining 98.1 g of a compound 1-2. Structural analysis and molecular weight measurement of the obtained compound 1-2 were performed in accordance with the methods described above. As a result, the molecular weights of the obtained compound 1-2 were Mn: 2,460 and Mw: 23,800. It was confirmed by ¹³C-NMR and ¹H-NMR that an olefin structure was included in the terminal portion of the molecular structure of the obtained compound 1-2.

### Synthesis of Compound 2

### Synthesis Example 2-1

Into a four-neck separable flask equipped with a stirring device, 1,1-bis(4-hydroxy-3-methylphenyl)-3,3,5-trimethylcyclohexane (30.78 g), 9,9-bis(4-hydroxy-3-methylphenyl)fluorene (8.58 g), 2,4-dichloro-6-phenyl-1,3,5-triazine (22.34 g), and potassium carbonate (22.1 g) were charged, N-methyl-2-pyrrolidone (69.1 g) was added, and the mixture was reacted at 100° C. for 6 hours under a nitrogen atmosphere. After the reaction, while the vessel was cooled to 10° C., m,p-(chloromethyl)styrene (10.0 g) was added dropwise, and the mixture was reacted at 100° C. for 4 hours. The obtained reaction solution was diluted by adding 55.0 g of N-methyl-2-pyrrolidone, salts were removed from the diluted solution by filtration, and the obtained solution was added to 6,900 g of methanol. The precipitated solid was separated by filtration, washed with a small amount of methanol, and collected by filtration again, and then dried under reduced pressure at 60° C. for 12 hours using a vacuum dryer, thereby obtaining a compound 2-1 represented by the following Formula (2-1). The obtained compound 2-1 had a number average molecular weight (Mn) of 1,800 and a weight average molecular weight (Mw) of 4,000.

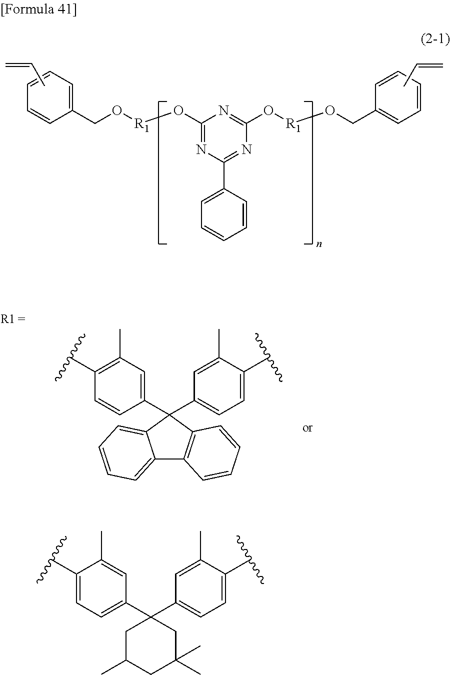

### Synthesis Example 2-2

Into a four-neck separable flask equipped with a stirring device, 1,1-bis(4-hydroxy-3-methylphenyl)-3,3,5-trimethylcyclohexane (41.52 g), 9,9-bis(4-hydroxy-3-methylphenyl)fluorene (11.61 g), 2,4-dichloro-6-phenyl-1,3,5-triazine (3014 g), and potassium carbonate (26.18 g) were charged, N-methyl-2-pyrrolidone (42.67 g) was added, and the mixture was reacted at 130° C. for 6 hours under a nitrogen atmosphere. After the reaction, while the vessel was cooled to 10° C., acryloyl chloride (3.52 g) was added dropwise, and the mixture was reacted at 50° C. for 6 hours. The obtained reaction solution was diluted by adding N-methyl-2-pyrrolidone (240.0 g), salts were removed from the diluted solution by filtration, and the obtained solution was added to methanol (12.90 kg). The precipitated solid was separated by filtration, washed with a small amount of methanol, and collected by filtration again, and then dried under reduced pressure at 120° C. for 12 hours using a vacuum dryer, thereby obtaining a compound 2-2 represented by the following Formula (2-2). The obtained compound 2-2 had a number average molecular weight (Mn) of 1,900 and a weight average molecular weight (Mw) of 4,100.

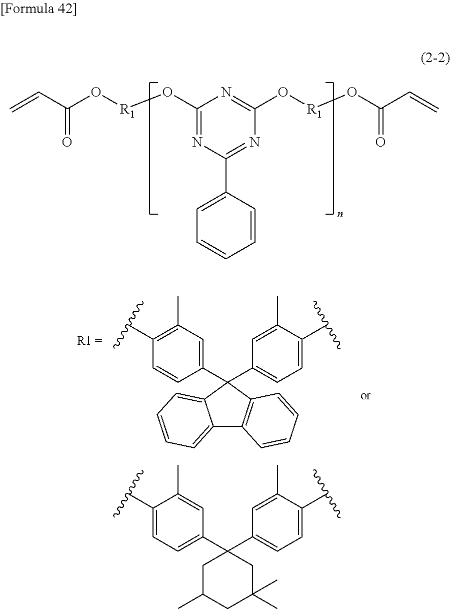

### Synthesis Example 2-3

A compound 2-3 represented by the following Formula (2-3) was obtained by synthesis in the same manner as in Synthesis Example 2-2, except that the raw material used was changed from acryloyl chloride to methacryloyl chloride (4.06 g). The obtained compound 2-3 had a number average molecular weight (Mn) of 1,900 and a weight average molecular weight (Mw) of 4,100.

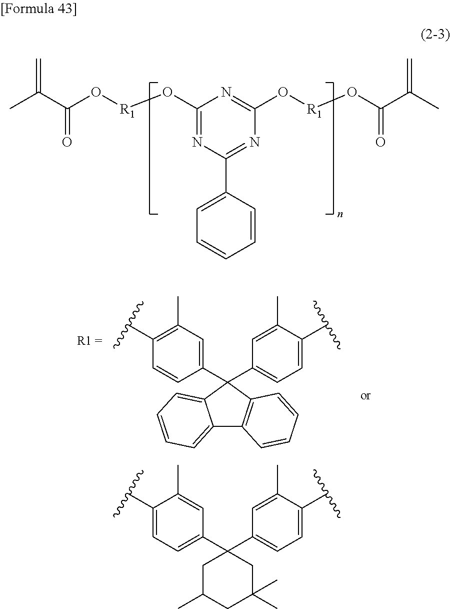

### Synthesis Example 2-4

A compound 2-4 represented by the following Formula (2-4) was obtained by synthesis in the same manner as in Synthesis Example 2-1, except that the raw materials and the alkali metal compound used were changed to 1,1-bis(4-hydroxy-3-methylphenyl)-3,3,5-trimethyleyclohexane (33.85 g), 4,6-dichloro-2-phenylpyrimidine (16.65 g), m,p-chloromethylstyrene (11.53 g), potassium carbonate (18.65 g), and N-methyl-2-pyrrolidone (55.0 g). The obtained compound 2-4 had a number average molecular weight (Mn) of 1,800 and a weight average molecular weight (Mw) of 4,000.

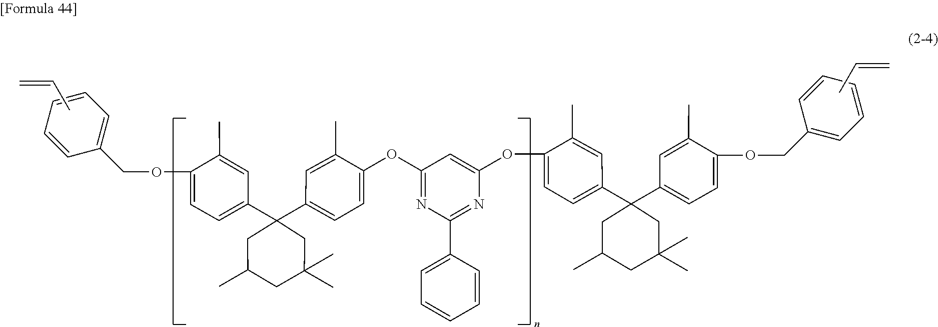

### Synthesis Example 2-5

A compound 2-5 represented by the following Formula (2-5) was obtained by synthesis in the same manner as in Synthesis Example 2-1, except that the raw materials and the alkali metal compound used were changed to 2,2-bis(4-hydroxy-3-methylphenyl)propane (26.43 g), 4,6-dichloro-2-phenylpyrimidine (17.08 g), m,p-chloromethylstyrene (11.53 g), potassium carbonate (19.23 g), and N-methyl-2-pyrrolidone (42.50 g). The obtained compound 2-5 had a number average molecular weight (Mn) of 1,600 and a weight average molecular weight (Mw) of 3,200.

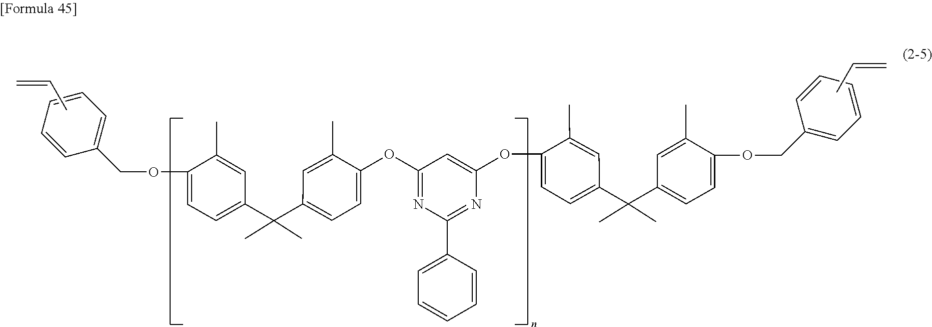

### Synthesis Example 2-6

A compound 2-6 represented by the following Formula (2-6) was obtained by synthesis in the same manner as in Synthesis Example 2-1, except that the raw materials and the alkali metal compound used were changed to 1,1-bis(4-hydroxyphenyl)-3,3,5-trimethylcyclohexane (57.95 g), 4,6-dichloropyrimidine (31.72 g), m,p-chloromethylstyrene (8.09 g), potassium carbonate (33.77 g), and N-methyl-2-pyrrolidone (42.67 g). The obtained compound 2-6 had a number average molecular weight (Mn) of 1,500 and a weight average molecular weight (Mw) of 3,100.

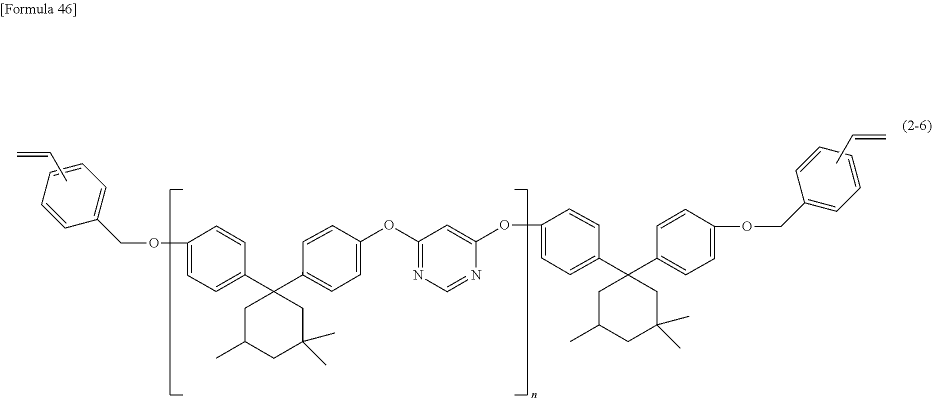

### Examples 1 to 41

The respective compounds were mixed at the mixing ratios shown in Tables 1 to 4 to prepare the compositions shown in Examples 1 to 41. Then, in accordance with the methods described above, Df, Dk, and Tg of film-shaped cured products obtained using the compositions of the respective examples were measured. The measurement results are shown in Tables 1 to 4. In Examples 34 and 35, Df, Dk, and Tg could not be measured due to insufficient curing.

TABLE 1

| Example | | 1 | 2 | 3 | 4 | 5 | 6 | 7 | 8 |
|---|---|---|---|---|---|---|---|---|---|
| Mixing ratio | Compound | 90 | 30 | | | | | | |
| (Mass ratio) | 1-1 | | | | | | | | |
| | Compound | | | 90 | 30 | 90 | 70 | 90 | 70 |
| | 1.2 | | | | | | | | |
| | Compound | 10 | 70 | 10 | 70 | | | | |
| | 2-1 | | | | | | | | |
| | Compound | | | | | 10 | 30 | | |
| | 2-2 | | | | | | | | |
| | Compound | | | | | | | 10 | 30 |
| | 2-3 | | | | | | | | |
| | Compound | | | | | | | | |
| | 2-4 | | | | | | | | |
| | Compound | | | | | | | | |
| | 2-5 | | | | | | | | |
| | Compound | | | | | | | | |
| | 2-6 | | | | | | | | |

| | | | | | | | | |
|---|---|---|---|---|---|---|---|---|
| Tg (° C.) | 116 | 144 | 136 | 215 | 135 | 160 | 136 | 161 |
| Dk | 2.6 or less | 2.6 or less | 2.6 or less | 2.6 or less | 2.6 or less | 2.6 or less | 2.6 or less | 2.6 or less |
| Df | 0.0005 | 0.00087 | 0.00051 | 0.0009 | 0.000577 | 0.000871 | 0.000587 | 0.000901 |

TABLE 2

| Example | | 9 | 10 | 11 | 12 | 13 | 14 | 15 |
|---|---|---|---|---|---|---|---|---|
| Mixing ratio | Compound | | | | | | | |
| (Mass ratio) | 1-1 | | | | | | | |
| | Compound | 97 | 95 | 80 | 70 | 30 | 97 | 95 |
| | 1-2 | | | | | | | |
| | Compound | 3 | 5 | 20 | 30 | 70 | | |
| | 2-1 | | | | | | | |
| | Compound | | | | | | | |
| | 2-2 | | | | | | | |
| | Compound | | | | | | | |
| | 2-3 | | | | | | | |
| | Compound | | | | | | 3 | 5 |
| | 2-4 | | | | | | | |
| | Compound | | | | | | | |
| | 2-5 | | | | | | | |
| | Compound | | | | | | | |
| | 2-6 | | | | | | | |

| Tg (° C.) | 127 | 130 | 149 | 163 | 215 | 126 | 129 |
|---|---|---|---|---|---|---|---|
| Dk | 2.6 or less | 2.6 or less | 2.6 or less | 2.6 or less | 2.6 or less | 2.6 or less | 2.6 or less |
| Df | 0.00045 | 0.00046 | 0.00056 | 0.00063 | 0.0009 | 0.00045 | 0.00047 |
| | Example | | 16 | 17 | 18 | 19 | 20 |
| | Mixing ratio | Compound | | | | | |
| | (Mass ratio) | 1-1 | | | | | |
| | | Compound | 90 | 80 | 70 | 50 | 30 |
| | | 1-2 | | | | | |
| | | Compound | | | | | |
| | | 2-1 | | | | | |
| | | Compound | | | | | |
| | | 2-2 | | | | | |
| | | Compound | | | | | |
| | | 2-3 | | | | | |
| | | Compound | 10 | 20 | 30 | 50 | 70 |
| | | 2-4 | | | | | |
| | | Compound | | | | | |
| | | 2-5 | | | | | |
| | | Compound | | | | | |
| | | 2-6 | | | | | |

| | | | | | |
|---|---|---|---|---|---|
| Tg (° C.) | 134 | 143 | 154 | 173 | 190 |
| Dk | 2.6 or less | 2.6 or less | 2.6 or less | 2.6 or less | 2.6 or less |
| Df | 0.00051 | 0.00052 | 0.00058 | 0.0007 | 0.0008 |

TABLE 3

| Example | | 21 | 22 | 23 | 24 | 25 | 26 | 27 | 28 |
|---|---|---|---|---|---|---|---|---|---|
| Mixing ratio | Compound | | | | | | | | |
| (Mass ratio) | 1-1 | | | | | | | | |
| | Compound | 97 | 95 | 90 | 80 | 70 | 50 | 30 | 97 |
| | 1-2 | | | | | | | | |
| | Compound | | | | | | | | |
| | 2.1 | | | | | | | | |
| | Compound | | | | | | | | |
| | Compound | | | | | | | | |
| | 2-3 | | | | | | | | |
| | Compound | | | | | | | | |
| | 2-4 | | | | | | | | |
| | Compound | 3 | 5 | 10 | 20 | 30 | 50 | 70 | |
| | 2.5 | | | | | | | | |
| | Compound | | | | | | | | 3 |
| | 2-6 | | | | | | | | |

| | | | | | | | | |
|---|---|---|---|---|---|---|---|---|
| Tg (° C.) | 123 | 124 | 127 | 131 | 138 | 145 | 154 | 125 |
| Dk | 2.6 or less | 2.6 or less | 2.6 or less | 2.6 or less | 2.6 or less | 2.6 or less | 2.6 or less | 2.6 or less |
| Df | 0.00041 | 0.00045 | 0.00045 | 0.0005 | 0.0006 | 0.00081 | 0.00083 | 0.00046 |

| Example | | 29 | 30 | 31 | 32 | 33 |
|---|---|---|---|---|---|---|
| Mixing ratio | Compound | | | | | |
| (Mass ratio) | 1-1 | | | | | |
| | Compound | 95 | 90 | 80 | 70 | 50 |
| | 1-2 | | | | | |
| | Compound | | | | | |
| | 2.1 | | | | | |
| | Compound | | | | | |
| | Compound | | | | | |
| | 2-3 | | | | | |
| | Compound | | | | | |
| | 2-4 | | | | | |
| | Compound | | | | | |
| | 2.5 | | | | | |
| | Compound | 5 | 10 | 20 | 30 | 50 |
| | 2-6 | | | | | |

| | | | | | |
|---|---|---|---|---|---|
| Tg (° C.) | 126 | 130 | 136 | 143 | 156 |
| Dk | 2.6 or less | 2.6 or less | 2.6 or less | 2.6 or less | 2.6 or less |
| Df | 0.00048 | 0.00054 | 0.00064 | 0.00075 | 0.00097 |

TABLE 4

| Example | | 34 | 35 | 36 | 37 | 38 | 39 | 40 | 41 |
|---|---|---|---|---|---|---|---|---|---|
| Mixing ratio | Compound | 100 | | | | | | | |
| (Mass ratio) | 1-1 | | | | | | | | |
| | Compound | | 100 | | | | | | |
| | 1-2 | | | | | | | | |
| | Compound | | | 100 | | | | | |
| | 2-1 | | | | | | | | |
| | Compound | | | | 100 | | | | |
| | 2-2 | | | | | | | | |
| | Compound | | | | | 100 | | | |
| | 2-3 | | | | | | | | |
| | Compound | | | | | | 100 | | |
| | 2-4 | | | | | | | | |
| | Compound | | | | | | | 100 | |
| | 2-5 | | | | | | | | |
| | Compound | | | | | | | | 100 |
| | 2-6 | | | | | | | | |

| | | | | | | | | |
|---|---|---|---|---|---|---|---|---|
| Tg (° C.) | — | — | 255 | 245 | 249 | 209 | 159 | 188 |
| Dk | — | — | 2.6 or less | 2.6 or less | 2.6 or less | 2.6 or less | 2.6 or ess | 2.6 or less |
| Df | — | — | 0.0011 | 0.0019 | 0.002 | 0.0011 | 0.0011 | 0.0015 |

As shown in Tables 1 to 3, when the compositions shown in Examples 1 to 33 were used, cured products having low Dk and Df and a Tg of 110° C. or higher and exhibiting excellent electrical properties and heat resistance were obtained. On the other hand, in Examples 34 and 35 in which only the compound 1-1 and only the compound 1-2 were used, respectively, the cured products were not sufficiently cured and could not be evaluated. In addition, in Examples 36 to 41 in which only the compounds 2-1 to 2-6 were used, Df was higher than that in Examples 1 to 33. Metal-clad laminates actually produced using the compositions of Examples 1 to 33 exhibited excellent electrical properties and heat resistance.

From the above, it was found that the first composition containing a specific compound 1 and compound 2 has a low dielectric loss tangent, excellent heat resistance, and well-balanced practical properties, and is excellent as a substrate material.

In addition, the present disclosure can provide electronic materials with excellent electrical properties and heat resistance, such as the first composition, a cured product obtained using the first composition, a prepreg, and a metal-clad laminate.

### Second Composition

### Compound 1

The compound 1-1 and the compound 1-2 were synthesized in the same manner as in the first composition.

### <Crosslinking Agent 1>

### [Preparation of Crosslinking Agent 1-1]

As a crosslinking agent 1-1, 1,2-bis(p-vinylphenyl)ethane (BVPE) (manufactured by Linchuan Chemical Co., Ltd.) having the following structure was prepared.

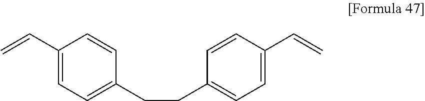 [SMILES: C=Cc1ccc(CCc2ccc(C=C)cc2)cc1]

### [Synthesis of Crosslinking Agent 1-2]

Into a 1 L four-necked flask equipped with a temperature controller, a stirring device, a cooling condenser, and a dropping funnel, 49.8 g (0.3 mol) of fluorene, 200 g of methyl isobutyl ketone, 2.91 g (9×10- mol) of tetra-n-butylammonium bromide, 0.73 g of hydroquinone, and 96 g of a 50 wt % aqueous NaOH solution (NaOH purity: 95%, 1.14 mol) were charged, and the mixture was heated to 62° C. with stirring to obtain a homogeneous solution. To the deep blue-green solution, 117 g of vinylbenzyl chloride CMS-AM manufactured by SEIMI CHEMICAL CO., LTD. (m-/p-isomer: 50/50 wt % mixture) (purity: 91%, 0.7 mol) was added dropwise over 20 minutes, and then, the mixture was reacted at 60 to 61° C. for 7 hours. After adding 200 ml of toluene to the obtained green reaction product, the solution was neutralized with 2 N hydrochloric acid and then washed three times with distilled water. After removal of toluene under reduced pressure, the obtained pale yellow viscous solid was recrystallized from fresh toluene to obtain 73.4 g (yield: 61.5%) of a grayish-white solid having a melting point of 142° C. as determined by DSC. The obtained compound was subjected to ¹H-NMR spectrum, IR spectrum, and GPC measurement to identify the structure and the weight average molecular weight Mw. Specifically, based on the GPC measurement results, the Mw of the obtained compound was 400, and from these measurement results, it was found that the obtained compound (crosslinking agent 1-2) is 9,9-bis(vinylbenzyl)fluorene (m-/p-isomer: 50/50 wt % mixture) having the structure shown below.

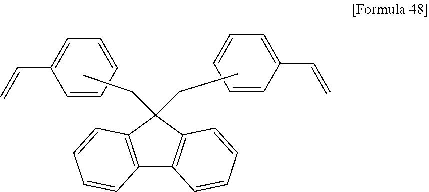

### [Synthesis of Crosslinking Agent 1-3]

A vinylbenzyl compound was obtained by performing the same procedure as in the synthesis of the crosslinking agent 1-2, except that fluorene was replaced with 35.6 g (0.3 mol) of indene, and by washing the obtained viscous liquid with methanol and then performing vacuum drying. It was confirmed that the obtained vinylbenzyl compound had an Mw of 500, and that in the structure shown below, substantially all of the two hydrogen atoms directly bonded to the carbon atom at the 1-position of indene were substituted with vinylbenzyl groups. In addition, GPC analysis revealed that the vinylbenzyl compound was a mixture of a species having two introduced vinylbenzyl groups and a species having three introduced vinylbenzyl groups.

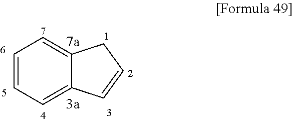

### [Preparation of Crosslinking Agent 1-4]

As a crosslinking agent 1-4, ethylene glycol dimethacrylate shown below (manufactured by TCI) was prepared.

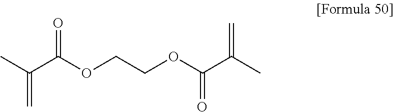

### Examples 42 to 51

The compound 1 and the crosslinking agent were mixed at the mixing ratios (parts by mass) shown in Table 5 described below to prepare the compositions shown in Examples 42 to 51. Then, in accordance with the methods described above, Df, Dk, and Tg corresponding to the compositions of each example were measured. The measurement results are shown in Table 5. However, in Example 50 in which no crosslinking agent was used, curing was insufficient and evaluation could not be performed.

In addition, metal-clad laminates were separately produced using the compositions obtained in the respective examples according to the following procedure, and the resulting laminates were evaluated. However, in Example 50 in which no crosslinking agent was used, curing was insufficient and evaluation could not be performed. With respect to the other examples, the curability of the prepared compositions was excellent.

### <Preparation of Resin Varnish>

A compound 1, an elastomer, a crosslinking agent, and an initiator described below were dissolved in toluene so as to achieve a solid content of 50 mass % at the mixing ratios shown in Table 5. Furthermore, a flame retardant and an inorganic filler were added to the obtained toluene solution at the mixing ratios shown in Table 5, and mixed and dispersed using a rotor/stator-type mixer to obtain a resin varnish.
Compound 1: the above-described compound 1-1 and resin 1-2
Crosslinking agent: the above-described crosslinking agent 1-1, crosslinking agent 1-2, crosslinking agent 1-3, and crosslinking agent 1-4
Elastomer: Tuftec H1043 (trade name, manufactured by Asahi Kasei Corporation)
Initiator: 2,3-dimethyl-2,3-diphenylbutane
Inorganic filler: spherical silica EQ2410-SCM (trade name, manufactured by Zhejiang Third Age Material Technology Co., Ltd.)
Flame retardant: ethylenebis(pentabromophenyl), trade name: SAYTEX8010 (manufactured by Albemarle Corporation)

### <Preparation of Substrate for Evaluation>

The obtained resin varnish was used to impregnate a glass cloth (E-glass, #2116), which was then sandwiched between metal bars and drawn out to remove excess varnish, and then, drying was performed at room temperature (25° C.) for 10 minutes. Next, the impregnated glass cloth was dried in an air oven at 130° C. for 4 minutes to prepare a prepreg. At that time, the amount of the curable composition relative to the prepreg, that is, the resin content (R.C.), was adjusted to be 55 mass %. Copper foils HS1-M2-VSP (trade name, manufactured by Mitsui Mining & Smelting Co., Ltd.), were placed on both surfaces of the prepreg, and molding and curing were performed using a vacuum press molding machine to obtain substrates for evaluation (copper-clad laminates for evaluation) corresponding to Examples 10 to 19. The curing conditions were a pressure of 3 MPa and a temperature of 200° C. maintained for 90 minutes.

TABLE 5

| | | | Example 42 | Example 43 | Example 44 | Example 45 | Example 46 | Example 47 |
|---|---|---|---|---|---|---|---|---|
| Compound 1 | | 1-1 | 100 | 85 | 100 | 100 | — | — |
| | | 1-2 | — | — | — | — | 100 | 100 |
| Crosslinking agent | | 1-1 | 20 | 35 | — | — | 20 | — |
| | | 1-2 | — | — | 20 | — | — | 20 |
| | | 1-3 | — | — | — | 20 | — | — |
| | | 1-4 | — | — | — | — | — | — |
| Elastomer | | | 22 | 22 | 22 | 22 | 22 | 22 |
| Initiator | | | 1 | 1 | 1 | 1 | 1 | 1 |
| Inorganic filler | | | 75 | 75 | 75 | 75 | 75 | 75 |
| Flame retardant | | | 50 | 50 | 50 | 50 | 50 | 50 |
| Film-shaped | Dk | | 2.6 or less | 2.6 or less | 2.6 or less | 2.6 or less | 2.6 or less | 2.6 or less |
| cured product | Df | | 0.00062 | 0.00071 | 0.0011 | 0.0011 | 0.00048 | 0.00096 |
| Substrate for | Tg | (° C.) | 163 | 200 | 150 | 155 | 195 | 178 |
| evaluation | Peel strength | (N/cm) | A+ | A+ | A+ | A+ | A+ | A+ |
| | | | | | Example 48 | Example 49 | Example 50 | Example 51 |
| | | Compound 1 | | 1-1 | — | — | 120 | 100 |
| | | | | 1-2 | 100 | 100 | — | — |
| | | Crosslinking agent | | 1-1 | — | 10 | | — |
| | | | | 1-2 | — | — | — | — |
| | | | | 1-3 | 20 | 10 | — | — |
| | | | | 1-4 | — | — | — | 20 |
| | | Elastomer | | | 22 | 22 | 22 | 22 |
| | | Initiator | | | 1 | 1 | 1 | 1 |
| | | Inorganic filler | | | 75 | 75 | 75 | 75 |
| | | Flame retardant | | | 50 | 50 | 50 | 50 |
| | | Film-shaped | Dk | | 2.6 or less | 2.6 or less | 2.6 or less | 2.6 or less |
| | | cured product | Df | | 0.00092 | 0.00070 | Not evaluable | 0.0017 |
| | | Substrate for | Tg | (° C.) | 165 | 185 | Not evaluable | 125 |
| | | evaluation | Peel strength | (N/cm) | A+ | At | Not evaluable | A+ |

From the above, it was found that the second composition containing a specific compound 1 and crosslinking agent 1 has a low dielectric loss tangent, heat resistance, and excellent curability, satisfies practical properties in a well-balanced manner, and is excellent as a substrate material.

In addition, the present disclosure can provide electronic materials with excellent electrical properties and heat resistance, such as the second composition, a cured product obtained using the second composition, a prepreg, and a metal-clad laminate.

It should be noted that the present disclosure is not limited to the above-described embodiments, and various modifications can be made without departing from the spirit thereof. In addition, the present disclosure may be implemented by appropriately combining the above-described embodiments and examples thereof.

From the disclosure thus described, it will be obvious that the embodiments of the disclosure may be varied in many ways. Such variations are not to be regarded as a departure from the spirit and scope of the disclosure, and all such modifications as would be obvious to one skilled in the art are intended for inclusion within the scope of the following claims.

What is claimed is:

1. A composition comprising:
a compound 1 having an olefin structure at a terminal portion; and
a compound 2 having a structure represented by the following Formula (1) and a heterocyclic structure: 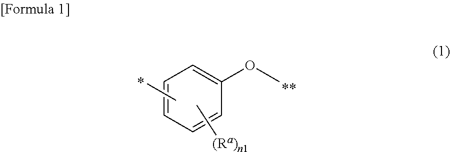
in Formula (1),
each R^{a} is independently a hydroxyl group, a halogen group, a substituted or unsubstituted C6-C20 aromatic hydrocarbon group, a substituted or unsubstituted C1-C20 alkyl group, a substituted or unsubstituted C5-C20 cycloalkyl group, or a substituted or unsubstituted C7-C20 aralkyl group,
n1 represents an integer of 0 to 4, and
* and ** each represent a bonding position.

2. The composition according to claim 1, wherein the compound 2 has a structure represented by the following Formula (2) or a structure represented by the following Formula (20): 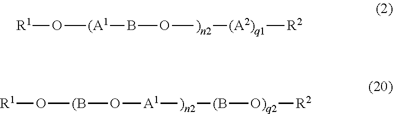
in Formulas (2) and (20),
R¹ and R² are each independently a C2-C50 group containing an ethylenically unsaturated double bond, a substituted or unsubstituted C6-C50 aromatic hydrocarbon group, a substituted or unsubstituted C6-C50 aliphatic hydrocarbon group, or a substituted or unsubstituted nitrogen-containing heteroaromatic ring,
A¹ and A² are each independently a group having a structure represented by Formula (1), provided that, in Formula (2), ** in Formula (1) represents a bonding position with B or R², and in Formula (20), ** in Formula (1) represents a bonding position with B or R²
each B is independently a divalent group having a nitrogen-containing heterocyclic structure,
each n2 is independently an integer of 1 or more,
q1 is 0 or 1, and when q1 is 0, (A²)_{q1} represents a single bond, and
q2 is 0 or 1, and when q2 is 0, (B—O)_{q2} represents a single bond.

3. The composition according to claim 1, wherein the compound 2 has a structure represented by the following Formula (3): 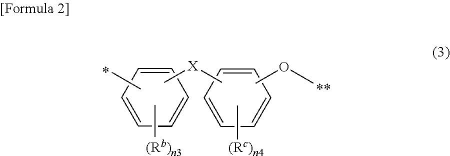
in Formula (3),
R^{b} and R^{c} are each independently a hydroxyl group, a halogen group, a substituted or unsubstituted C6-C20 aromatic hydrocarbon group, a substituted or unsubstituted C1-C20 alkyl group, a substituted or unsubstituted C5-C20 cycloalkyl group, or a substituted or unsubstituted C7-C20 aralkyl group,
n3 and n4 each independently represent an integer of 0 to 4,
X is a single bond, a substituted or unsubstituted C6-C20 aromatic hydrocarbon group, a substituted or unsubstituted C1-C20 alkylene group, a substituted or unsubstituted C5-C20 cycloalkylene group, a substituted or unsubstituted C1-C20 alkylidene group, a substituted or unsubstituted C5-C20 cycloalkylidene group, a substituted or unsubstituted C8-C20 aralkylene group, a substituted or unsubstituted C7-C20 aralkylidene group, or a group obtained by combining these groups, and
* and ** each represent a bonding position.

4. The composition according to claim 2, wherein the group having a structure represented by Formula (1) is a group represented by the following Formula (3): 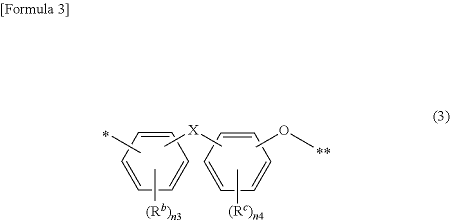
in Formula (3),
R^{b} and R^{c} are each independently a hydroxyl group, a halogen group, a substituted or unsubstituted C6-C20 aromatic hydrocarbon group, a substituted or unsubstituted C1-C20 alkyl group, a substituted or unsubstituted C5-C20 cycloalkyl group, or a substituted or unsubstituted C7-C20 aralkyl group,
n3 and n4 each independently represent an integer of 0 to 4,
X is a single bond, a substituted or unsubstituted C6-C20 aromatic hydrocarbon group, a substituted or unsubstituted C1-C20 alkylene group, a substituted or unsubstituted C5-C20 cycloalkylene group, a substituted or unsubstituted C1-C20 alkylidene group, a substituted or unsubstituted C5-C20 cycloalkylidene group, a substituted or unsubstituted C8-C20 aralkylene group, a substituted or unsubstituted C7-C20 aralkylidene group, or a group obtained by combining these groups, and
* and ** each represent a bonding position, provided that * is a bonding position with 0, and ** is a bonding position with B or R².

5. The composition according to claim 1, wherein the heterocyclic structure is a structure selected from the following: 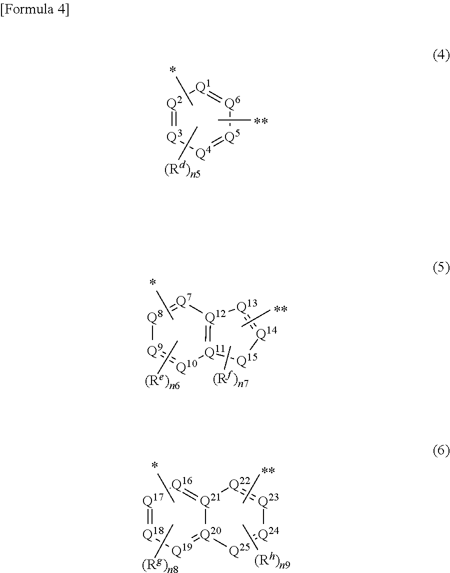
in Formulas (4) to (6),
R^{d} to R^{h} are each independently a substituted or unsubstituted C1-C20 alkyl group or a substituted or unsubstituted C6-C20 aromatic hydrocarbon group,
n5 represents an integer of 0 to 4,
n6, n8, and n9 each independently represent an integer of 0 to 3,
n7 represents an integer of 0 to 2,
Q¹ to Q²⁵ are each independently a nitrogen atom or a carbon atom, provided that at least one of Q¹ to Q⁶ is a nitrogen atom, at least one of Q⁷ to Q¹⁵ is a nitrogen atom, at least one of Q¹⁶ to Q²⁵ is a nitrogen atom, and when at least one of Q¹¹ and Q¹² is a nitrogen atom, the bond between Q¹¹ and Q¹², and the bond between Q⁷ and Q¹² and the bond between Q¹² and Q¹³, or the bond between Q¹⁰ and Q¹¹ and the bond between Q¹¹ and Q¹², are single bonds, and when at least one of Q²⁰ and Q²¹ is a nitrogen atom, the bond between Q²⁰ and Q²¹, and the bond between Q¹⁶ and Q²⁰ and the bond between Q²¹ and Q²², or the bond between Q¹⁹ and Q²⁰ and the bond between Q²⁰ and Q²⁵, are single bonds, and
* and ** each represent a bonding position.

6. The composition according to claim 2, wherein the divalent group having a nitrogen-containing heterocyclic structure is a group selected from the following: 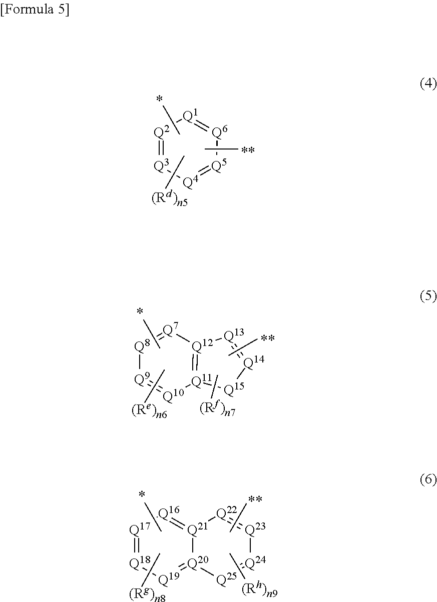
in Formulas (4) to (6),
R^{d} to R^{h} are each independently a substituted or unsubstituted C1-C20 alkyl group or a substituted or unsubstituted C6-C20 aromatic hydrocarbon group,
n5 represents an integer of 0 to 4,
n6, n8, and n9 each independently represent an integer of 0 to 3,
n7 represents an integer of 0 to 2,
Q¹ to Q²⁵ are each independently a nitrogen atom or a carbon atom, provided that at least one of Q¹ to Q⁶ is a nitrogen atom, at least one of Q⁷ to Q¹⁵ is a nitrogen atom, at least one of Q¹⁶ to Q²⁵ is a nitrogen atom, and when at least one of Q¹¹ and Q¹² is a nitrogen atom, the bond between Q¹¹ and Q¹², and the bond between Q⁷ and Q¹² and the bond between Q¹² and Q¹³, or the bond between Q¹⁰ and Q¹¹ and the bond between Q¹¹ and Q¹⁵, are single bonds, and when at least one of Q²⁰ and Q²¹ is a nitrogen atom, the bond between Q²⁰ and Q²¹, and the bond between Q¹⁶ and Q¹¹ and the bond between Q²¹ and Q²², or the bond between Q¹⁹ and Q²⁰ and the bond between Q²⁰ and Q²⁵, are single bonds, and
* and ** are each a bonding position with A¹ or O in Formula (2), and a bonding position with O or A¹ in Formula (20).

7. The composition according to claim 1, wherein the compound 2 is a compound represented by the following Formula (7): 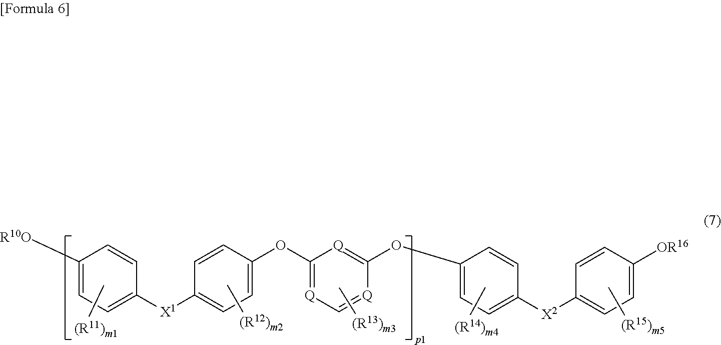
in Formula (7),
R¹⁰ and R¹⁶ are each independently a C2-C50 group containing an ethylenically unsaturated double bond, a substituted or unsubstituted C6-C50 aromatic hydrocarbon group, a substituted or unsubstituted C6-C50 aliphatic hydrocarbon group, or a substituted or unsubstituted nitrogen-containing heteroaromatic ring,
R¹¹, R¹², R¹⁴, and R¹⁵ are each independently a hydroxyl group, a halogen group, a substituted or unsubstituted C6-C20 aromatic hydrocarbon group, a substituted or unsubstituted C1-C20 alkyl group, a substituted or unsubstituted C5-C20 cycloalkyl group, or a substituted or unsubstituted C7-C20 aralkyl group,
each R¹³ is independently a substituted or unsubstituted C1-C20 alkyl group or a substituted or unsubstituted C6-C20 aromatic hydrocarbon group,
X¹ and X² are each independently a single bond, a substituted or unsubstituted C6-C20 aromatic hydrocarbon group, a substituted or unsubstituted C1-C20 alkylene group, a substituted or unsubstituted C5-C20 cycloalkylene group, a substituted or unsubstituted C1-C20 alkylidene group, a substituted or unsubstituted C5-C20 cycloalkylidene group, a substituted or unsubstituted C8-C20 aralkylene group, a substituted or unsubstituted C7-C20 aralkylidene group, or a group obtained by combining these groups,
each Q is independently a nitrogen atom or a carbon atom, provided that at least two of Q are nitrogen atoms,
m1, m2, m4, and m5 each independently represent an integer of 0 to 4,
each m3 independently represents an integer of 0 to 2, and
p1 is an integer of 1 or more.

8. The composition according to claim 1, wherein the compound 2 is a compound represented by the following Formula (7A): 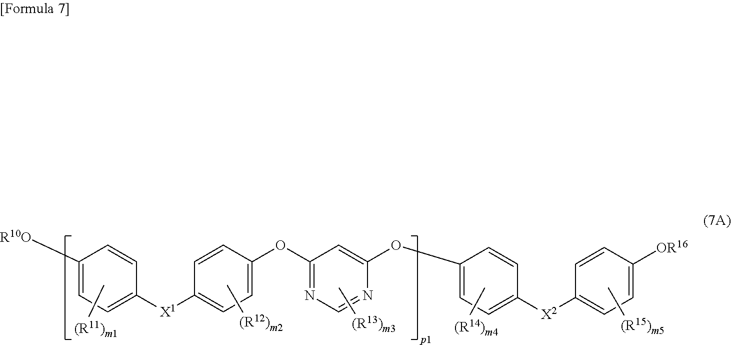
in Formula (7A),
R¹⁰ and R¹⁶ are each independently a C2-C50 group containing an ethylenically unsaturated double bond, a substituted or unsubstituted C6-C50 aromatic hydrocarbon group, a substituted or unsubstituted C6-C50 aliphatic hydrocarbon group, or a substituted or unsubstituted nitrogen-containing heteroaromatic ring,
R¹¹, R¹², R¹⁴ and R¹⁵ are each independently a hydroxyl group, a halogen group, a substituted or unsubstituted C6-C20 aromatic hydrocarbon group, a substituted or unsubstituted C1-C20 alkyl group, a substituted or unsubstituted C5-C20 cycloalkyl group, or a substituted or unsubstituted C7-C20 aralkyl group,
each R¹³ is independently a substituted or unsubstituted C1-C20 alkyl group or a substituted or unsubstituted C6-C20 aromatic hydrocarbon group,
X¹ and X² are each independently a single bond, a substituted or unsubstituted C6-C20 aromatic hydrocarbon group, a substituted or unsubstituted C1-C20 alkylene group, a substituted or unsubstituted C5-C20 cycloalkylene group, a substituted or unsubstituted C1-C20 alkylidene group, a substituted or unsubstituted C5-C20 cycloalkylidene group, a substituted or unsubstituted C8-C20 aralkylene group, a substituted or unsubstituted C7-C20 aralkylidene group, or a group obtained by combining these groups,
m1, m2, m4, and m5 each independently represent an integer of 0 to 4,
each m3 independently represents an integer of 0 to 2, and
p1 is an integer of 1 or more.

9. The composition according to claim 1, wherein the compound 1 has an isoalkenyl group at a terminal portion and further has a benzene ring structure in a molecular structure.

10. The composition according to claim 1, wherein a content ratio of the compound 1 with respect to a total content of the compound 1 and the compound 2 is 10 to 99 mass %.

11. The composition according to claim 1, wherein a dielectric loss tangent Df at 25° C. and a measurement frequency of 10 GHz is 0.0003 to 0.0009.

12. The composition according to claim 1, wherein a glass transition temperature Tg is 110 to 250° C.

13. A prepreg comprising the composition according to claim 1.

14. A metal-clad laminate comprising a cured product of the composition according to claim 1 and a metal foil.

15. A composition comprising a compound 1 having an olefin structure at a terminal portion and a crosslinking agent having an olefin structure and a benzene ring structure.

16. The composition according to claim 15, wherein the crosslinking agent includes at least one selected from the following crosslinking agents A to D: 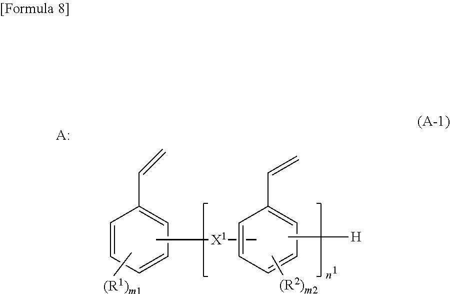
in Formula (A-1),
R¹ and R² are each independently a hydroxyl group, a halogen group, a substituted or unsubstituted C1-C20 hydrocarbon group, a substituted or unsubstituted C1-C20 heterocyclic group, a C1-C20 alkoxy group, a C1-C20 thioalkoxy group, or a C1-C20 thioaryloxy group,
each X¹ is independently a C1-C20 divalent organic group.
n¹ is an integer of 1 to 10,
m¹ is an integer of 0 to 4, and
each mA is independently an integer of 0 to 3, 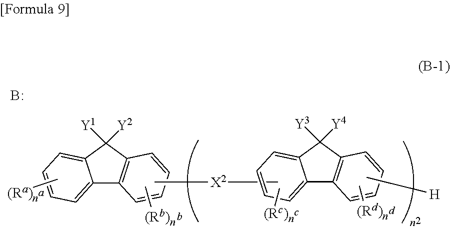
in Formula (B-1),
Y¹ to Y⁴ are each independently a hydrogen atom, a vinyl group, an allyl group, a group represented by the following Formula (B-2), or a group represented by the following Formula (B-3), provided that at least one of Y¹ to Y⁴ is a vinyl group, an allyl group, a group represented by the following Formula (B-2), or a group represented by the following Formula (B-3),
R^{a} to R^{d} are each independently a halogen group, a substituted or unsubstituted C1-C20 hydrocarbon group, a C1-C20 alkoxy group, a C1-C20 thioalkoxy group, or a C1-C20 thioaryloxy group,
each X² is independently a C1-C20 divalent organic group,
n2 is an integer of 0 to 20,
n^{a} and n^{b} are each independently an integer of 0 to 4, and
n^{c} and n^{d} are each independently an integer of 0 to 3, 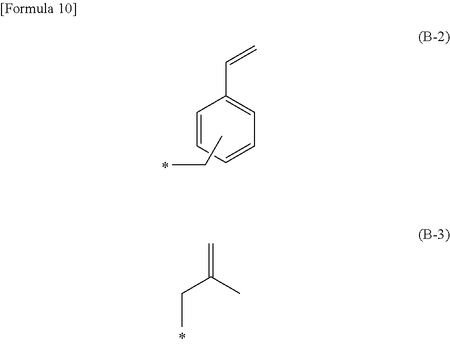
in Formulas (B-2) and (B-3), ,
* represents a bonding position, 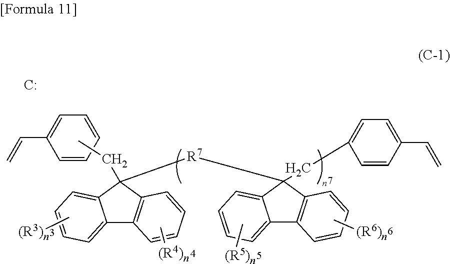
in Formula (C-1),
R³ to R⁶ are each independently a hydroxyl group, a halogen group, a substituted or unsubstituted C1-C20 hydrocarbon group, a C1-C20 alkoxy group, a C1-C20 thioalkoxy group, or a C1-C20 thioaryloxy group,
each R⁷ is independently a C1-C20 divalent organic group,
n³ to n¹ are each independently an integer of 0 to 4, and
n⁷ is an integer of 1 to 20, 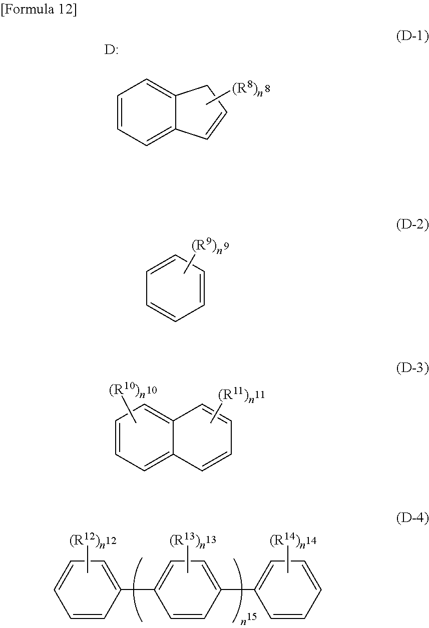
in Formulas (D-1) to (D-4),
each R⁸ is independently a vinyl group, an allyl group, a group represented by the following Formula (B-2), or a group represented by the following Formula (B3-3),
R⁹ to R¹⁴ are each independently a hydroxyl group, a halogen group, a substituted or unsubstituted C1-C20 hydrocarbon group, a substituted or unsubstituted C1-C20 heterocyclic group, a C1-C20 alkoxy group, a C1-C20 thioalkoxy group, a C1-C20 thioaryloxy group, a vinyl group, an allyl group, a group represented by the following Formula (B-2), a group represented by the following Formula (D-5), or a group represented by the following Formula (B-3), provided that each compound represented by any one of Formulas (D-2) to (D-4) has at least one selected from a vinyl group, an allyl group, a group represented by the following Formula (B-2), a group represented by the following Formula (D-5), or a group represented by the following Formula (B-3),
n⁸ is an integer of 1 to 3,
n¹¹ is an integer of 1 to 6,
n¹⁰ and n¹⁴ are each independently an integer of 0 to 4, provided that either n¹⁰ or n¹¹ is an integer of 1 or more,
n¹² and n¹¹ are each independently an integer of 0 to 5, n¹¹ is an integer of 0 to 4, provided that any one of n¹² to n¹¹ is an integer of 1 or more, and
n⁵ is an integer of 0 to 20, 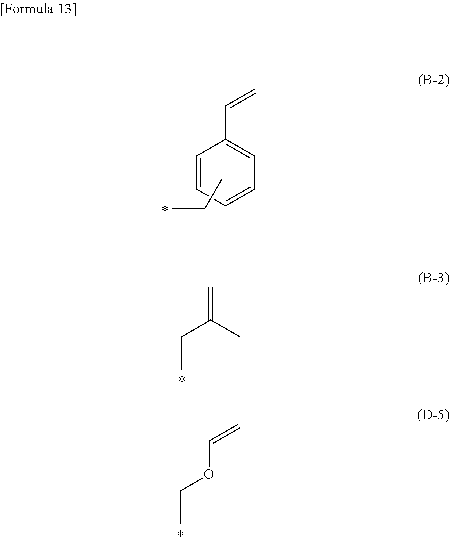
in Formulas (B-2 (B-3), and (D-5),
* represents a bonding position.

17. The composition according to claim 15, wherein the composition contains two or more kinds of the crosslinking agent.

18. The composition according to claim 15, wherein the compound 1 has an isoalkenyl group at a terminal portion and further has a, benzene ring structure in a molecular structure.

19. The composition according to claim 15, wherein a glass transition temperature Tg of a cured product of the composition is 120° C. or higher.

20. The composition according to claim 15, wherein a, dielectric loss tangent Df of a cured product of the composition at 25° C. and a measurement frequency of 10 GHz is 0.003 or less.

21. A prepreg comprising the composition according to claim 15.

22. A metal-clad laminate comprising a cured product of the composition according to claim 15 and a metal foil.
